(19) United States
(12) Patent Application Publication
(10) Pub. No.: US 2010/0107039 A1
(43) Pub. Date: Apr. 29, 2010

(54) SEMICONDUCTOR MEMORY WITH REED-SOLOMON DECODER

(75) Inventor: Haruki Toda, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Minato-ku (JP)

(21) Appl. No.: 12/524,880

(22) PCT Filed: Jan. 30, 2008
(86) PCT No.: PCT/JP2008/051903

§ 371 Date: Jul. 29, 2009

(30) Foreign Application Priority Data
Feb. 1, 2007 (JP) 2007-023142

(51) Int. Cl. H03M 13/05; G06F 11/10

(52) U.S. Cl. 714/764; 714/784; 714/E11.032; 714/763

(57) ABSTRACT

A semiconductor memory device with an error checking/correction system includes a memory cell array. The error checking/correction system is capable of symbolizing data to a symbol, searching errors of data read from the memory cell array by solving equations with decoders representing a solution, correcting data based on the searched errors, and outputting the corrected data in parallel with the other process to the other data.

### TECHNICAL FIELD

The present invention relates to a semiconductor memory device, and more particularly to an error checking/correction system therein.

### BACKGROUND ART

A flash memory, or an electrically erasable programmable nonvolatile semiconductor memory device, has an error rate that increases as the number of rewrite times increases. In particular, an advance of mass storage and fine patterning in production processes elevates the error rate. If data is multi-valued for achievement of mass storage, the error rate rises additionally. Therefore, it is an important technology to mount an ECC (Error Correcting Code) system on the flash memory.

A flash memory chip or a memory controller operative to control the chip may include the ECC circuit mounted therein as proposed in the art (see, for example, Patent Document 1).

In error correction of 2 bits or more executed in an ECC system that utilizes a finite Galois field GF(2ⁿ), a solution of an error location search equation may be found by sequentially assigning elements in the finite field to select an element that satisfies the equation as the solution. Such the error location search however, requires a massive amount of calculation time and greatly lowers the read/write performance of the memory in the case of the on-chip system.

Therefore, there is a need for a fast ECC system that does not require such the sequential search, therefore, that does not sacrifice the performance of the flash memory.

### [Patent Document 1] JP 2000-173289A

### DISCLOSURE OF INVENTION

### Technical Problem

The invention has an object to provide a semiconductor memory device including an on-chip symbol data error correction system.

### Technical Solution

In an aspect the present invention provides a semiconductor memory device with an error checking/correction system, comprising: a memory cell array; and an error checking/correction system capable of symbolizing data to be written in the memory cell array at every set of certain bits as a symbol, searching errors of data read from the memory cell array by solving equations with decoders representing a solution, correcting data based on the searched errors, and outputting the corrected data in parallel with the other process to the other data.

### EFFECT OF THE INVENTION

The invention is possible to provide a semiconductor memory device including an on-chip symbol data error correction system.

### BRIEF DESCRIPTION OF DRAWINGS

FIG. 1 A table indicative of relations between components of expression indexes modulo 255.

FIG. 2 A table indicative of associations between indexes n of αⁿ and representations by two expression indexes shown in FIG. 1.

FIG. 3 A diagram showing a configuration of an ECC system in one embodiment.

FIG. 4 A configuration example of a memory core to which the same ECC system is applied.

FIG. 5 A diagram showing encoding/decoding methods in 3 cases in the same ECC system.

FIG. 6 A diagram for illustrating a method of generating a code polynomial in the same ECC system.

FIG. 7 A diagram showing a code computing system in the same ECC system.

FIG. 8 A diagram showing a configuration of a shift resister SR and a clock circuit used in FIG. 7.

FIG. 9 An association table between coefficient pre-decoding of elements in GF(256) and components modulo 17 of expression indexes.

FIG. 10 An association table between coefficient pre-decoding of elements in GF(256) and components modulo 15 of expression indexes.

FIG. 11 A diagram for illustrating a relation between clocks on taking input data and transferring data to a code computing system.

FIG. 12 A diagram showing a pre-decoding circuit 700a in a pre/index decoding circuit 700 of FIG. 7.

FIG. 13 A diagram showing an index-decoding circuit 700b in the pre/index decoding circuit 700 of FIG. 7.

FIG. 14 A diagram showing an index/binary conversion circuit 700c in the pre/index decoding circuit 700 of FIG. 7.

FIG. 15 A diagram showing a configuration of a zero judge circuit 711 in each adder unit of FIG. 7.

FIG. 16 A diagram showing a configuration of a binary/index conversion circuit 712 in each adder unit of FIG. 7.

FIG. 17 A diagram showing circuitry of calculating a component modulo 17 in an adder (agᵢ adder) in the code computing system.

FIG. 18 A diagram showing circuitry of calculating a component modulo 15 in an adder (agᵢ adder) in the code computing system.

FIG. 19A A diagram showing specific circuitry of an adder 173 of FIG. 17.

FIG. 19B A diagram showing a circuit symbol of the same adder.

FIG. 20A A diagram showing specific circuitry of an adder 183 of FIG. 18.

FIG. 20B A diagram showing a circuit symbol of the same adder.

FIG. 21 A diagram showing a circuit symbol and specific circuitry of a full adder.

FIG. 22 A diagram showing a circuit symbol and specific circuitry of a half adder.

FIG. 23A A table (part 1) showing associative relations between coefficients of elements in GF(256) and expression indexes.

FIG. 23B A table (part 2) showing associative relations between coefficients of elements in GF(256) and expression indexes.

FIG. 24 A diagram showing a configuration of an input decoding circuit 706 in a 4-bit parity checker/ladder 707.

FIG. 25 A diagram showing a configuration example of the 4-bit parity checker/ladder 707.

FIG. 26 A diagram showing a circuit symbol and specific circuitry of a 2-bit parity checker.

FIG. 27 A diagram showing a circuit symbol and specific circuitry of a 4-bit parity checker.

FIG. 28 A diagram for illustrating timing synchronization in data reading using data latches in 2 systems.

FIG. 29 A diagram showing a configuration of a syndrome computing system.

FIG. 30 A diagram showing a configuration of a pre-decoder in the same syndrome computing system.

FIG. 31 A diagram showing a configuration of an index decoder in the same syndrome computing system.

FIG. 32 A diagram showing a configuration of an index/binary conversion circuit in the same syndrome computing system.

FIG. 33 A diagram showing a configuration of a zero judge circuit in the same syndrome computing system.

FIG. 34 A diagram showing a configuration of an αidj (17) adder of adder circuits in the same syndrome computing system.

FIG. 35 A diagram showing a configuration of an αidj (15) adder of adder circuits in the same syndrome computing system.

FIG. 36 A diagram showing a configuration of a binary/index conversion circuit at the output section in the adder circuit.

FIG. 37 A diagram showing a configuration of an index input section of α in the αidj adder.

FIG. 38 A diagram showing a table of conversion relations between component indexes of an expression index of n, that is, {15n(17), 17n(15)}.

FIG. 39 A table showing relations between components of an expression index of αⁿ for use in the αidj adder.

FIG. 40 A diagram showing a configuration example of an index decoder at the input section in a 4-bit parity checker operative to derive a sum of outputs from the syndrome calculation adders.

FIG. 41 A diagram similarly showing another configuration example of an index decoder at the input section in a 4-bit parity checker operative to derive a sum of outputs from the syndrome calculation adders.

FIG. 42 A diagram showing a pre-decoding circuit at an input section in a first-stage adder circuit for error search.

FIG. 43 A diagram showing an index decoding circuit operative to decode the output from the same pre-decoding circuit.

FIG. 44 A diagram showing a zero decoding circuit operative to detect the state of S0=0.

FIG. 45 A diagram showing a configuration of the input section in the first-stage adder circuit for error search.

FIG. 46 A diagram showing a configuration of an SmSn adder (17) in the same circuit.

FIG. 47 A diagram showing a configuration of an SmSn adder (15) in the same circuit.

FIG. 48 A diagram showing a configuration of an S₁/S₀ adder (17) in the same circuit.

FIG. 49 A diagram showing a configuration of an S₁/S₀ adder (15) in the same circuit.

FIG. 50 A diagram showing a configuration of a first-stage parity checker for error search.

FIG. 51 A diagram showing another configuration of a first-stage parity checker for error search.

FIG. 52 A diagram showing a configuration of a pre-decoding circuit at the input section in a second-stage adder circuit for error search.

FIG. 53 A diagram showing an index decoding circuit operative to decode the output from the same pre-decoding circuit.

FIG. 54 A diagram showing a zero decoding circuit operative to detect the state of A0=0, B0=0.

FIG. 55 A diagram showing a configuration of one second-stage adder circuit for error search, or an AC adder (17).

FIG. 56 A diagram showing a configuration of one second-stage adder circuit for error search, or an AC adder (15).

FIG. 57 A diagram showing a configuration of one second-stage adder circuit for error search, or an a adder (17).

FIG. 58 A diagram showing a configuration of one second-stage adder circuit for error search, or an a adder (15).

FIG. 59 A diagram showing a configuration of one third-stage adder circuit for error search, or a D adder (17).

FIG. 60 A diagram showing a configuration of one third-stage adder circuit for error search, or a D adder (15).

FIG. 61 A diagram showing a configuration of one third-stage adder circuit for error search, or an S₁/a adder (17).

FIG. 62 A diagram showing a configuration of one third-stage adder circuit for error search, or an S₁/a adder (15).

FIG. 63 A table showing associative relations between indexes k and yₖ collectively for configuring a decoder at an input section in a final-stage adder circuit for error search.

FIG. 64 A table similarly showing relations between expression indexes {15yₖ(17), 17yₖ(15)} and expression index components 15k(17) in the case of 2 errors.

FIG. 65 A table similarly showing relations between expression indexes {15yₖ(17), 17yₖ(15)} and expression index components 17k(15) in the case of 2 errors.

FIG. 66 A diagram showing a configuration of one final-stage adder circuit for error search, or an ay adder (17).

FIG. 67 A diagram showing a configuration of one final-stage adder circuit for error search, or an ay adder (15).

FIG. 68 A diagram showing a configuration of the decoding circuit at the input section in the adder circuit in FIGS. 66, 67.

FIG. 69 A diagram showing a configuration of an index/binary conversion circuit at the same section.

FIG. 70 A diagram showing a decoder operative to generate a no index signal.

FIG. 71 A diagram showing a configuration of a binary/index conversion circuit at an output section in an adder circuit.

FIG. 72 A diagram showing a configuration of one final-stage adder circuit, or an S_{0y} adder (17).

FIG. 73 A diagram showing a configuration of one final-stage adder circuit, or an S_{0y} adder (15).

FIG. 74 A diagram showing circuitry of a 2-bit parity checker for calculating an symbol error En and an associated input decoder unit.

FIG. 75 A diagram showing a configuration of an error location decoder in the case of 2 errors.

FIG. 76 A diagram showing a configuration of an error location decoder in the case of 1 error.

FIG. 77 A diagram showing an error location decoder including a combination of the error location decoders of FIGS. 75 and 76.

FIG. 78 A diagram showing various gate circuits for use in symbol correction.

FIG. 79 A diagram showing a configuration of an error correction circuit.

FIG. 80 A diagram showing a calculation method for reconstructing an information polynomial from a corrected code polynomial.

FIG. 81 A diagram showing a configuration of a system for computing the same information polynomial.

FIG. 82 A diagram showing a timing control circuit for use in the same computing system.

FIG. 83 A diagram showing a configuration of a pre-decoding circuit in a pre/index decoding circuit at an input/output section in the same computing system.

FIG. 84 A diagram showing a configuration of an index decoding circuit in the same pre/index decoding circuit.

FIG. 85 A diagram showing a configuration of an index/binary conversion circuit at the output section in the same pre/index decoding circuit.

FIG. 86 A diagram showing a configuration of a zero judge circuit for use in each adder system in the same computing system.

FIG. 87 A diagram showing a configuration of a binary/index conversion circuit for use at an output section in each adder system in the same computing system.

FIG. 88 A diagram showing a configuration of an input decoding unit in a 4-bit parity checker/ladder in the same computing system.

FIG. 89 A diagram showing a configuration of the same 4-bit parity checker/ladder.

FIG. 90 A diagram for illustrating a code generation method for reducing index decoders in a case C.2.

FIG. 91 A diagram showing a code computing system in the same case C.2.

FIG. 92A A table (part 1) showing associations of elements in GF(256) and byte data in the same case 0.2.

FIG. 92B A table (part 2) showing associations of elements in GF(256) and byte data in the same case C.2.

FIG. 93 A diagram showing a symbol MUX circuit in the code computing system of FIG. 91.

FIG. 94 A diagram showing a zero judge circuit in the same code computing system.

FIG. 95 A diagram showing the brief for storing a finite field element in the memory as symbol data of an expression index in the case C.2.

FIG. 96 A diagram showing a pre-decoding circuit in the pre/index decoding circuit of FIG. 95.

FIG. 97 A diagram showing an index decoding circuit in the same pre/index decoding circuit.

FIG. 98 A diagram showing an index/binary conversion circuit at the output section in the same index decoding circuit.

FIG. 99 A diagram showing the deMUX circuit of FIG. 95.

FIG. 100 A diagram for illustrating timing synchronization in reading data using data latches in 2 systems.

FIG. 101 A diagram showing a data flow in reading data using the same data latches in 2 systems.

FIG. 102 A diagram showing a specific configuration of the same data latch.

FIG. 103 A diagram showing a specific configuration of a symbol correction unit.

FIG. 104 A diagram showing circuitry of a syndrome computing system.

FIG. 105 A diagram showing a configuration of a symbol MUX circuit.

FIG. 106 A diagram showing a configuration of a zero judge circuit.

FIG. 107 A diagram showing a configuration of a binary/index conversion circuit.

FIG. 108 A diagram showing a configuration of a bbi decoder circuit.

FIG. 109 A diagram showing a configuration of an f(x) computing system.

FIG. 110 A diagram showing a configuration of a clock circuit for use in the same computing system.

FIG. 111 A diagram showing a configuration of a deMUX circuit at the output section in the same computing system.

FIG. 112 A diagram showing a configuration of a c(x) computing system in a case C.3.

FIG. 113 A diagram showing clocks and shift resisters for use in the same c(x) computing system.

FIG. 114 A diagram for illustrating an f(x) reconstruction method in the case C.3.

FIG. 115 A diagram showing a specific configuration example (1) of the f(x) computing system.

FIG. 116 A diagram showing a specific configuration example (2) of the f(x) computing system.

FIG. 117 A diagram showing clocks and shift resisters for use in the specific configuration example (2) of the same f(x) computing system.

FIG. 118 A diagram showing a specific configuration example (3) in the same f(x) computing system.

### BEST MODE FOR CARRYING OUT THE INVENTION

In one embodiment of the invention, the error checking/correction system is configured to symbolize data to be written in the memory cell array at every set of certain bits as a symbol corresponding to a finite field element of a Galois Field, search errors of data read from the memory cell array by solving equations of finite elements with decoders representing solution elements wherein the solution element is expressed by a specific index, correct data based on the searched errors, and output the corrected data in parallel with the other process to the other data.

In another embodiment of the invention, the error checking/correction system is operative to previously create a table of candidates for a solution of an error location search equation and derive an index of a root using the table to check/correct a symbol error. The error checking/correction system executes a variable conversion to the error location search equation to separate a variable part from a syndrome part and utilizes a correspondence relation between indexes of a finite field element assigned to the variable part and a finite field element assigned to the syndrome part to check a symbol error location.

In another embodiment of the invention, the error checking/correction system is operative, in an index calculation for symbol error location checking and correction, to divide the number of elements in the finite field GF(2^{m}) except a zero element into mutually prime integer factors having almost the same dimension, and use expression indexes expressing indexes of primitive roots of finite field elements with residues modulo respective integer factors.

In another embodiment of the invention, the error checking/correction system is operative to associate data to be written in the memory cell array at every certain bits with a coefficient of an irreducible residue polynomial of a primitive polynomial and multiply the irreducible residue polynomial and a code generator polynomial to generate code data symbolized at the every certain bits.

In another embodiment of the invention, the error checking/correction system is operative to divide the number of elements in the finite field GF(2^{m}) into mutually prime integer factors having almost the same dimension, and use expression indexes expressing indexes of primitive roots of finite field elements with residues modulo respective integer factors to configure code data to be written in the memory cell array as a binary representation of the expression index or a code derived from the binary representation through a further conversion.

In another embodiment of the invention, the error checking/correction system includes a first and a second data register operative to alternately receive data read out of the memory cell array, and an error checking/correction unit operative to execute error checking and correction to read data in the first and second data registers, wherein the error checking/correction unit executes error checking/correction to read data in one of the first and second data registers and overwrites corrected data therein while outputting overwritten data from the other.

In another embodiment of the invention, the error checking/correction system is capable of symbolizing data to be written in the memory cell array at every byte as a finite field element associate with an element in a finite field GF(256), checking data read out of the memory cell array for an error-caused symbol and correcting the data. The error checking/correction system is operative to divide the number of elements, 255, in the finite field into mutually prime integer factors, 17 and 15, and express an index of a primitive root of a finite field element with an expression index a(17) as a residue modulo 17 and an expression index b(15) as a residue modulo 15. The error checking/correction system divides byte data to be symbolized into an upper part and a lower part, of each 4 bits, and regards the upper part as a binary representation of a(17) and the lower part as a binary representation of b(15) if a(17) is equal to 0-15, regards the upper part as a binary representation of b(15) and the lower part as a binary representation of a(17) if a(17) is equal to 16, and regards the data as a zero element of the finite field element if all bits are equal to 1.

An ECC system mounted on a memory requires real-time data correction and therefore desires fast computational processing. In addition, ECC is effective to random error occurrences, if it uses a BCH (Bose-Chaudhuri-Hocquenghem) code or an RS (Reed-Solomon) code as known. A fast, on-chip, symbol error checking/correction system using the RS code is proposed herein.

The ECC system using the RS code symbolizes a set of certain data bits as a finite field element associated with a finite field element, checks an error-caused symbol and corrects the error. In this case, as for errors in a symbol, the errors can be corrected up to the number of bits coded as the symbol. Accordingly, the error correction rate can be improved higher than when the BCH code is used.

A fast error check calculation requires a comparison of a table for solutions previously created with a syndrome computed from data read out of the memory to find a solution of an error location search equation. The key in this syndrome comparison is the use of a variable conversion to create an equation having a variable part containing an unknown number and a separated syndrome part in the error location search equation.

The following embodiment shows that, in 2-symbol error correction, appropriate setting of parameters as a method of variable conversion can separate the variable part from the syndrome part. The comparison of the table for solutions with the syndrome is executed through a comparison between indexes of finite field elements. In this case, a concept “expression index” is introduced to show that the comparison can be executed faster as parallel computations of shorter calculations.

The ECC system using such the RS code mounted on the flash memory chip makes it possible to improve the reliability of data retention without deteriorating the performance of the memory from external of the memory.

The ECC system using such the RS code in this embodiment has features as summarized below.

(a) The system executes a variable conversion to an error location search polynomial with a finite field element obtained from a syndrome as a parameter to separate a variable part from a syndrome part. Then, through an index comparison of a finite field element assigned to the variable part with a finite field element assigned to the syndrome part, the system derives a finite field element that satisfies the error location search polynomial, finds an error-caused symbol, and corrects the error in the symbol.

(b) The system divides the numeric value expressing the number of elements in the finite field except a zero element into mutually prime integer factors having almost the same dimension, and uses “expression index” representations expressing indexes by primitive roots of finite field elements with residues modulo integers of respective factors to parallel the error location search and the correction computation.

(c) When code data to be used in the system is stored in the memory, the system uses a finite field element expressed by the code data as a coefficient of an irreducible residue polynomial of a primitive polynomial.

(d) When the finite field element expressed by the code data is stored in the memory, the system uses the finite field element expressed by the code data as a binary representation of the expression index of an index of a primitive root or a code converted from the binary representation of the expression index.

(e) For fast location search and error correction, the system includes a first and a second data register arrange in parallel to retain symbol data read out of the memory. The symbol data read out of the memory for error location search calculation is retained in the first data register and the error-corrected code data is overwritten therein. In parallel with the operation of converting the retained code data into information data while outputting it, the next symbol data read out of the memory is retained in the second data register while continuing the error location search calculation.

(f) A symbol error checking/correction system using a finite Galois field GF(256) divides byte data to be symbolized into an upper part and a lower part, of each 4 bits. In this case, the system uses expression indexes 15n(17) or n(17) and 17n(15) or n(15) expressed with residues modulo 17 and 15, respectively. If 15n(17) or n(17) is equal to 0-15, then the system regards the lower part as a binary representation of 17n(15) or n(15) and the upper part as a binary representation of 15n(17) or n(17). If 15n(17) or n(17) is equal to 16, then the system regards the upper part as a binary representation of 17n(15) or n(15) and the lower part as a binary representation of 15n(17) or n(17). If all bits are equal to 1, then the system regards the data as a zero element of the finite field element and symbolizes it.

The ECC system of the embodiment is described in detail below with reference to the drawings: The below-described system is used in correction of up to 2 symbol errors using the RS code and this is referred to as a 2EC-RS-ECC system.

### [Data Encoding in 2EC-RS-ECC System]

First, data encoding is described. The 2EC system uses a Galois field (finite field) GF(2⁸). The Galois field GF(2⁸) has a primitive irreducible polynomial m₁(x) with a root α. In this case, α is a primitive root in the Galois field. The primitive irreducible polynomial m₁(x) can be represented by the following 8th order polynomial.

α:m₁(x)=x⁸+x⁴+x³+x²+1 [Expression 1]

In error correction of 2 symbols, an irreducible polynomial g(x) with roots α⁰, α¹, α² and α³ is used as a code generator polynomial, and coefficients of terms in GF(2⁸) with the orders 4, 3, 2, 1, 0 of x are denoted with g₄, g₃, g₂, g₁, g₀ as shown in Expression 2.

$$\begin{matrix}g ( x ) = ( x + {α}^{0} ) ( x + α ) ( x + {α}^{2} ) ( x + {α}^{3} ) \\ = {g}_{4} {x}^{4} + {g}_{3} {x}^{3} + {g}_{2} {x}^{2} + {g}_{1} x + {g}_{0}\end{matrix} \qquad [ Expression 2 ]$$

The coefficients are calculated specifically as in the following Expression 3.

$${g}_{4} = 1 \\ {g}_{3} = {α}^{0} + {α}^{1} + {α}^{2} + {α}^{3} = {α}^{75} \\ \begin{matrix}{g}_{2} = {α}^{0} {α}^{1} + {α}^{0} {α}^{2} + {α}^{0} {α}^{3} + {α}^{1} {α}^{2} + {α}^{1} {α}^{3} + {α}^{2} {α}^{3} \\ = {α}^{1} + {α}^{2} + {α}^{4} + {α}^{5} \\ = {α}^{249}\end{matrix} \\ \begin{matrix}{g}_{1} = {α}^{0} {α}^{1} {α}^{2} + {α}^{1} {α}^{2} {α}^{3} + {α}^{2} {α}^{3} {α}^{0} + {α}^{3} {α}^{0} {α}^{1} \\ = {α}^{3} + {α}^{6} + {α}^{5} + {α}^{4} \\ = {α}^{78}\end{matrix} \\ {g}_{0} = {α}^{0} {α}^{1} {α}^{2} {α}^{3} = {α}^{6} \qquad [ Expression 3 ]$$

The method with RS code treats a range of certain data bits as one symbol. Accordingly, 256 finite field elements in GF(2⁸) become respective symbols and each element can be represented by a coefficient of an irreducible residue of m₁(x) or a 7th order polynomial (irreducible residue polynomial) in GF(2). Therefore, if 8-bit data (=1-byte data) is treated as 1 symbol, a length of 256×8=2048 bits (=256 bytes) is the maximum correctable data bit length.

In order to make the circuitry scale of the on-ship ECC system suppressed smaller to some extent, the quantity of information data treated simultaneously as a unit of error checking/correction is preferably selected as a smaller value than the maximum data bit length. In the embodiment described below, this is limited to 128 bits (=16 bytes) though there is no inevitably to limit the quantity of information data to 16 bytes from the viewpoint of the system.

The elements forming the codes in the ECC system are 256 in number containing a zero factor in the finite field and 16 bytes of information data are associated with the finite field elements. If symbolizing coefficients containing a zero element at bit locations 32-159 on an 8-bit basis are denoted with a₀, a₁, . . . , a₁₅, then a 15th order information polynomial f(x) with these coefficients in GF(2⁸) is used as shown in Expression 4.

f(x)=a₁₅x¹⁵+a₁₄x¹⁴+ . . . +a₂x²+a₁x+a₀ [Expression 4]

For data encoding, the 15th order information polynomial f(x) is multiplied by the preceding 4th order code generator polynomial g(x) to yield a 19th order code generator polynomial c(x) containing a check bit as shown in the following Expression, 5.

$$\begin{matrix}c ( x ) = f ( x ) g ( x ) \\ = {c}_{19} {x}^{19} + {c}_{18} {x}^{18} + … + {c}_{1} x + {c}_{0}\end{matrix} \qquad [ Expression 5 ]$$

The code polynomial c(x) in Expression 5 has 20 coefficients c₀, c₁, . . . , c₁₉, which become coded data. Namely, as shown in Expression 6, code information on a symbol c₁ becomes data bits to be stored in the memory. Each code data is byte data and corresponds to a finite field element.

c₁=g₄aᵢ₋₄+g₃aᵢ₋₃+g₂aᵢ₋₂+g₁aᵢ₋₁+g₀aᵢ [Expression 6]

### [Data Decoding in 2EC-RS-ECC System]

Next, a decoding method for executing error checking/correction to data read out of the memory is described. An error caused in a data symbol is represented by a 19th order error polynomial e(x), and data read out of the memory is represented by a polynomial ν(x) as the following Expression 7.

$$\begin{matrix}v ( x ) = c ( x ) + e ( x ) \\ = {d}_{19} {x}^{19} + {d}_{18} {x}^{18} + … + {d}_{1} x + {d}_{0}\end{matrix} \qquad [ Expression 7 ]$$

Coefficients in the error polynomial e(x) of Expression 7 can be found through decoding, and the coefficients, if found, can be used in error correction.

At a first stage in decoding, roots α⁰, α¹, α² and α³ of g(x) are substituted into ν(x). The values at this time are, in accordance with the way to create c(x), made equal to those substituted into e(x), or S₀, S₁, S₂ and S₃, respectively, as shown in Expression 8. They are referred to as syndromes.

ν(α⁰)=S₀→e(α⁰)=S₀

ν(α¹)=S₁→e(α¹)=S₁

ν(α²)=S₂→e(α²)=S₂

ν(α³)=S₃→e(α³)=S₃ [Expression 8]

If there are symbol errors at i-th and j-th orders, they result in e(x)=eᵢxⁱ+eᵢx^{j}. Accordingly, derivation of i, j allows error locations to be determined, and derivation of eᵢ, eⱼ allows error correction.

These error locations can be found through a calculation within GF(256) mainly using indexes of the roots α of m₁(x)=0. The use of a residue pn(x) in xⁿ≡pn(x) mod m₁(x) results in αⁿ=pn(α).

The error-caused orders i and j are given X₁=pi(α)=αⁱ and X₂=pj(α)=α^{j} and indexes of α in the syndromes S₀, S₁, S₂ and S₃ are denoted with σ₀, σ₁, σ₂, and σ₃, respectively. The error symbols eᵢ and eⱼ are denoted with E₁ and E₂.

The elements in GF(256) thus defined have relations therebetween, which are represented by relational expressions (1)-(4) in the following Expression 9 as obvious from the syndrome calculation.

### [Expression 9]

e(α⁰)=E₁+E₂=S₀ (1)

e(α¹)=E₁X₁E₂X₂=S₁ (2)

e(α²)=E₁X₁²+E₂X₂²=S₂ (3)

e(α³)=E₁X₁³+E₂X₂³S₃ (4)

At a second stage, the relational expressions (1)-(4) in Expression 9 are used to express X₁, X₂, E₁, E₂ with the syndromes S₀, S₁, S₂, S₃. First, from the relational expressions (1) and (2) the following Expression 10 can be derived.

E₁=(S₀X₂+S₁)/(X₁+X₂)

E₂=(S₀X₁+S₁)/(X₁+X₂) [Expression 10]

Substitution of Expression 10 into the relational expressions (3), (4) yields the following Expression 11.

X₁+X₂=(S₀S₃+S₁S₂)/(S₀S₂+S₁²)

X₁X₂=(S₁S₃+S₂²)/(S₀S₂+S₁²) [Expression 11]

On the basis of this expression, an error location search equation Λ^{R}(x) for searching X₁ and X₂ can be represented by the next Expression 12 using the syndromes.

$$\begin{matrix}{Λ}^{R} ( x ) = ( x + {X}_{1} ) ( x + {X}_{2} ) \\ = {x}^{2} + ( {S}_{0} {S}_{3} + {S}_{1} {S}_{2} ) / ( {S}_{0} {S}_{2} + {S}_{1}^{2} ) x + \\ ( {S}_{1} {S}_{3} + {S}_{2}^{2} ) / ( {S}_{0} {S}_{2} + {S}_{1}^{2} )\end{matrix} \qquad [ Expression 12 ]$$

At a third stage, a root of Λ^{R}(x)=0 is found in GF(256). Namely, when Λ^{R}(αⁿ) is searched within a range of n=0-254, a hit n indicates the error symbol location X₁, X₂, from which the symbol error E₁, E₂ can be derived.

The root of Λ^{R}(x)=0 can not always be found and this equation may be first order. The errors differ in number case by case. Although the details are described later, the numbers of errors and the conditions in respective cases are summarized as in the following Expression 13.

### [Expression 13]

0 error: S₀=S₁=S₂=S₃=0.
1 error: S₀S₁S₂S₃≠0 and S₀S₂=S₁²
   In this case X₁=S₁/S₀, E₁=S₀
2 errors: S₀S₂# S₁² and S₀S₃≠S₁S₂
3 errors or more: This case corresponds to none of the above or finds no solution in 2 errors
   (Error Correction is Impossible)

The syndrome conditions in the cases of 0, 1, 2 errors shown in Expression 13 are necessary and sufficient conditions. A specific description is given as follows.

In the case of 0 error, S₀=S₁=S₂=S₃=0 is resulted obviously. Accordingly, the reverse can be established as well. In the description of the case, Eᵢ=0 can be established in the finite field based on ΣEᵢ=0, ΣEᵢXᵢ=0, ΣE₁Xᵢ²=0, ΣE₁Xᵢ³=0.

If a generator element in the Galois field is denoted with a to represent Xᵢ=α^{a+δ(i)} (δ(1)=0), then ΣEᵢα^{0δ(i)}=0, ΣEᵢα^{1δ(i)}=0, ΣEᵢα^{2δ(i)}=0, σEᵢα^{3δ(i)}=0 are established.

As relations between finite field elements are unique, simultaneous satisfaction of these relations requires Ei=0, or δ(i)=0, that is, Xᵢ=α^{a} as α^{0δ(i)}=α^{1δ(i)}=α^{2δ(i)}=α^{3δ(i)}. As the latter is 1 error, it becomes 0 error when E₁=S₀=0.

The following description is given to 1 error. If S₀=E₁, S₁=E₁X₁, S₂=E₁X₁², S₃=E₁X₁³, then S₁²=E₁S₂=S₀S₂, S₁S₂=E₁S₃=S₀S₃ (S₁S₃=E₁²X₁⁴=S₂²). As E₁≠0, X₁≠0, so E₁=S₀, X₁=S₁/S₀ at S₀S₁S₂S₃≠0.

To the contrary, if S₁²=S₀S₂, then (ΣEᵢXᵢ)²=(ΣE₁)(ΣEᵢXᵢ²) therefore ΣEᵢEⱼ(δᵢⱼ−1)Xᵢ²=0. If S₁S₃=S₂², then (ΣEᵢXᵢ²)²=(ΣEᵢXᵢ)(ΣEᵢXᵢ³), therefore ΣEᵢEⱼ(δᵢⱼ−1)Xᵢ⁴=0.

If Xᵢ=α^{a+δ(i)} (δ(1)=0) then ΣEᵢEⱼ(δᵢⱼ−1)α^{2δ(i)}=0, ΣEᵢEⱼ(δᵢⱼ−1)α^{4δ(i)}=0. The relations between the elements are unique. Accordingly, if α^{2δ(i)}=α^{4δ(i)}, then δ(i)=0 and Xᵢ=α^{a}. As S₀S₁S₂S₃≠0, so Eᵢ≠0, meaning 1 error.

The following description is given to 2 errors. In the case of 2 errors, X₁+X₂≠0, X₁X₂≠0 and, as E₁+E₂=0, E₁X₁+E₂X₂=S₁, E₁X₁²=E₂X₂²=S₂, E₁X₁³+E₂X₂³=S₃, so E₁=S₀X₂+S₁)/(X₁+X₂), E₂=(S₀X₁+S₁)/(X₁+X₂).

In calculations on GF(2), simultaneous equations are modified to derive (S₁²+S₀S₂)(X₁+X₂)=S₀S₃+S₁S₂, (S₁²+S₀S₂)X₁X₂=S₂²+SᵢS₃ from S₁(X₁+X₂)+S₀X₁X₂=S₂, S₂(X₁+X₂)+S₁X₁X₂=S₃.

To the contrary, if S₀S₂≠S₁², then S₀S₃≠S₁S₂ and the equations for deriving 2 roots X₁ᵣ X₂ can be converted into x=ay to find solutions. The equations can be satisfied only in the case of 2 errors and accordingly the solutions correspond to 2 errors. If no error can be found in the finite field, it is the case other than 2 errors.

### [Calculation Method for Error Location Search]

Next, a calculation method for the error location search equation Λ^{R}(x)=0 is described. In this embodiment, finite field elements are not sequentially substituted into x to find a solution of the equation. Instead, candidates for a solution are previously prepared as a table, and a certain calculation method is used to find an index n of the root x=αⁿ that satisfies Λ^{R}(x)=0. This calculation method is the key to achieve a high-speed, on-chip ECC system.

For that purpose, first, Λ^{R}(x) is modified and divided into a variable part and a completely separated syndrome part to enable the index n of the solution to be found only with a relation between an index of a candidate for a solution and an index of a syndrome. Specifically, A=S₀S₂+S₁², B=S₀S₃+S₁S₂, C=S₁S₃+S₂² are introduced to execute a variable conversion as in the following Expression 14.

x=ay=(B/A)y [Expression 14]

Thus, the error location search equation Λ^{R}(x)=0 can be rewritten as in the following Expression 15 in which the variable part y²+y can be separated from the syndrome part A/CB².

y²+y=D=AC/B² [Expression 15]

Basic indexes required for syndrome calculations to solve such the variable-converted equation are σ₀ of S₀, σ₁ of Sᵢ, σ₂ of S₂, σ₃ of S₃, σ_{A} of A, σ_{B} of B, σ_{C} of C, σ_{D} of D, and σₐ of a.

α^{k} is substituted into the variable y to find an index yk as in α^{2k}+α^{k}=α^{yk} to create the table. The syndrome part D in the equation has the index σ_{D}. Accordingly, k that satisfies σ_{D}≡yₖ mod 255 is the index at y corresponding to the error location. The actual error locations i, j can be determined as n in αⁿ from x=ay=α^{σa+k}=αⁿ.

From pre-conversion y₁ and y₂ corresponding to the error locations X₁ and X₂, the symbol errors E₁=eᵢ and E₂=eⱼ can be derived as in the following Expression 16 based on the equations in Expression 10.

E₁=S₀y₂+S₁/a=eᵢ

E₂=S₀y₁+S₁/a=eⱼ [Expression 16]

After the symbol errors E₁, E₂ are found, based on these errors and data dᵢ, dⱼ read out of the memory, correct codes cᵢ, cⱼ can be obtained as in the following Expression 17.

c₁₉=d₁₉, c₁₈=d₁₈, . . . , cᵢ=dᵢ+E₁, . . . , cⱼ=dⱼ+E₂, . . . , c₀=d₀ [Expression 17]

Final information data a₁ is derived through a conversion using a relational equation in Expression 18 (same as the above-described Expression 6) including code data originated from encoded information data.

cᵢ=g₄aᵢ₋₄+g₃aᵢ₋₃+g₂aᵢ₋₂+g₁aᵢ₋₁+g₀aᵢ [Expression 18]

### [Index Congruence Calculation Method for Error Location Search]

A calculation required next for error location search is to determine an index from a congruence between indexes, and the calculation method required from the system configuration is described below.

Either index congruence is an index of an element in GF(256) and accordingly has a modulus of 255. This calculation corresponds to a comparison on a scale of 255×255, which increases the circuitry scale, if executed properly.

In order to reduce the circuitry scale, 255 is divided into two mutually prime integer factors, and an index congruence is decomposed into two separated parallel congruences modulo these factors. Namely, the number capable of satisfying these two congruences simultaneously can satisfy the original congruence. This fact is utilized. Specifically, in this embodiment, in accordance with 255=17×15, two congruences modulo 17 and 15 are solved simultaneously when each congruence modulo 255 is solved.

Hereinafter, an index of a primitive root of a finite field element, which can be expressed with a residue modulo 17 of an index multiplied by 15 and a residue modulo 15 of an index multiplied by 17, is referred to as an “expression index”.

Of course, the 15-fold applied to the modulus of 17 and the 17-fold applied to the modulus of 15 are made for convenience. Accordingly, any multipliers may be used including 1 if they are mutually prime to the moduli without changing them in the construction of the system after once determined. When the multipliers are changed, an association in a relational table between a later-described expression index and an element in GF(256) varies. An example of the conversion is shown later.

The following Expression 19 shows two separated congruences derived from a computational congruence for an index σ02 of a product of syndromes S₀S₂.

σ02≡σ₀+σ₂ mod(255)→15σ02≡15σ₀+15σ₂ mod(17)17σ02≡17σ₀+17σ₂ mod(15) [Expression 19]

The following Expression 20 shows two separated congruences derived from a computational congruence for an index σ03 of a product of syndromes S₀S₃.

σ03≡σ₀+σ₃ mod(255)→15σ03≡150σ₀+15σ₃ mod(17)17σ03≡17σ₀+17σ₃ mod(15) [Expression 20]

The following Expression 21 shows two separated congruences derived from a computational congruence for an index 612 of a product of syndromes S₁S₂-

σ12≡σ₁+σ₂ mod(255)→15σ12≡150σ₁+15σ₂ mod(17)17σ12≡17σ₁+17σ₂ mod(15) [Expression 21]

The following Expression 22 shows two separated congruences derived from a computational congruence for an index σ13 of a product of syndromes S₁S₃.

σ13≡σ₁+σ₂ mod(255)→15σ13≡15σ₁+15σ₃ mod(17)17σ13≡17σ₁+17σ₂ mod(15) [Expression 22]

Two congruences for use in deriving an expression index σₐ of a=B/A from indexes σ_{A} and σ_{B} of A and B obtained from the syndromes are represented by the following Expression 23.

σₐ≡σ_{B}−σ_{A} mod(255)→15σₐ≡15σ_{B}−15σ_{A} mod(17)17σₐ≡17σ_{B}−17σ_{A} mod(15) [Expression 23]

Two congruences for use in deriving an expression index σ_{AC} of AC from A, C obtained through calculations between the syndromes are represented by the following Expression 24.

σ_{AC}≡σ_{A}−σ_{C} mod(255)→15σ_{AC}≡15σ_{A}+15σ_{C} mod(17)17σ_{AC}≡17σ_{A}+17σ_{C} mod(15) [Expression 24]

Two congruences for use in deriving an expression index σ_{D} of D=AC/B² from A, B, C obtained through calculations between the syndromes are represented by the following Expression 25.

σ_{D}≡σ_{AC}−2σ_{B} mod(255)→15σ_{D}≡15σ_{AC}−30σ_{B} mod(17)17σ_{D}≡17σ_{AC}−34σ_{B} mod(15) [Expression 25]

From the index σ_{D} obtained from the syndromes, an index k as in yₖ=σ_{D} can be derived using an associative relation table of the index k and yₖ. A modular arithmetic equation for deriving a sum of the index k and the index σ_{D} is represented by the following Expression 26.

n≡σₐ+k(mod 255)→15n≡15σₐ+15k(mod 17)17n≡17σₐ+17k(mod 15) [Expression 26]

As described above, the computation in the index congruence is executed with residues indexes mod 17 and mod 15, that is, the expression indexes to yield n, or an expression index with two components. In some case, however, σ_{D} may correspond to yₖ with no associated k.

A modular arithmetic equation for deriving an index σ_{S1/a} of S₁/a as an expression from an index σ_{A} obtained from the syndrome index is represented by the following Expression 27.

σ_{S1/a}≡σ₁−σₐ mod(255)→15σ_{S1/a}≡15σ₁−15σₐ mod(17)17σ_{S1/a}≡17σ₁−17σₐ mod(15) [Expression 27]

A modular arithmetic equation for deriving an index of the product S₀y as a sum of k and the index σ₀ of S₀ in which k corresponds to yₖ=σ_{D} from the index σ_{D} obtained from the syndrome using an associative relation table of the index k and yₖ to the product S₀y of S₀ is represented by the following Expression 28.

σ_{S0y}≡σ₀+k(mod 255)→15σ_{S0y}≡15σ₀+15k(mod 17)17σ_{S0y}≡17σ₀−17k(mod 15) [Expression 28]

Such the computation is executed with residues indexes or expression indexes mod 17 and mod 15 to yield σ_{s0y} as an expression index of two components. In some case, however, σ_{D} may correspond to yₖ with no associated k. The index σ_{s0y} can be used to calculate symbol errors.

A modular arithmetic equation for deriving an index σₓ of X₁=S₁/S₀ as an expression index from the index of S₀ and the index of S₁ obtained through calculations between the syndromes is represented by the following Expression 29. This index is used to calculate an error location in the case of 1 error.

σ_{X}≡σ₁−σ₀(mod 255)→15σ_{X}≡15σ₁−15σ₀(mod 17)17σ_{X}≡17σ₁−17σ₀(mod 15) [Expression 29]

As described above, on finding a relation between residues relative to a modulus of a large number, components of expression indexes modulo factors of mutually prime, almost equal numbers can be used for parallel processing to reduce the quantity of computations.

Specifically, in this embodiment, in order to parallel the computations, 255 is divided into mutually prime two factors 15 and 17, and two separated congruences are made with moduli of these factors. In this case, a residue modulo 17 of a 15-folded index and a residue modulo 15 of a 17-folded index are used as expression indexes.

Expression indexes of residues n modulo 255 are generally {an(17), bn(15)} where integers a, b suitably selected for (a, 17)=1, (b, 15)=1. In the embodiment, a=15, b=17 are selected though this selection has no inevitably and an expression index of a=b=1 may also be possible.

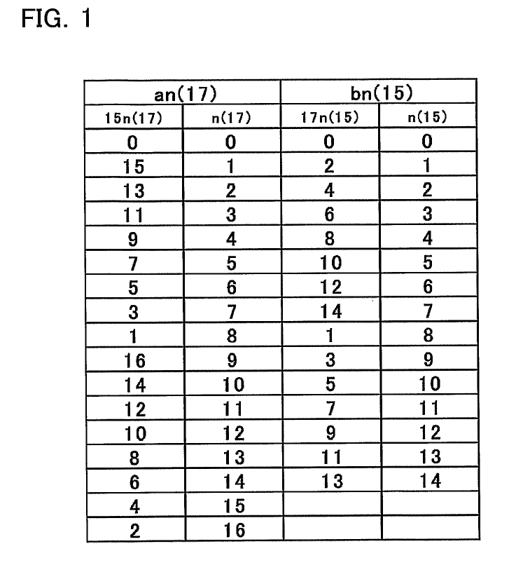

FIG. 1 shows an example of an association table between components when another expression index {n(17), n(15)} is used instead of the expression index {15n(17), 17n(15)} used in the embodiment.

In the embodiment, 255 is decomposed into 15 and 17 or two almost equally sized, mutually prime integers in a product. Depending on the size of the finite field, though, it may be divided into three or more mutually prime, almost equal integers in a product. In this case, an expression index modulo these integers having three or more components can be used in computations for parallel arithmetic, as can be analogized easily.

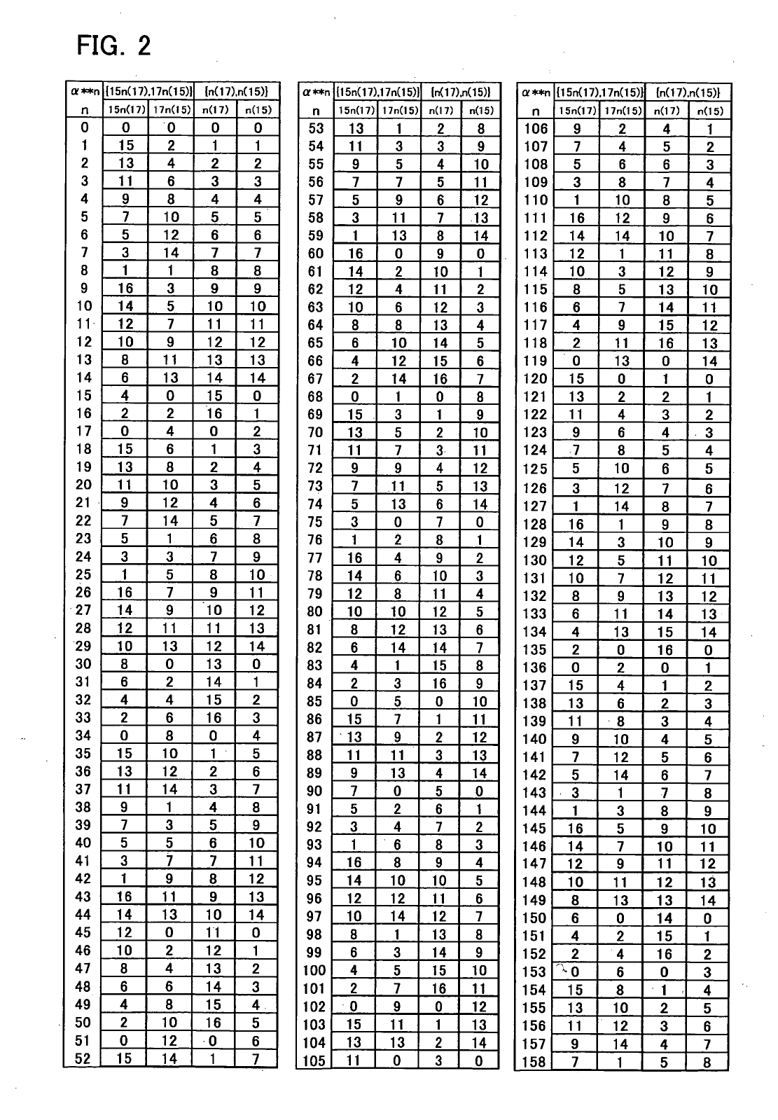

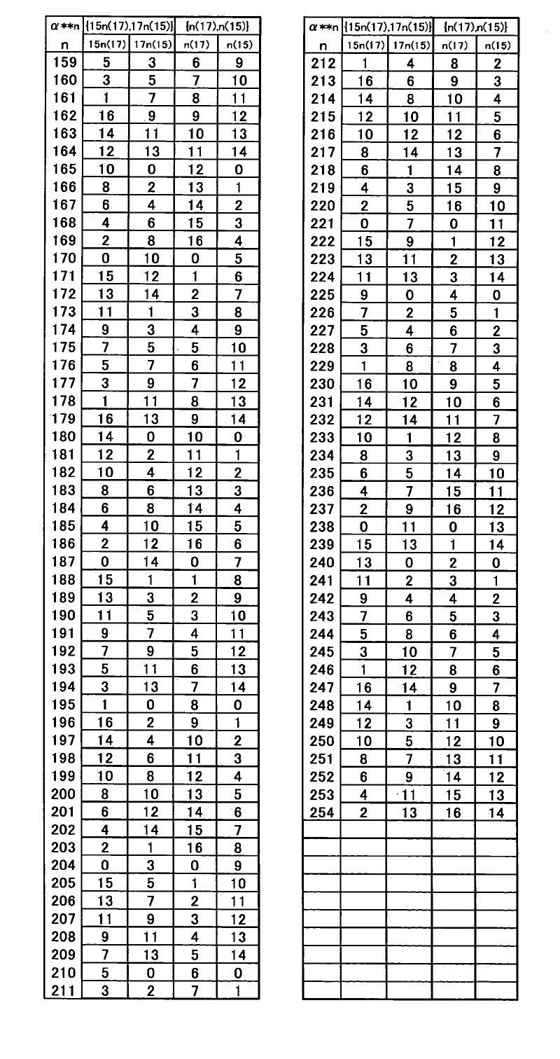

FIG. 2 shows an association of an index n of αⁿ with an expression with two expression indexes shown in FIG. 1.

### [2EC-RS-ECC System Configuration]

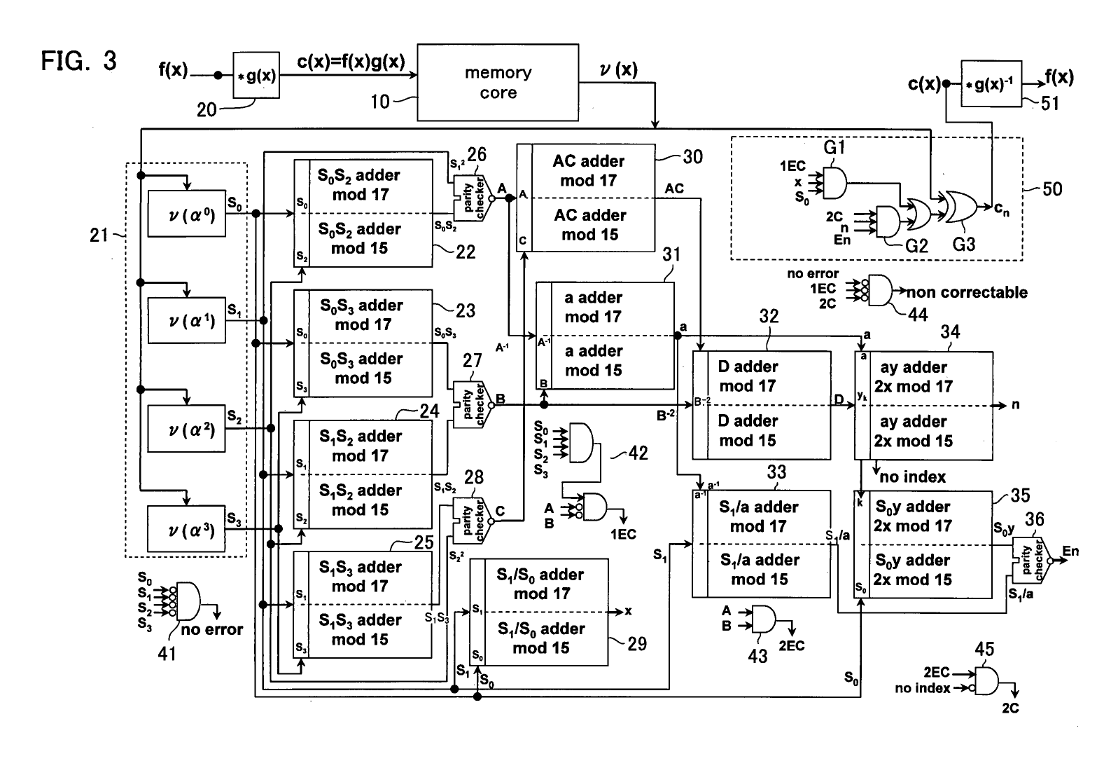

FIG. 3 is a diagram of a 2EC-RS-ECC system configuration capable of correcting errors up to 2 symbols and warning the presence of errors in 3 or more symbols.

A unit operative to generate input data to a memory core 10 is an encoding unit 20. If data of 16 bytes is denoted with a₀-a₁₅, then a 15th order information polynomial f(x) with coefficients of a₀-a₁₅ becomes input data as a correction unit.

When GF(256) is used, the information polynomial f(x) may be determined as a polynomial of the order in accordance with the number of bytes appropriately required from the configuration of data bits and selected within a range equal to or below 256 bytes. The present embodiment, though, uses information of 16 bytes, which can be easily configured as an on-chip system.

The information polynomial f(x) is multiplied by a code generator polynomial g(x) to yield a 19th order polynomial c(x) in GF(256) of which coefficients are code data to be written as symbol data in the memory.

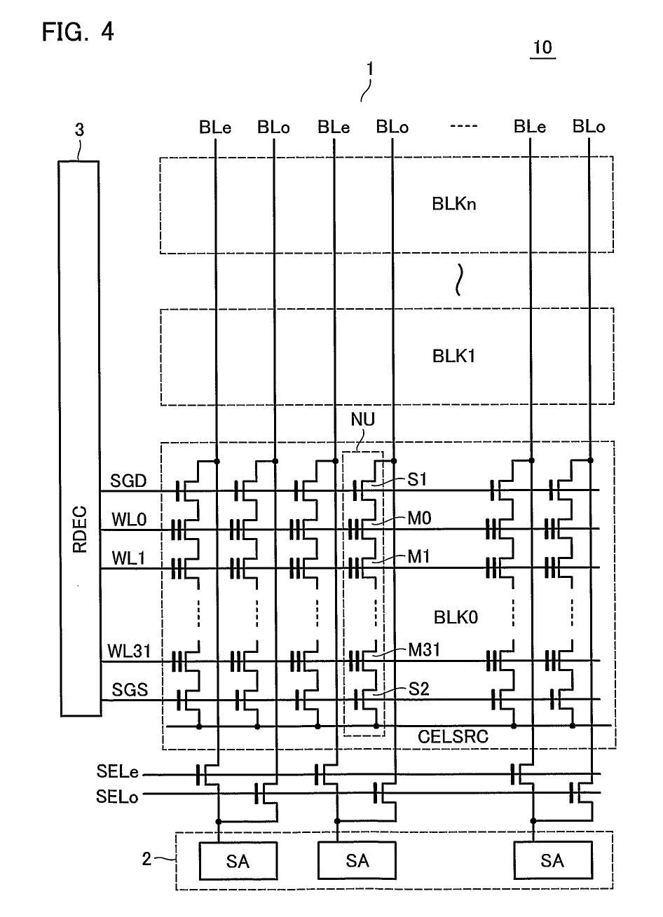

FIG. 4 shows a specific example of an NAND-type flash memory as an example of the memory core 10. A cell array 1 comprises arrayed NAND cell units NU. An NAND cell unit NU includes plural (32 in the shown example) serially connected electrically erasable programmable nonvolatile memory cells M0-M31.

The NAND cell unit NU has one end connected via a selection gate transistor S1 to a bit line BLe (BLo) and the other end connected via a selection gate transistor S2 to a common source line CELSRC.

The memory cells M0-M31 have respective control gates connected to word lines WL0-WL31. The selection gate transistors S1, S2 have respective gates connected to selection gate lines SGD, SGS. The word lines WL0-WL31 and the selection gate lines SGD, SGS are selectively driven from a row decoder 3.

A set of NAND cell units that share the word lines configures a block, which becomes a data erase unit. As shown, plural blocks BLK0-BLKn are arranged in the bit line direction.

A sense amp circuit 2 connected to the bit lines includes sense amps SA corresponding to one page subjected to simultaneous write and read. An even bit line BLe and an adjacent odd bit line BLo share one sense amp SA in the example shown herein.

The data of 20 bytes read out of the memory core 10 is treated as coefficients of a 19th order polynomial ν(x). From the polynomial ν(x), syndromes S₀, Sᵢ, S₂, S₃ are generated at a syndrome arithmetic unit 21. It substitutes roots α⁰, α¹, α², α³ of g(x) to ν(x) to obtain the syndromes S₀, S₁, S₂, S₃.

Based on the obtained syndromes, it executes error location search. If all the syndromes S₀, Sᵢ, S₂, S₃ are zero, then a gate 41 provides “no error”.

In a calculation of error location search, a product related to syndromes is obtained through an addition of binary numbers represented by indexes using an adder. Specifically, each adding unit includes two adders operative to solve two congruences mod 17 and mod 15 in a simultaneous parallel manner and executes computing with expression indexes. A sum is obtained through a union operation mod 2 between coefficients of orders represented by coefficients of a seventh order polynomial as elements in a finite field at a parity checker.

First, products and a quotient between syndromes S₀S₂, S₀S₃, S₁S₂, S₁S₃ and Sᵢ/S₀ are calculated at adding units 22, 23, 24, 25 and 29, respectively. On receipt of the outputs from these adding units, a parity checker 26 executes a union operation A=S₀S₂+S₁², a parity checker 27 executes a union operation B=S₀S₃+S₁S₂, and a parity checker 28 executes a union operation C=S₁S₃+S₂².

If S₀S₁S₂S₃≠0 and A=0 and B=0, then a gate circuit 42 provides a signal 1EC=“H” indicative of 1 error. If A≠0 and B≠0, then a gate circuit 43 provides a signal 2EC=“H” indicative of 2 errors.

An adding unit 30 is a section to obtain a factor AC of D on derivation of y from y²+y=D corresponding to 2EC and has the input portions A and C. An adding unit 31 is a section to calculate a=B/A for variable conversion x=ay and has the input portions B and A⁻¹.

An adding unit 32 is a section to derive D from the inputs of AC and B⁻². An adding unit 33 is a section to calculate S₁/a in a symbol error En=S_{0yk}+S₁/a and has the input portions S₁ and a⁻¹.

An adding unit 34 is a section to calculate an expression index at an error location n. It has an input portion, which decodes an index k of y that satisfies y²+y=D. It provides a signal “no index” if there is no corresponding decoded output. It receives the input D and transfers a decoded result k to an input portion of an adding unit 35 located beneath. In addition, it obtains a sum of an index of another input a and k to execute a variable conversion x=ay.

When the signal “no index” is output, the case is not related to 2 errors. Accordingly, a gate circuit 45 generates a signal 2C distinguishing this case from an AND of the signal 2EC and the inverted signal “no index”.

The adding unit 35 is a section to calculate S_{0yk} in a symbol error En=S_{0yk}+S₁/a. The inputs thereto include the decoded result k from the input section of the adding unit 34 located above and S₀. A parity checker 36 at the right end is a section to obtain a sum mod 2 between coefficients of the same order of a polynomial converted from an input index and operative to calculate the symbol error En=S_{0yk}+S₁/a.

Data read out of the memory core 10 is finally corrected at a correction circuit 50 surrounded by a dotted line. In the case of 1 error, the signal 1EC=“H” is output. On receipt of this signal and the error location x as well as the syndrome S₀, an AND gate G1 provides an output of “H”. As a result, each bit of the symbol read out of the memory is corrected at an XOR gate G3.

In the case of 2 errors, the signal 2C=“H” is output. On receipt of this signal and the error location n as well as the symbol error En, an AND gate G2 provides an output of “H”. As a result, each bit of the symbol read out of the memory is corrected at the XOR gate G3.

Neither one of the signals “no error”, 1EC, 2EC is generated in the case of 3 errors or more. In this case, a gate circuit 44 generates a signal “non correctable” indicative of the impossibility of correction.

The output from the correction circuit 50 is received at an output decoding unit 51. If code information of 20 bytes is denoted with c₀-c₁₉, then a 19th order polynomial c(x) with coefficients of c₀-c₁₉ is converted through a reverse operation with g(x) into the 16-byte data with the 16 coefficients a₀-a₁₅ of the information polynomial f(x) and provided to external.

The sections in the ECC system are described in detail below.

For implementation of three different methods, the following description is given to brief these methods. These methods relate to how external data is viewed as a symbol and what symbol should be stored in the memory, and to an achievement of a high-speed I/O interface.

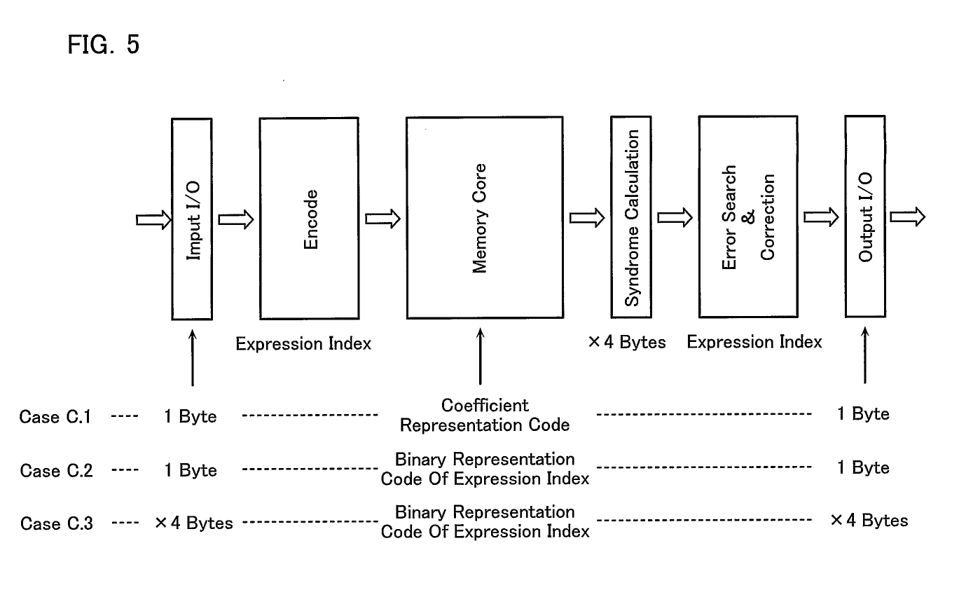

FIG. 5 shows the three cases C.1-C.3.

Case C.1 . . . . External data is regarded on a byte basis as an element in GF(256) or a coefficient of a seventh order irreducible residue polynomial pn(x) and is subjected to a code computation. Data to be stored in the memory is symbolized on a byte basis as a coefficient of the residue polynomial pn(x). In the description of the case C.1, basic methods of encoding and decoding are described.

Case C.2 . . . . A method for reducing the number of decoding circuits between coefficient representations of pn(x) and index representations, or the parts having the largest circuitry scale in the case C.1. External data is regarded as a binary representation of an expression index of an element in GF(256) to increase the parts that can be computed without decoding.

A symbol is stored in the memory on a byte basis as a binary representation of an expression index. The case C.2 is described only on the parts changed from the case C.1.

Case C.3 . . . . In the cases C.1, C.2, data is exchanged on a byte basis between the ECC system and the outside on the assumption that a data block simultaneously processed at ECC is read into the memory in 16 cycles. It may be required, however, to increase the bandwidth for data transfer with simultaneous processing of 2 bytes or more. Therefore, as an example of multi-byte simultaneous transfer or a method of exchanging data on a 4-byte basis is used as the case C.3, or as a modification of the case C.2 scheme, an interface configuration is described.

### [Description of Case C.1

First, the case C.1 is described in detail.

### (Data Encoding Unit)

The following description is given to a method of creating from external data a code polynomial c(x) having a coefficient that is code data to be stored in the memory.

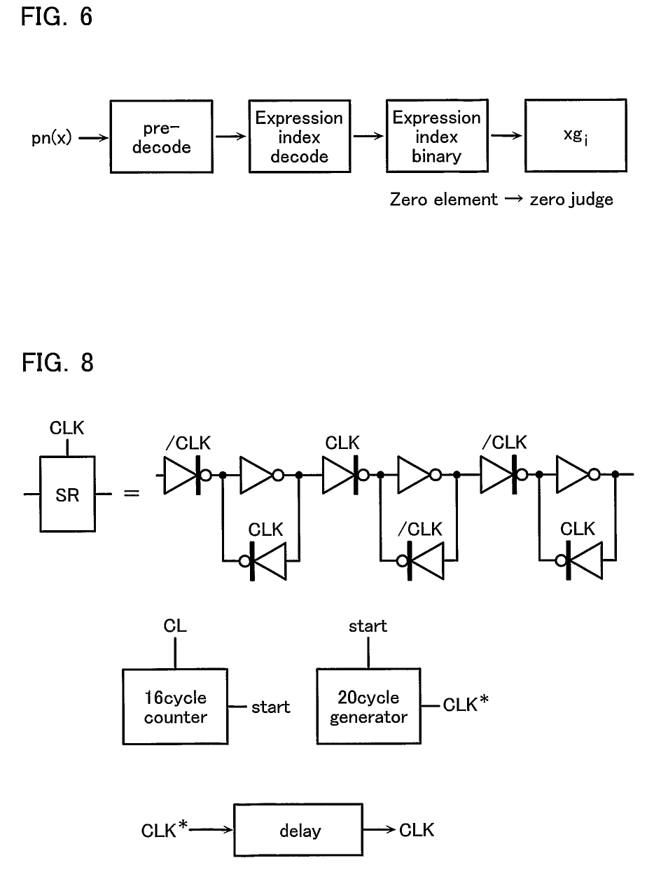

The external data is symbolized at every 8 bits (=1 byte). In order to associate a coefficient ai of the information data polynomial f(x) with a finite field element as a symbol, 8-bit data is associated with a coefficient of the seventh order irreducible residue polynomial pn(x) in GF(256). In this case, a product operation between elements is executed as additions and subtractions of indexes and, to reduce the computational scale, a coefficient of the residue polynomial pn(x) is converted into an expression index. Further, in this case, a coefficient of pn(x) is pre-decoded as shown in FIG. 6 to reduce the circuitry scale for the expression index, and the expression index is converted into one suitable for binary representation.

The representation is used to execute a product operation of an element gᵢ for creating c(x). Namely, the code polynomial is c(x)=f(x)g(x) and accordingly coefficients of the same order are compared with each other to calculate a coefficient cᵢ of c(x) using cᵢ=g₄aᵢ₋₄+g₃aᵢ₋₃+g₂aᵢ₋₂+g₁aᵢ₋₁+g₀aᵢ.

As gᵢ can be represented by an expression index and g₄=1={0,0}, g₃=α⁷⁵={3,0}, g₂=α²⁴⁹={12,3}, g₁=α⁷⁸={14,6}, g₀=α⁶={5,12}, they can be all processed through calculations of expression indexes.

A representation of α^{m}αⁿ=α^{m+n} by expression indexes results in {15m(17), 17m(15)} {15n(17), 17n(15)}={15(m+n)(17), 17(m+n)(15)}={15m+17n(17), 17m+17n(15)}. Namely, a product can be calculated as a sum of expression index components.

A sum of finite field elements is executed by parity check using expression indexes. A code cᵢ as a sum can be obtained as a coefficient expression of a residue polynomial pn(x) of a finite field element. This is directly stored in the memory as symbol data.

On conversion into an expression index, an index corresponding to a zero element in GF(256) can not be obtained as an index of a root α. Accordingly, in association with an expression index {32, 15} never used in other elements, a zero element is expressed virtually with the expression index{32,15}, that is, FF with all bytes being “1” in binary representation, judgement of a zero element “zero judge” is executed.

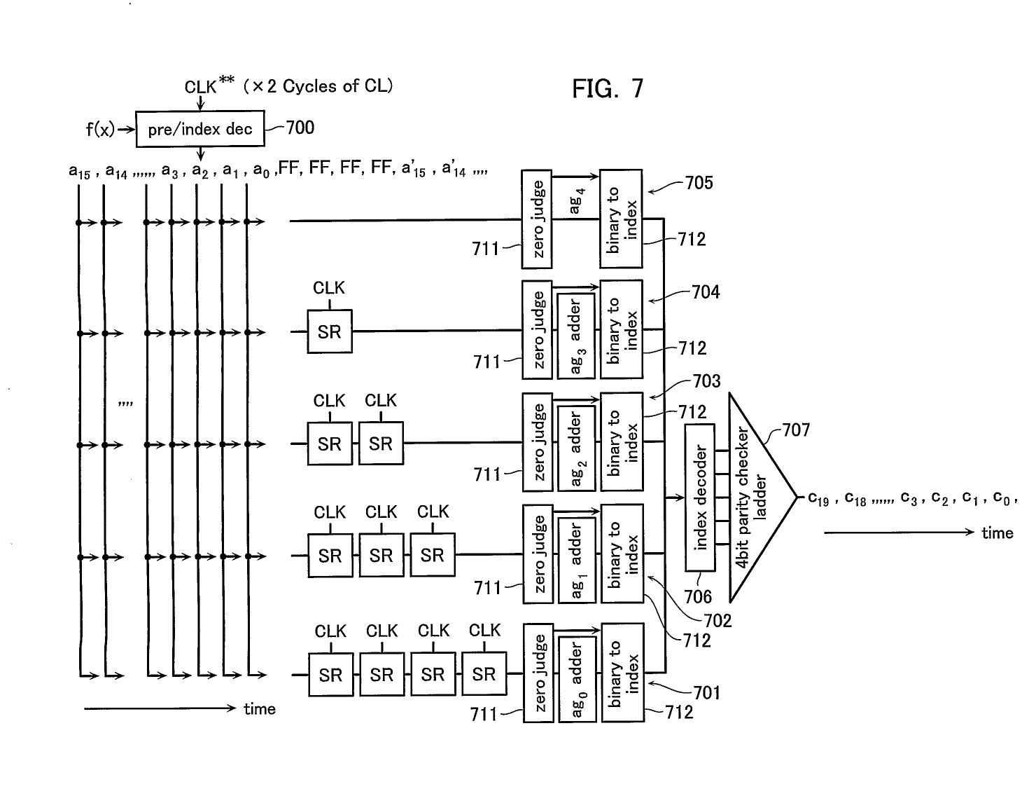

FIG. 7 shows a specific system for code calculation.

External data f(x) is taken in using a clock CL. A clock CLK** with a doubled speed and doubled cycles of the clock CL may be used to operate a pre/index decoding circuit 700 for binary representation of an expression index.

This is because the taking of external data requires 16 cycles while the processing in a computing system requires 20 cycles. Namely, it corresponds to the fact that f(x) is a 15th order polynomial while c(x) is a 19th order polynomial.

The data fed into the computing system includes a₁₅, a₁₄, a₃, a₂, a₁, a₀, FF, FF, FF, FF, a′₁₅, a′₁₄ and so on in order of time. FF represents a zero element in GF(256) with data of all “1” bits.

These pieces of index binary data are simultaneously fed into ag₀, ag₁, ag₂, ag₃ and ag₄ adder systems 701, 702, 703, 704 and 705.

For simultaneous data input to the adder systems, the ag₀ adder system 701 receives data through 4-stage shift resisters SR, and the ag₁ adder system 702 receives data through 3-stage shift resisters SR. The ag₂ adder system 703 receives data through 2-stage shift resisters SR, and the ag₃ adder system 704 receives data through 1-stage shift resister SR.

The ag₄ adder system 705 includes no adder actually present because g₄=1 and directly receives data with the configuration of the decoder only through no shift resister.

FIG. 8 shows a shift resister SR and a clock circuit used in FIG. 7. The shift resister SR determines taking data at the rise of a clock CLK and outputs previously retained data. The clock CLK is generated with a certain delay from a clock CLK*. The clock CLK* is generated 20 cycles in accordance with a trigger signal “start”.

The clock CLK** corresponds to first 16 cycles of the clock CLK*. The signal “start” is a signal generated at every 16 cycles of the clock CL for taking external data.

The adder systems 701-705 are additionally provided with zero judge circuits 711 operative to judge zero elements. In the case of a zero element, the output of a binary/index conversion or a conversion of a binary number from an adder output decoding unit into an index, is made “0” at the zero judge circuit 711 independent of the calculated result from the adder.

Five adder outputs are converted again into indexes at binary/index converter circuits 712. In order to obtain a sum, they are calculated through an index decoder 706 at a 4-bit binary checker/ladder 707 and output as code data c₁₉, c₁₈, . . . , c₂, c₁, c₀, that is, coefficients of pn(x) of an element in GF(256).

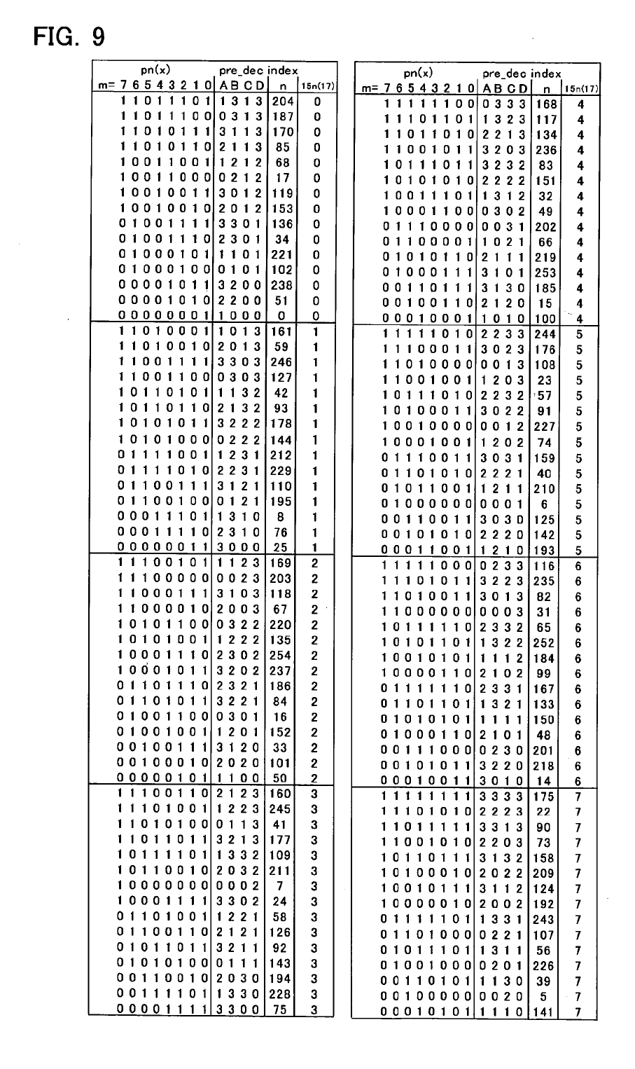

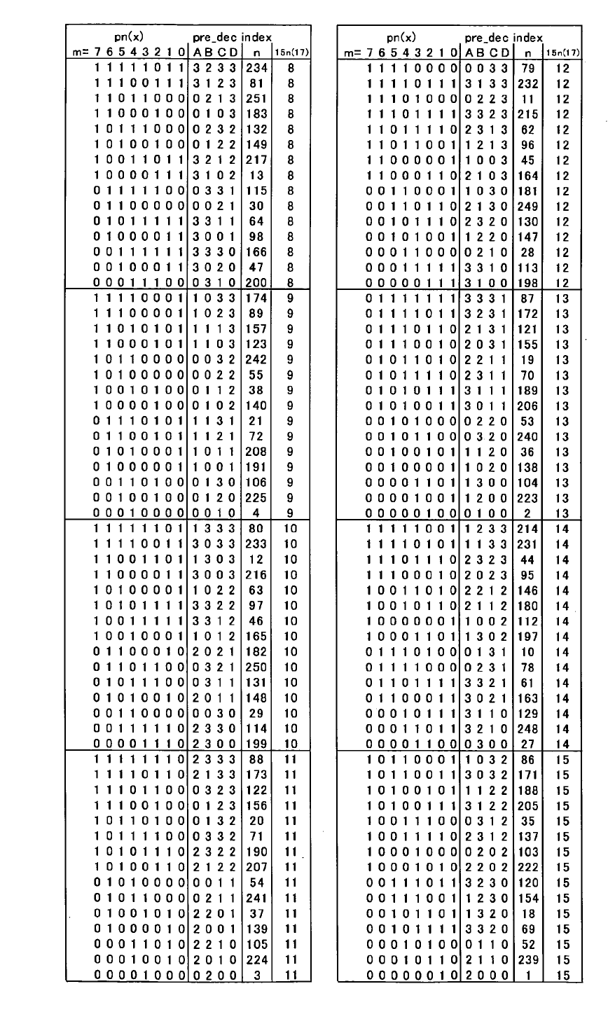

FIG. 9 is an association table between coefficient pre-decoding of elements in GF(256) and components modulo 17 of expression indexes. Namely, in this table, an index n of an irreducible residue pn(x) is multiplied by 15 and classified into residues modulo 17, that is, 15n(17).

It shows i (=0-3) of signals Ai, Bi, Ci, Di classified with indexes of 0-16, each classification containing 15 pieces of n, and pre-decoded in accordance with coefficients of associated orders of pn(x). A corresponds to m=0, 1, B to m=2, 3, C to m=4, 5 and D to m=6, 7, respectively.

These Ai, Bi, Ci, Di determine connections of signals to transistor gates in the decoder for index generation. For example, in the index 1, NAND nodes NOR-connected in parallel correspond to n=161, 59, 246, 127, 42, 93, 178, 144, 212, 229, 110, 195, 8, 76, 25, and NAND transistor gates are connected to the associated Ai, Bi, Ci, Di. Specific circuitry is shown later.

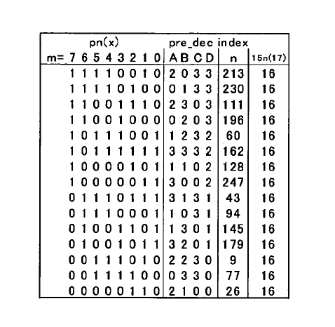

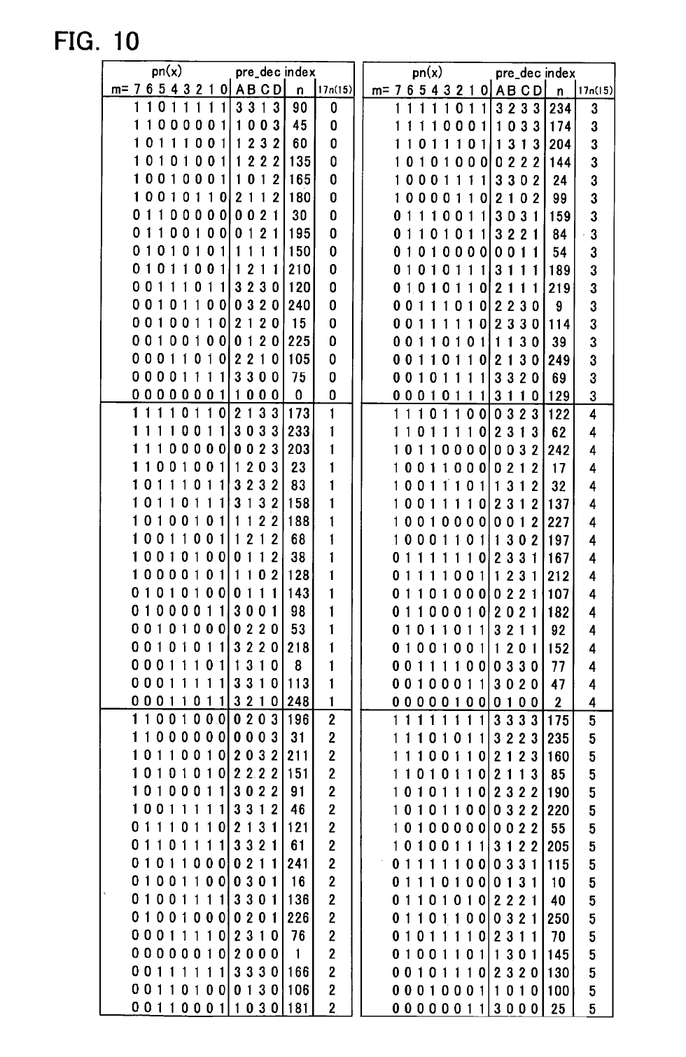

FIG. 10 is an association table between coefficient pre-decoding of elements in GF(256) and components modulo 15 of expression indexes. Namely, in this table, an index n of an irreducible residue pn(x) is multiplied by 17 and classified into residues modulo 15, that is, 17n(15).

It shows i (=0-3) of signals Ai, Bi, Ci, Di classified with indexes of 0-14, each classification containing 17 pieces of n, and pre-decoded in accordance with coefficients of associated orders of pn(x). A corresponds to m=0, 1, B to m=2, 3, C to m=4, 5 and D to m=6, 7, respectively.

These Ai, Bi, Ci, Di determine connections of signals to transistor gates in the decoder for index generation. For example, in the index 1, NAND nodes NOR-connected in parallel correspond to n=173, 233, 203, 23, 83, 158, 188, 68, 38, 128, 143, 98, 53, 218, 8, 113, 248, and NAND transistor gates are connected to the associated Ai, Bi, Ci, Di. Specific circuitry is shown later.

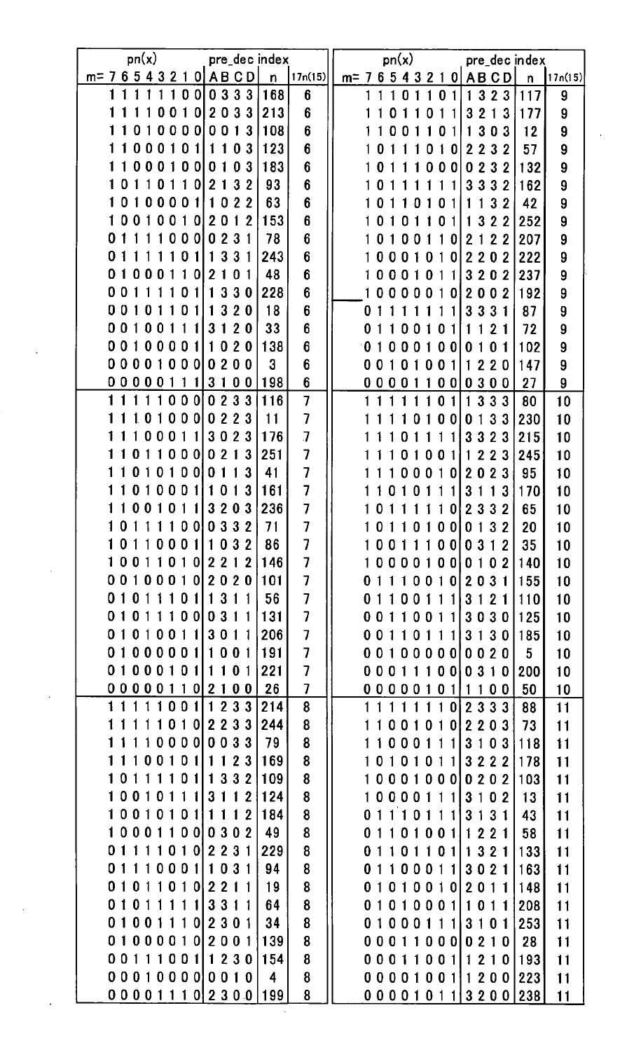

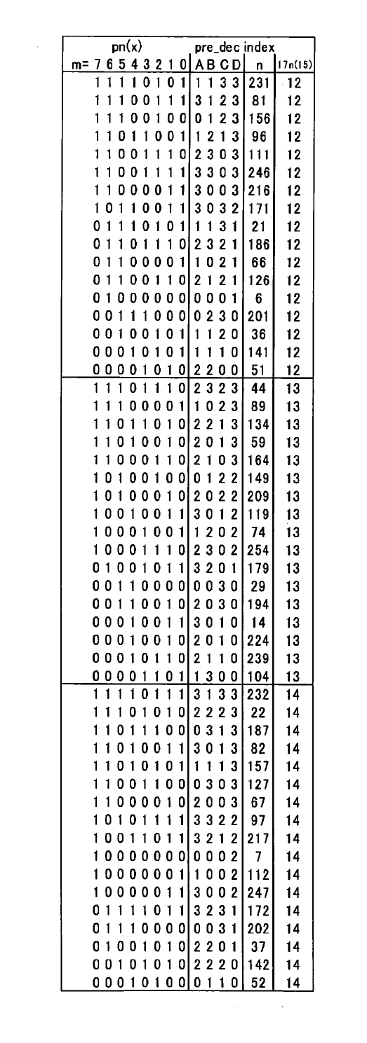

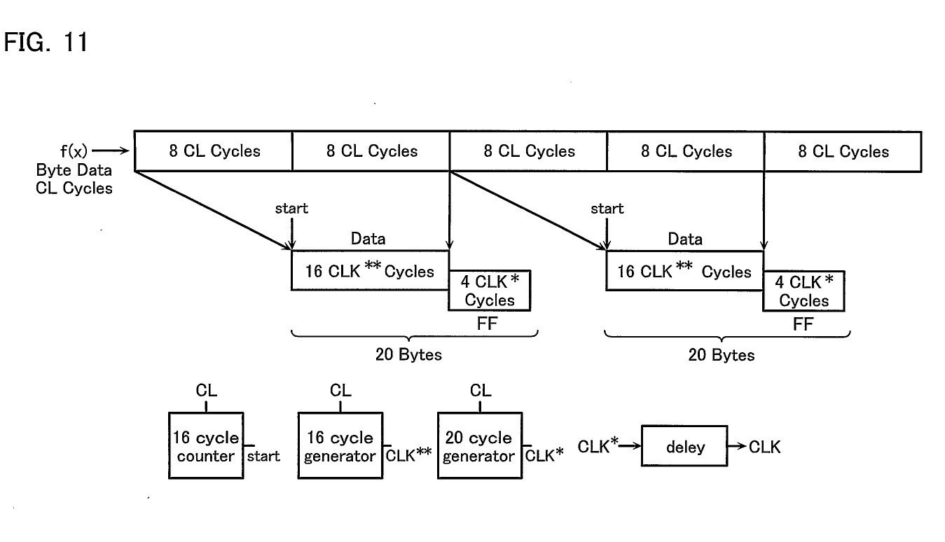

Referring now to FIG. 11, a relation between clocks and so forth on taking input data and transferring data to the code computing system is described. Data of f(x) on a byte basis is taken using the clock CL. 16 cycles of the clock CL correspond to information data of 16 bytes=128 bits, or a unit data block subjected to ECC.

The functioning of the ECC system requires encoding the information data to configure code data of 20 bytes=160 bits. In order to avoid a gap to arise in data taking, in this embodiment, internal data is processed with the clocks CLK* and CLK** having a speed doubled of the clock CL to execute arithmetic processing to the accumulated, taken data.

Namely, the trigger signal “start” is generated at every 16 CL cycles, thereby generating the clock CLK** in 16 cycles and the clock CLK* in 20 cycles to convert the data ahead 8 CL cycles into an expression index as internal data in the pre/index decoding circuit 700.

After the conversion with the pre/index decoding circuit 700 in 16 CLK** cycles, the pre/index decoding circuit 700 can not work in 4 CLK* cycles. Accordingly, FF is transferred to the computing system. The computing system is driven by the clock CLK or the delayed clock CLK*.

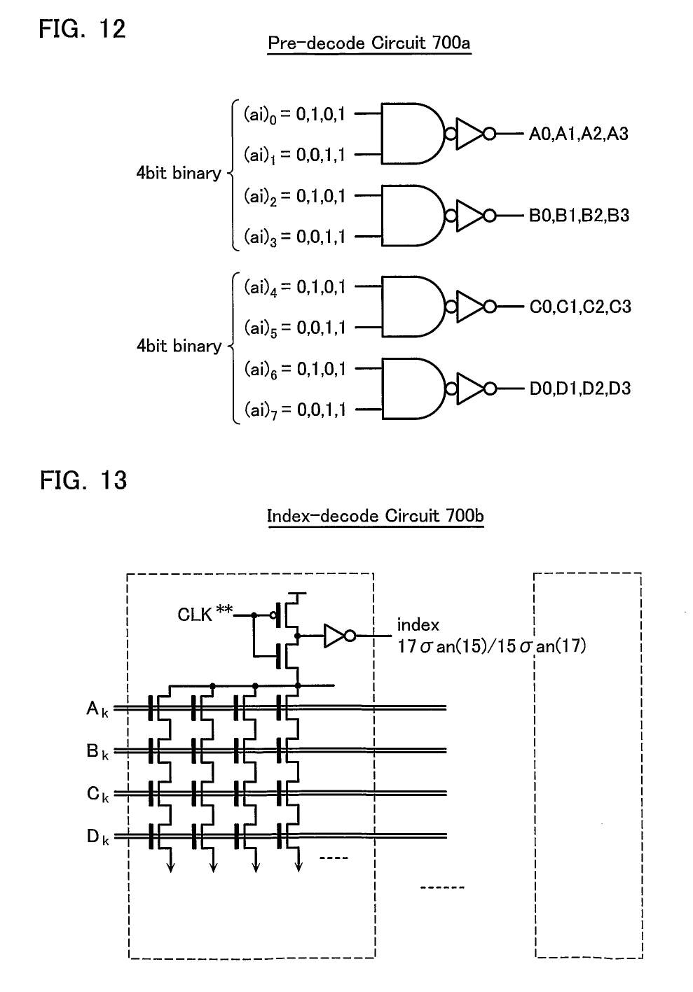

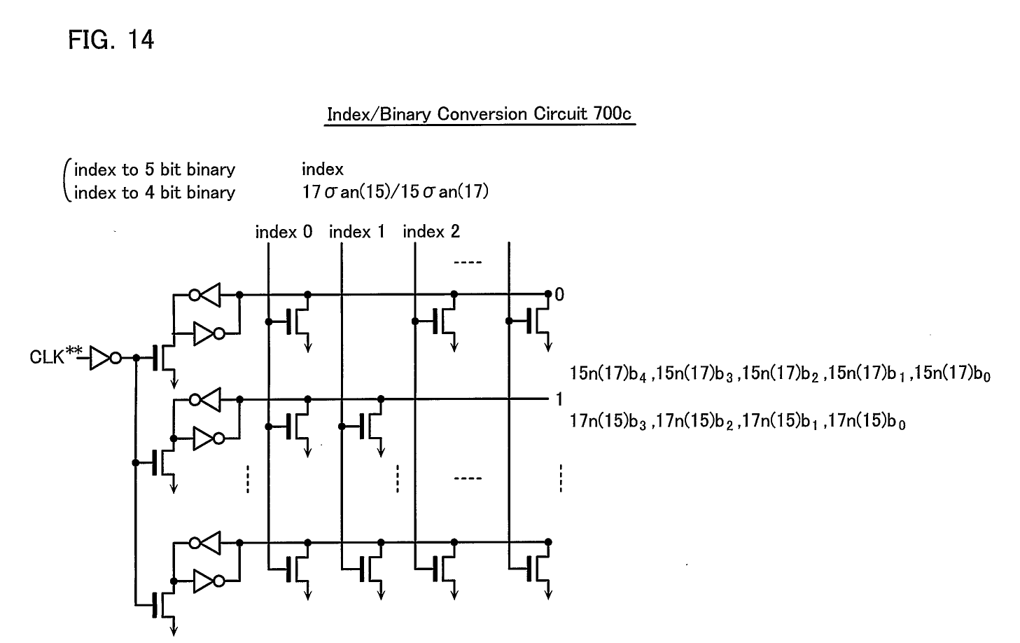

FIGS. 12-14 show components in the pre/index decoding circuit 700. Namely, FIG. 12 shows a pre-decoding circuit 700a, FIG. 13 shows an index-decoding circuit 700b, and FIG. 14 shows an index/binary conversion circuit 700c.

The pre-decoding circuit 700a generates signals in accordance with the association table of coefficients of the irreducible residue pn(x) and Ai, Bi, Ci, Di.

The index-decoding circuit 700b receives signals Ak, Bk, Ck, Dk, which are NAND-connected in accordance with the table, grouped and NOR-connected to generate components of an expression index in synchronization with the clock CLK**.

The index/binary conversion circuit 700c converts the output from the index-decoding circuit 700b into a binary representation in synchronization with the clock CLK**. It converts a component modulo 17 into binary data of 5 bits and a component modulo 15 into binary data of 4 bits. If the clock CLK** is not generated, bits in the binary representation are all made “1” to exhibit an expression FF of a zero element.

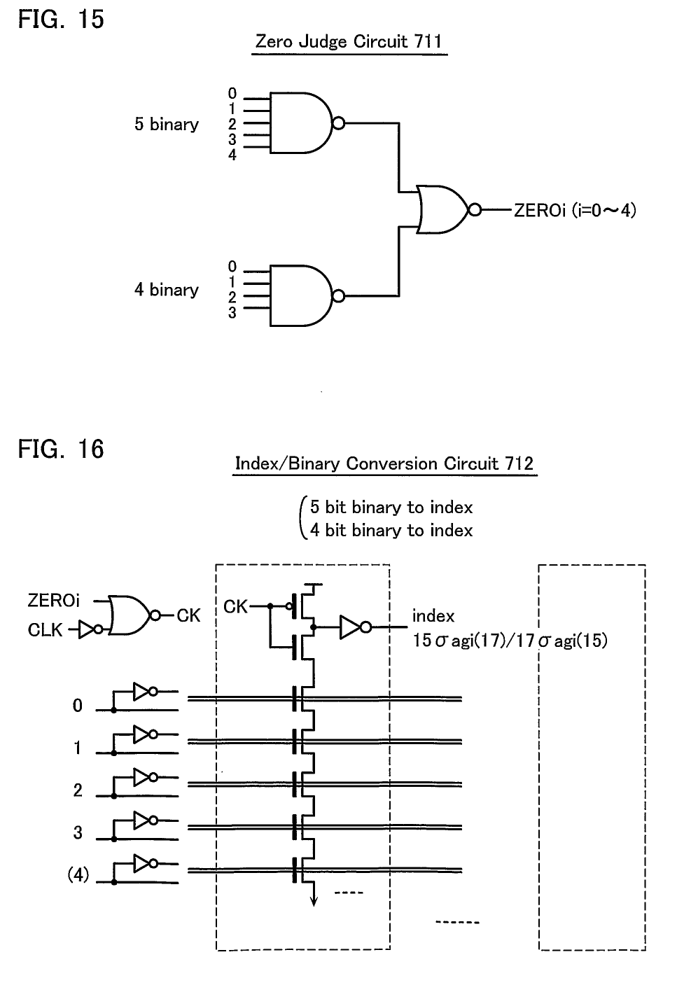

FIG. 15 shows a configuration of the zero judge circuit 711 in the input section of each adder system 701-705 shown in FIG. 7. If the binary representation is FF, then this circuit judges it as a zero element and outputs a signal ZEROi.

FIG. 16 shows a configuration of the binary/index conversion circuit 712 in the output section of each adder system 701-705 shown in FIG. 7. As the calculated result from the adder is an index in binary representation, this index can be utilized in a calculation between expression indexes at the next stage. For that purpose, this index is returned to the original index at this circuit. If the output ZEROi from the zero judge circuit 711 in the input section is “1”, then the clock CK can not rise and this circuit is kept inactive. In this case, independent of the calculated result from the adder, all expression index components are made “0”.

In FIGS. 15 and 16, i=0-4 correspond to the ag₀, agᵢ, ag₂, ag₃ and ag₄ adder systems 701, 702, 703, 704 and 705, respectively.

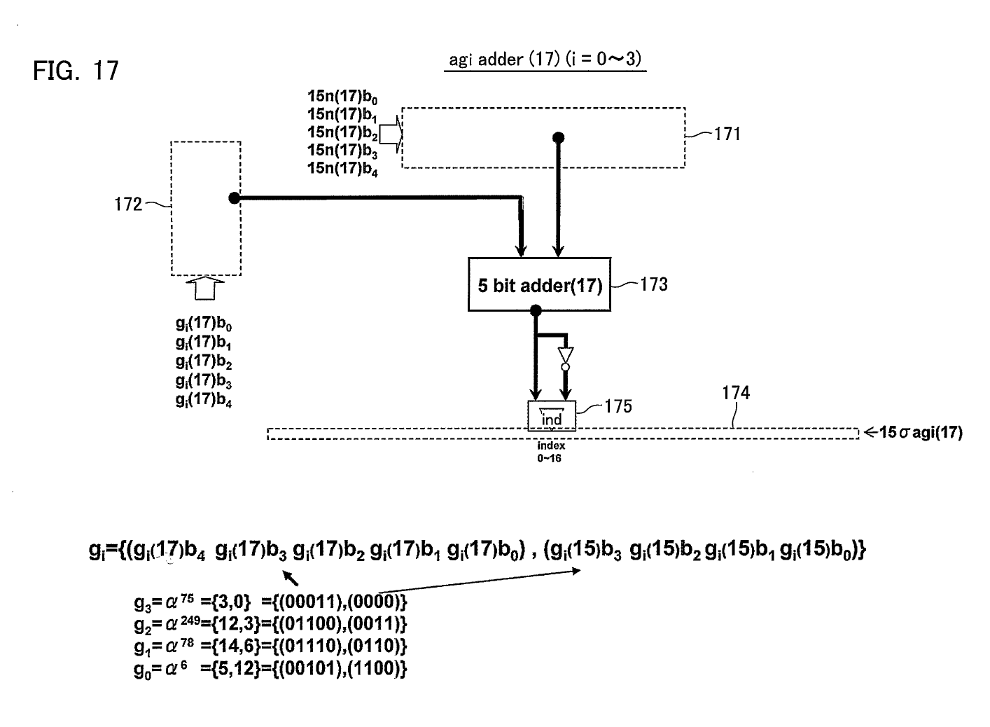

FIG. 17 shows circuitry of a partial agᵢ adder (17) operative to calculate a component modulo 17 of the adder (agᵢ adder) in the code computing system. Inputs 171, 172 are index/binary-converted outputs (5 binary outputs) 15n(17)b₀−15n(17)b₄ and binary representations gᵢ(17)b₀−gᵢ(17)b₄ of a component modulo 17 of an expression index of gᵢ, respectively. The gᵢ inputs are fixed inputs, which are first components of gᵢ shown in the associated figures.

These inputs 171, 172 are subjected to a union operation at a 5-bit adder (17) 173. An output 174 is decoded at a binary/index conversion circuit 175 into an expression index component 15σagi(17).

FIG. 18 shows circuitry of a partial agᵢ adder (15) operative to calculate a component modulo 15 of the adder (agᵢ adder) in the code computing system. Inputs 181, 182 are index/binary-converted outputs (4 binary outputs) 17n(15)b₀−17n(15)b₃ and binary representations gᵢ(15)b₀−gᵢ(15)b₃ of a component modulo 15 of an expression index of gᵢ, respectively. The gᵢ inputs are fixed inputs, which are second components of gᵢ shown in the associated figures.

These inputs 181, 182 are subjected to a union operation at a 4-bit adder (15) 183. An output 184 is decoded at a binary/index conversion circuit 185 into an expression index component 17σagi(15).

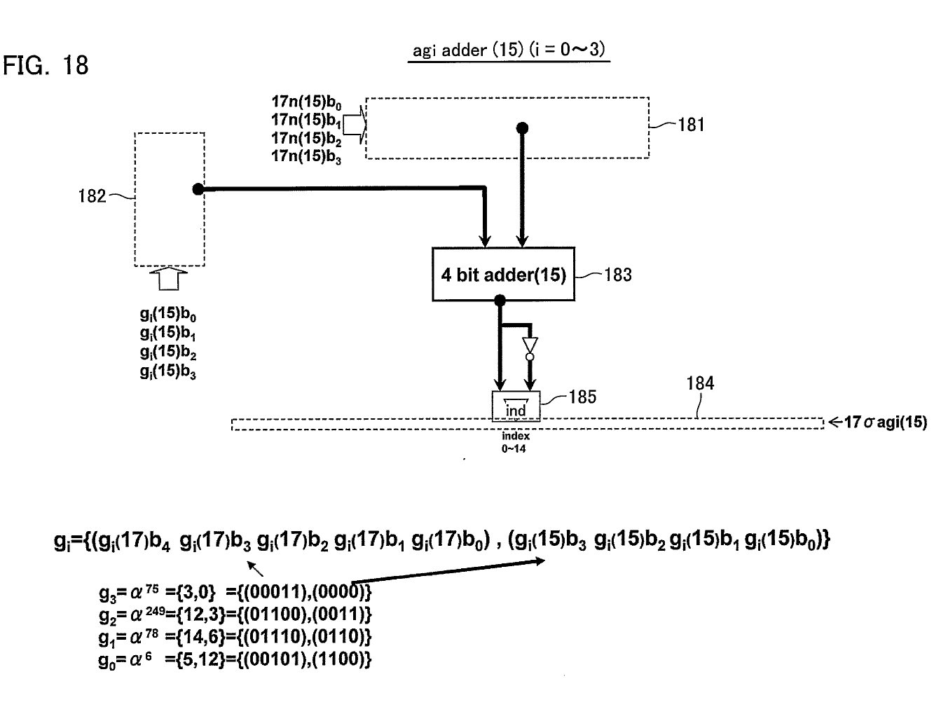

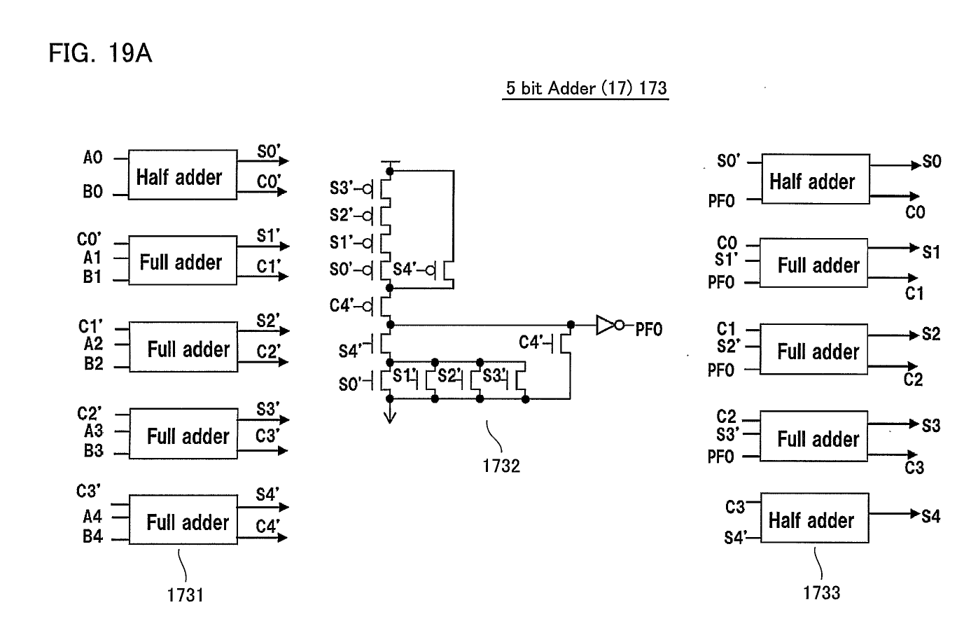

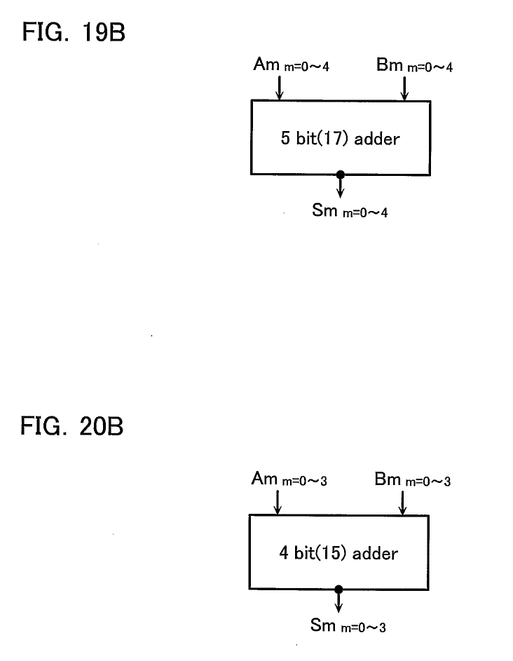

FIGS. 19A and 19B show a specific circuit example and circuit symbols of the 5-bit adder (17) 173 shown in FIG. 17. This is an adding circuit including half adders and full adders for deriving sums of digits of Am and Bm represented in binary numbers to derive a sum of residues modulo 17.

As shown, it comprises a first-stage adder unit 1731 of 5 bits, a carry correction circuit 1732 operative to carry a sum from the unit on detection of 17 or more in the sum, and a second-stage adder unit 1733 operative to add a complement number of 17 relative to 32, or 15 (=32-17), to the sum if the sum is equal to 17 or more, together with the carry correction circuit 1732.

The carry correction circuit 1732 generates a signal PF0 in accordance with the state of the output from the first-stage adder unit 1731. Specifically, it is configured to generate the signal PF0 (=“H”) on detection of “1” in the highest bit output S4′ and “1” in at least one of other bit outputs S0, S1′-S3′ from the first-stage adder unit 1731, that is, 17 or more in the sum.

The second-stage adder unit 1733 includes a logic integrated therein to add a complement number of 17, (01111), if the output from the first-stage adder unit 1731 is equal to 17 or more.

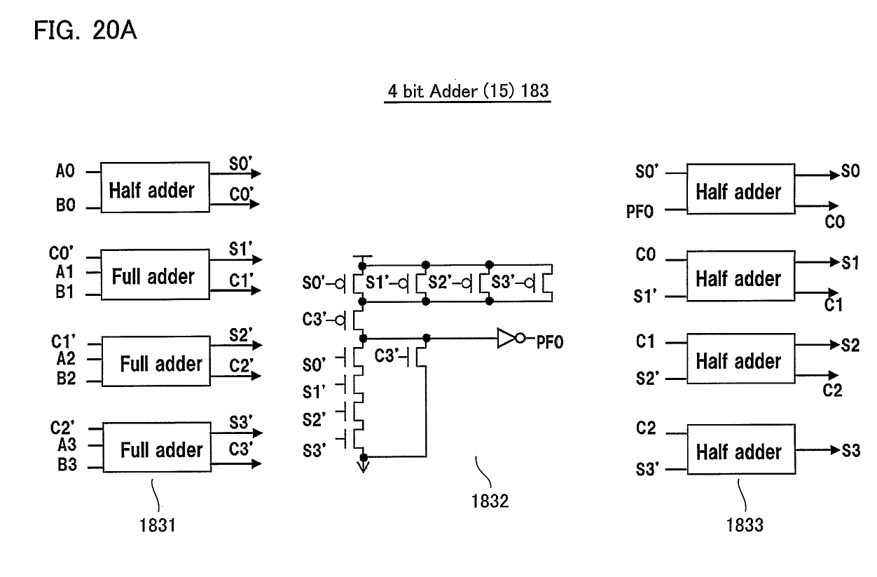

FIGS. 20A and 203 show a specific circuit example and circuit symbols of the 4-bit adder (15) 183 shown in FIG. 18. This is a 4-bit adding circuit operative to derive a sum of residues modulo 15. As shown, it comprises a first-stage adder unit 1831 of 4 bits, a carry correction circuit 1832 operative to carry a sum from the unit on detection of 15 or more in the sum, and a second-stage adder unit 1833 operative to add a complement number of 15 to the sum if the sum is equal to 15 or more, together with the carry correction circuit 1832.

The carry correction circuit 1832 generates a signal PF0 in accordance with the state of the output from the first-stage adder unit 1831.

The second-stage adder unit 1833 includes a logic integrated therein to add a complement number of 15, 1=(0001), if the output from the first-stage adder unit 1831 is equal to 15 or more.

These adders 173, 183 are configured to require no synchronization such as clocks and determine the output once the input is determined to reduce the load of timing control in the system.

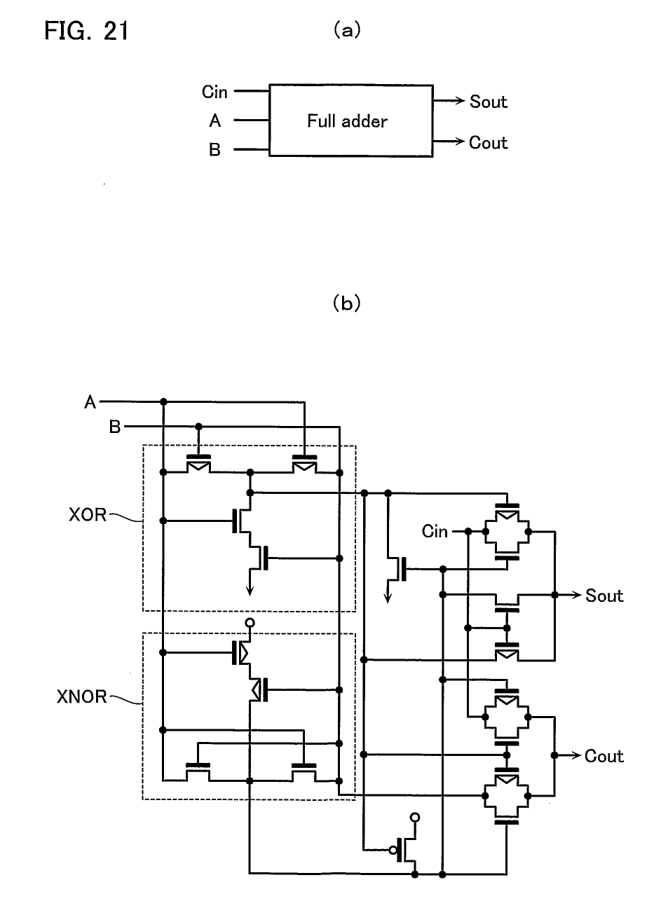

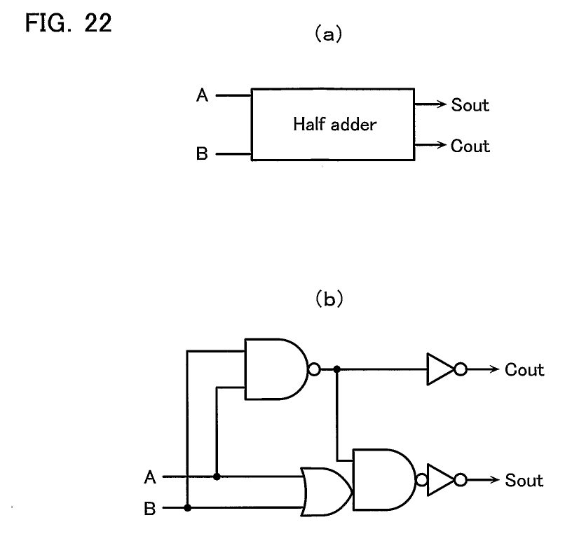

FIGS. 21(a), (b) and FIGS. 22(a), (b) show circuits symbols and specific circuits of a full adder and a half adder used in the above adders 173, 183 as basic units for an addition of binary numbers. The full adder logically operates bits A and B for addition in an XOR circuit and an XNOR circuit, and through a further logic with a carry signal Cin, outputs a sum Sout of A, B, Cin and a carry signal Cout. The half adder can be configured with general logic gates.

The adder outputs in the above data encoding system are used to calculate code data cᵢ=g₄aᵢ₋₄+g₃aᵢ₋₃+g₂aᵢ₋₂++g₀aᵢ. The calculation herein regards an element in the finite field as a residue polynomial pn(x) and derives a sum of coefficients modulo 2 thereof. The following description is given to a method of adding a residue polynomial pn(x) expressed with an expression index to derive coefficients thereof.

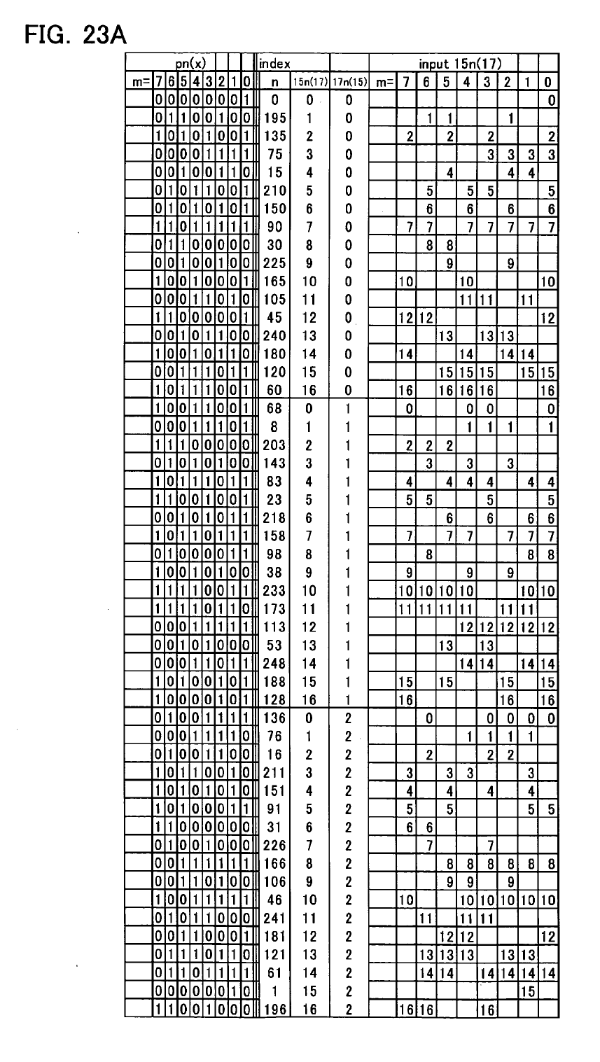

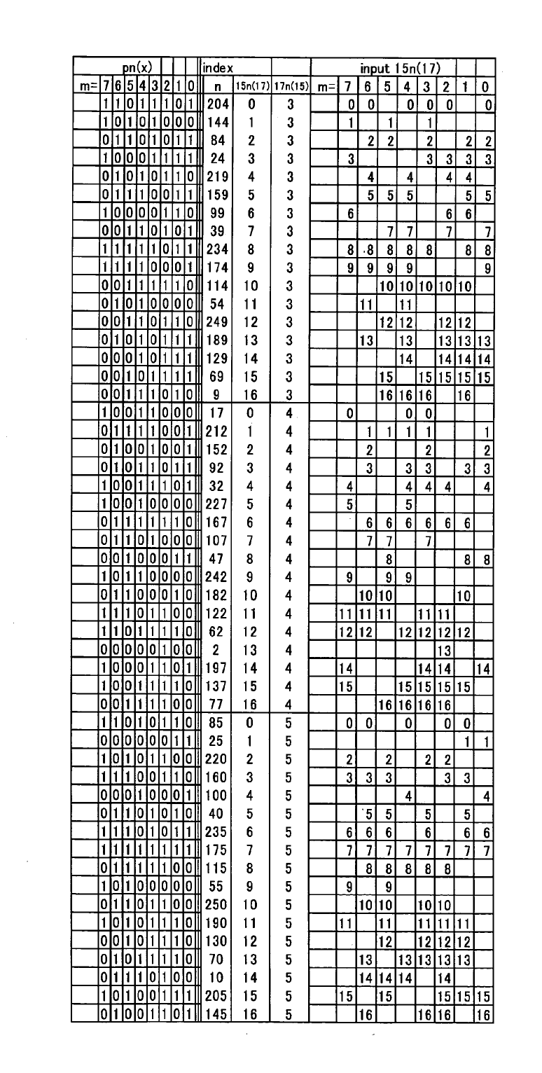

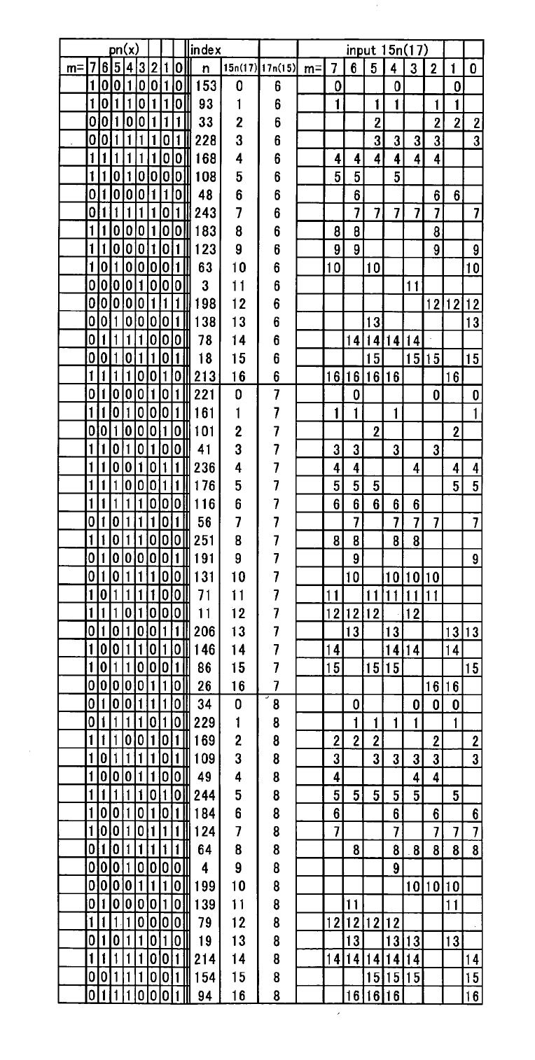

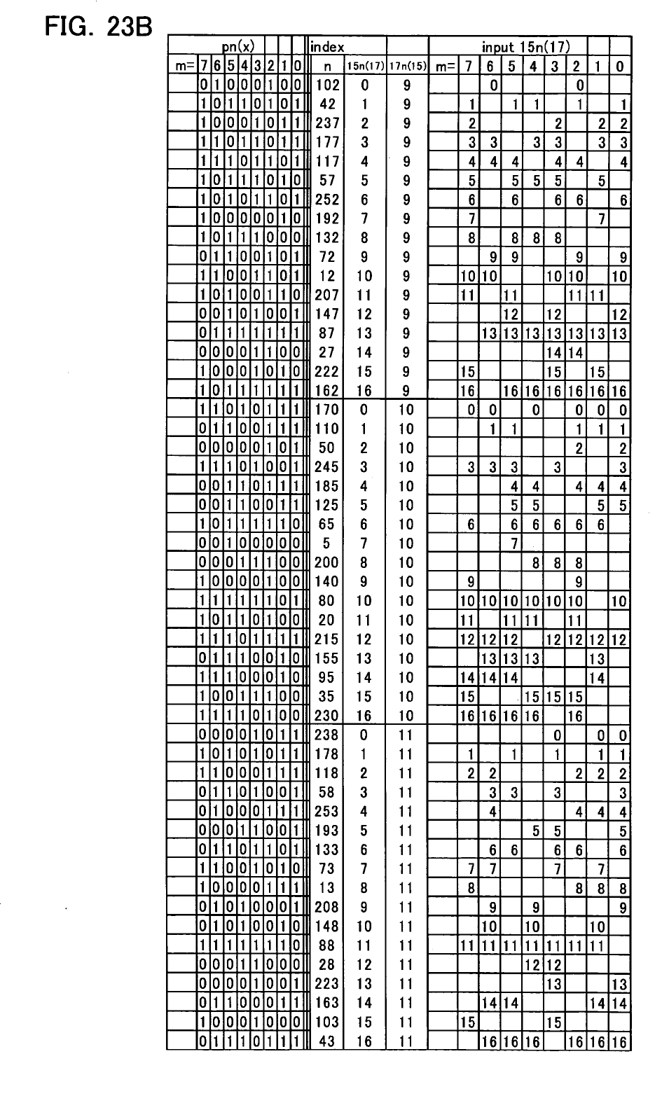

FIGS. 23A and 23B are tables showing relations among an m-th order coefficient of the residue polynomial pn(x), an index n of an element αⁿ, and an expression index {15n(17), 17n(15)} grouped under values 0-14 of an expression index 17n(15). Expression index components 15n(17) in each group are arranged from 0 to 16 in ascending order.

The ‘input 15n(17)’ section shows values of 15n(17) in the case of a coefficient 1 because the part with a coefficient 0 does not contribute to the sum of coefficients of pn(x). As pn(x) corresponds to the expression index {15n(17), 17n(15)} in a one-to-one relation, the contribution of an m-th order coefficient of the polynomial pn(x) to the sum of coefficients can be decoded from the table when a certain expression index is given.

Namely, with respect to each m-th order, under one transistor having a gate input of one expression index component 17n(15), a transistor having a gate input of 15n(17) with an m-th order coefficient 1 of pn(x) belonging to this 17n(15) is NOR-connected thereto. In addition, if the expression index hits this group, a current path can be formed. Such the connection is made on each component 17n(15) from the table in the figure to discharge a common node.

This common node indicates the inversion of an m-th order coefficient of pn(x) with respect to one expression index. For example, m=7 makes the following NOR connections from the table.

(1) NOR connection of 15n(17)=2, 7, 10, 12, 14, 16 under 17n(15)=0,
(2) NOR connection of 15n(17)=0, 2, 4, 5, 7, 9, 10, 11, 15; 16 under 17n(15)=1,
(3) NOR connection of 15n(17)=3, 4, 5, 6, 10, 16 under 17n(15)=2,
(4) NOR connection of 15n(17)=0, 1, 3, 6, 8, 9 under 17n(15)=3,
(5) NOR connection of 15n(17)=0, 4, 5, 9, 11, 12, 14, 15 under 17n(15)=4,
(6) NOR connection of 15n(17)=0, 2, 3, 6, 7, 9, 11, 15 under 17n(15)=5,
(7) NOR connection of 15n(17)=0, 1, 4, 5, 8, 9, 10, 16 under 17n(15)=6,
(8) NOR connection of 15n(17)=1, 3, 4, 5, 6, 8, 11, 12, 14, 15 under 17n(15)=7,
(9) NOR connection of 15n(17)=2, 3, 4, 5, 6, 7, 12, 14 under 17n(15)=8,
(10) NOR connection of 15n(17)=1, 2, 3, 4, 5, 6, 7, 8, 10, 11, 15, 16 under 17n(15)=9,
(11) NOR connection of 15n(17)=0, 3, 6, 9, 10, 11, 12, 14, 15, 16 under 17n(15)=10,
(12) NOR connection of 15n(17)=1, 2, 7, 8, 11, 15 under 17n(15)=11,
(13) NOR connection of 15n(17)=1, 8, 10, 11, 12, 14, 15, 16 under 17n(15)=12,
(14) NOR connection of 15n(17)=0, 1, 2, 4, 5, 7, 8, 9, 12, 14 under 17n(15)=13, and
(15) NOR connection of 15n(17)=0, 1, 2, 3, 6, 7, 8, 9, 10, 12, 14, 16 under 17n(15)=14.

The coefficient 1 is decoded depending on the fact that the common node can be discharged through these NOR connections or not. For example, if {15n(17) 17n(15)}={11, 4}, then the node is discharged through the NOR connection of 15n(17)=0, 4, 5, 9, 11, 12, 14, 15 under 17n(15)=4, and the coefficient of the m=7th order is decoded as 1.

The zero element “00000000” of pn(x) is associated with 15n(17)=16, 17n(15)=15. The fact that all the coefficients of pn(x) are “0” corresponds to that an associated decoding can not be found in these tables.

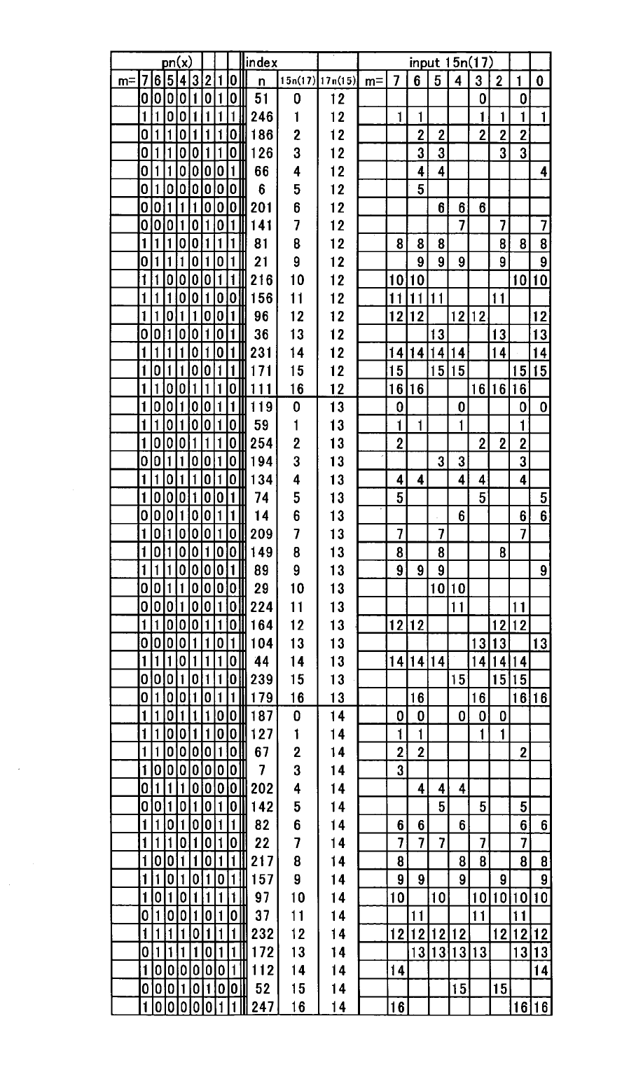

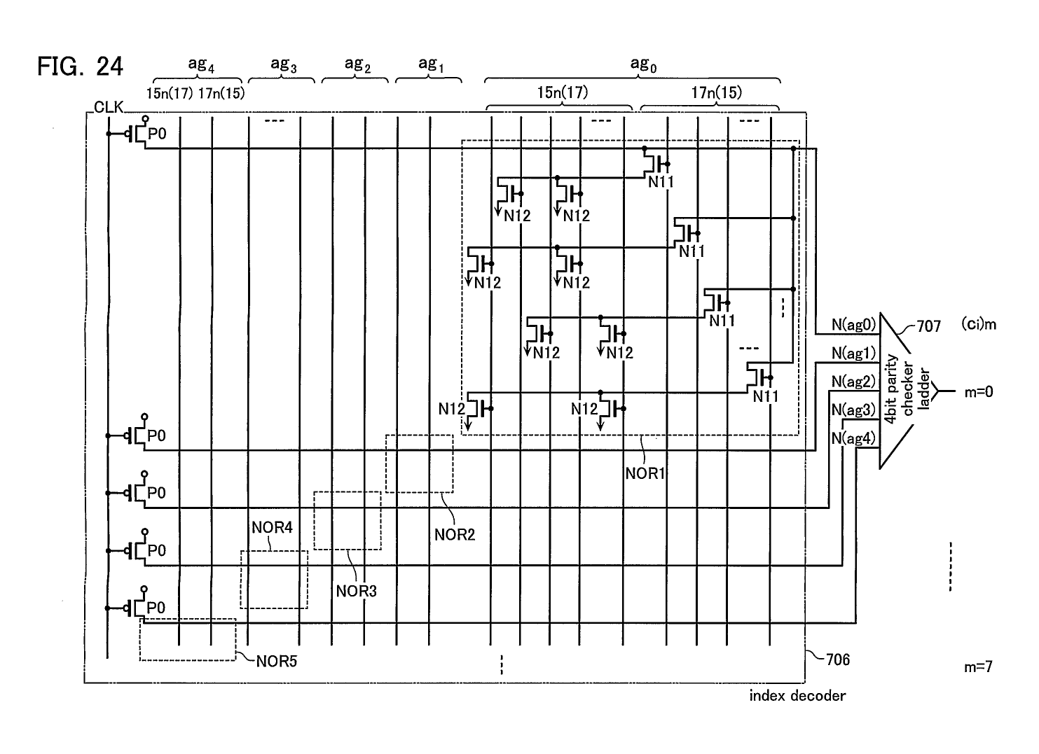

FIG. 24 shows a configuration of the input index decoder 706 in the 4-bit parity checker/ladder 707 operative to calculate cᵢ=g₄ₐᵢ₋₄g₃ₐᵢ₋₃g₂ₐᵢ₋₂g₁ₐᵢ₋₁g₀ₐᵢ shown in FIG. 7 using the above-described tables of FIGS. 23A and 23B.

Input signals are expression indexes of output elements from the adders ag₄, ag₃, ag₂, ag₁, ag₀. There are common nodes N(ag₄) N(ag₃), N(ag₂), N(ag₁), N(ag₀) corresponding to m-th order coefficients at these elements. These common nodes are precharged to Vdd through PMOS transistors PO driven by the signal CLK.

For the common nodes of the elements, NMOS transistors N11 having gates driven by the expression index component 17n(15), and NMOS transistors N12 having gates driven by the expression index component 15n(17) are provided to configure NOR circuits NOR1, NOR2, NOR3, NOR4, NOR5. An arrangement of the NMOS transistors N11, N12 can be determined from the tables in FIGS. 23A and 23B.

The 5 common nodes are subjected to parity check at the 4-bit parity checker/ladder 707 to obtain an m-th order coefficient (cᵢ)ₘ of cᵢ.

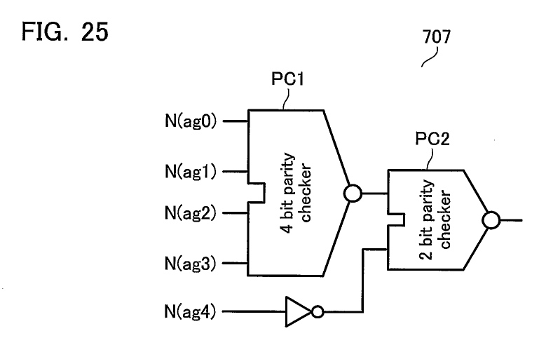

FIG. 25 shows a configuration example of the 5-input, 4-bit parity checker/ladder 707. The 4 inputs N(ag₀)−N(ag₃) are fed to a 4-bit parity checker PC1 and the output therefrom and the inverted input of N(ag₄) are fed to a 2-bit parity checker PC2.

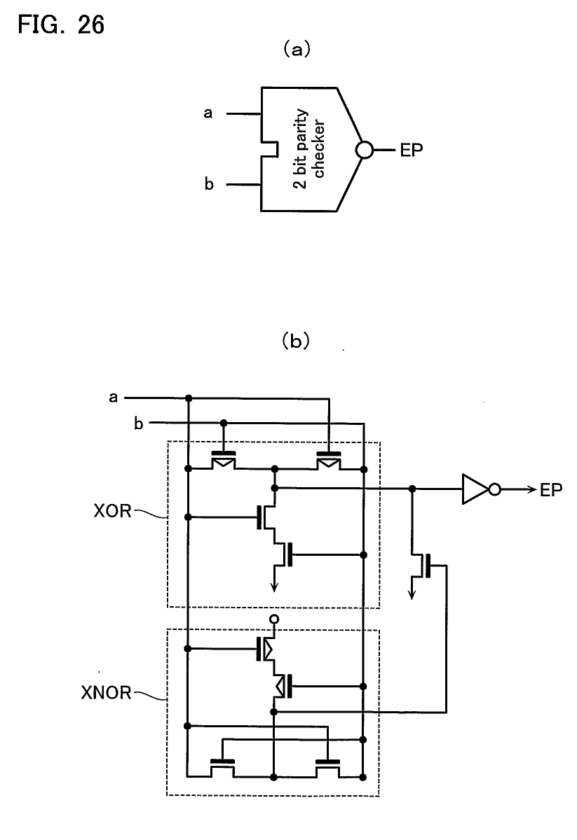

FIGS. 26(a), (b) show a circuit symbol and a specific circuit example of the 2-bit parity checker PC2. It logically operates 2 bits a and b at an XOR section and an XNOR section to output EP=“1” in the case of even parity, that is, if the number of “1”s in the input terminals is even.

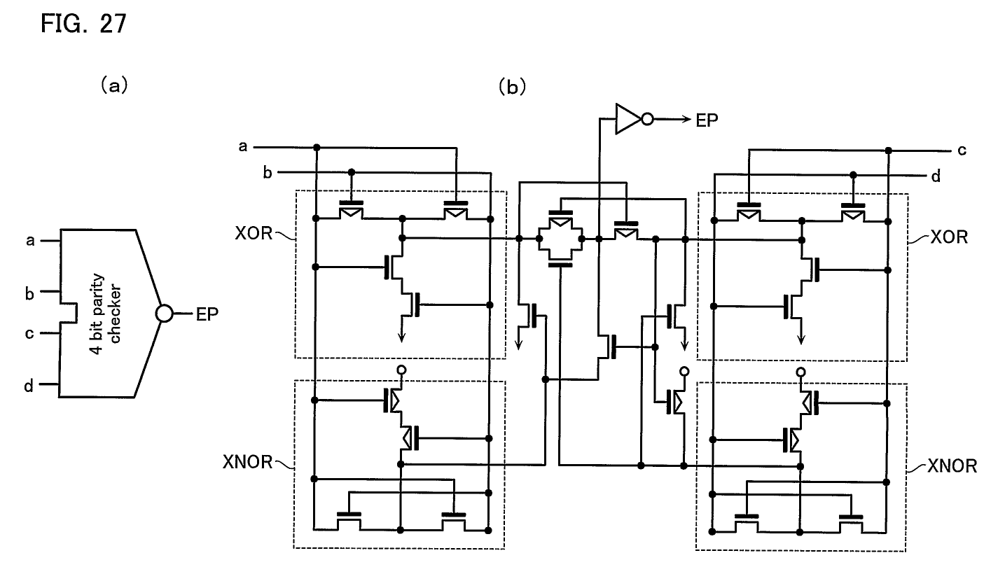

FIGS. 27(a), (b) show a circuit symbol and a specific circuit example of the 4-bit parity checker PC1. It receives 4 bits a, b, c and d and logically operates outputs from components or 2-bit parity checkers to output EP=“1” if even “1”s are present in the input terminals.

### (Timing Control of Data Read and Error Correction)

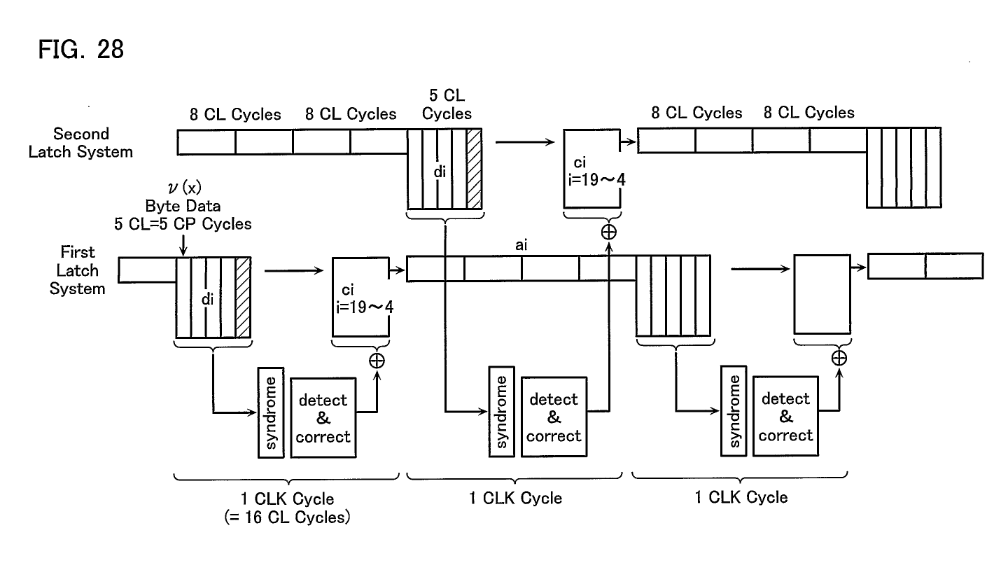

Next, a relation associated with timing synchronization in reading data out of the memory is described with reference to FIG. 28. The same names may also be used for the clock names and so forth that have been used until the symbol data is written in the memory but it should be noted that they are not related to the same signals.

As storage places for data read out of the memory core, data registers of 20 bytes (data latches) are prepared in 2 systems. These first and second data latch systems are interleaved in use to output data without any break.

There are 2 types of clocks. One is used for data transfer and includes a clock CL for providing an output of data as well as a clock CP having the same period as the clock CL but generated intermittently in a set at every 5 cycles for reading data out of the memory. Another is a clock CLK for driving the ECC system in which 1 CLK cycle=16 CL cycles.

Data dᵢ (i=19-0) of 20 bytes is read out of the memory on a 4-byte basis in 5 CP cycles and held in the first data latch to calculate a syndrome. On the basis of this syndrome, error search and symbol error calculation are executed and code data cᵢ (i=19-4) or corrected dᵢ is used to correct the output from the latch. In this case, c₃-c₀ are not used in information data correction. Thus, 1 CLK cycle of ECC is finished.

Next, the code cᵢ obtained at the latch output is used to sequentially calculate information data aᵢ (i=15-0) in synchronization with the clock CL and output them. In addition, the next data of 20 bytes is read out into the second data latch. Namely, the first and second latch systems operate in an interleaved manner such that one provides an output of information data aᵢ while the other simultaneously latches the next read data for syndrome calculation, and error checking and correction.

Next, a system for executing error location search and error correction to the data read out of the memory is described below specifically.

### (Syndrome Arithmetic Unit)

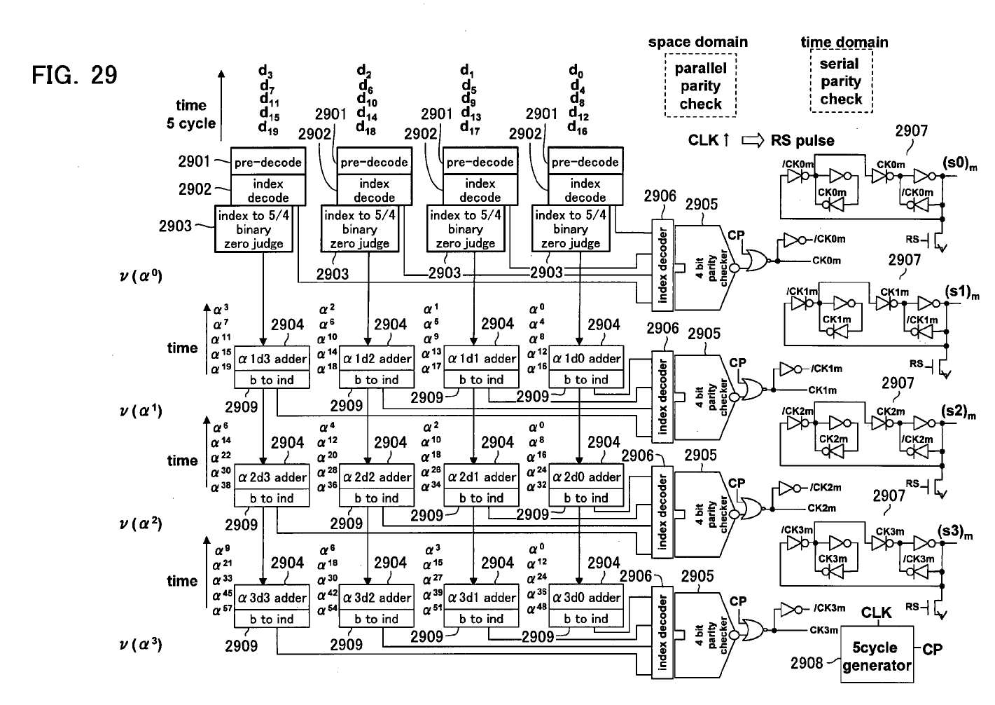

First, FIG. 29 shows an overview of a syndrome computing system (syndrome arithmetic unit 21 in FIG. 3). Coefficients of a 19th order polynomial read out of the memory, or pieces of symbol data, are denoted with d₁₉, d₁₈, . . . , d₂, d₁, d₀. These are multiplied by an appropriate power of α and summed to obtain syndromes s0, s1, s2, s3 in this system. This syndrome computing system uses the main clock CLK as a trigger for error search/correction to generate a shorter period clock CP in 5 cycles from a clock generator 2908 and executes calculations in synchronization with the clock CP.

Input sections receive data of each 4 bytes d₁₉-d₁₆, d₁₅-d₁₂, d₁₁-d₉, d₇-d₄, d₃-d₀ in 5 cycles, which represent elements in GF(256) as coefficients of pn(x). The input sections include pre-decoders 2901, index decoders 2902 and index/binary conversion circuits 2903. These input circuit sections convert the data into expression indexes in binary representation. They also judge a zero element.

Based on the expression indexes in binary representation, 4 syndromes are calculated simultaneously in 5 cycles. Namely, data of 4 bytes is simultaneously fed into 12 expression index adder circuits 2904. Of course, for reduced circuitry, only 3 adders may be used to execute a calculation on a byte basis in 20 cycles.

Corresponding to 4 syndromes, 4 4-bit parity checkers 2905 are provided to derive a sum of simultaneously processed 4 GF(256)s each. This is provided for parallel parity check in space domain. The outputs from the parity checkers 2905 in 5 cycles are subjected to parity check at “1”-counter circuits 2907, which make an alternate shift between “1” and “0” when the 4-bit parity checkers 2905 output “1”. This is equivalent to serial parity check in time domain. A calculation on a byte basis in 20 cycles requires no parallel parity check in space domain.

The calculation of the uppermost syndrome s0 is a multiplication by the 0-th power of α, that is, 1, and accordingly requires no adder circuit substantially. Thus, the expression index is directly fed into the 4-bit parity checker 2905.

The calculations of the syndrome s1 and lower require the adder circuits 2904. The adder circuits 2904 for syndrome si calculations (i=1-3) receive expression indexes in binary representation of data and also receive expression indexes in binary representation of indexes of powers of a required for calculations to derive a sum thereof. The results are fed into the 4-bit parity checkers 2905 as expression indexes. If the input data is a zero element, then output expression indexes are all made “0” independent of the calculated result from the adder.

The outputs from the 4-bit parity checkers 2905 are used as signals for driving the counter circuits 2907 at the next stage in synchronization with the clock CP. The counter circuits 2907 newly start counting “1” when they are reset by a reset pulse RS generated at the rise of the clock CLK.

The 4-bit parity checkers 2905 and the counter circuits 2907 are provided as many as 8, or m=0-7, for associated syndromes because the counts of pn(x) represent elements. This allows each syndrome to be output as pn(x) as an element in GF(256).

FIG. 30 shows a configuration example of the pre-decoder 2901 at the input section in the computing system of FIG. 29. This decoder generates signals in accordance with the above association table between coefficients of pn(x) and Ai, Bi, Ci, Di.

FIG. 31 shows a configuration example of the index decoder 2902 at the same input section. This decoder receives Ak, Bk, Ck, Dk, which are NAND-connected in accordance with the table, grouped and NOR-connected to generate components of expression indexes in synchronization with the clock CP.

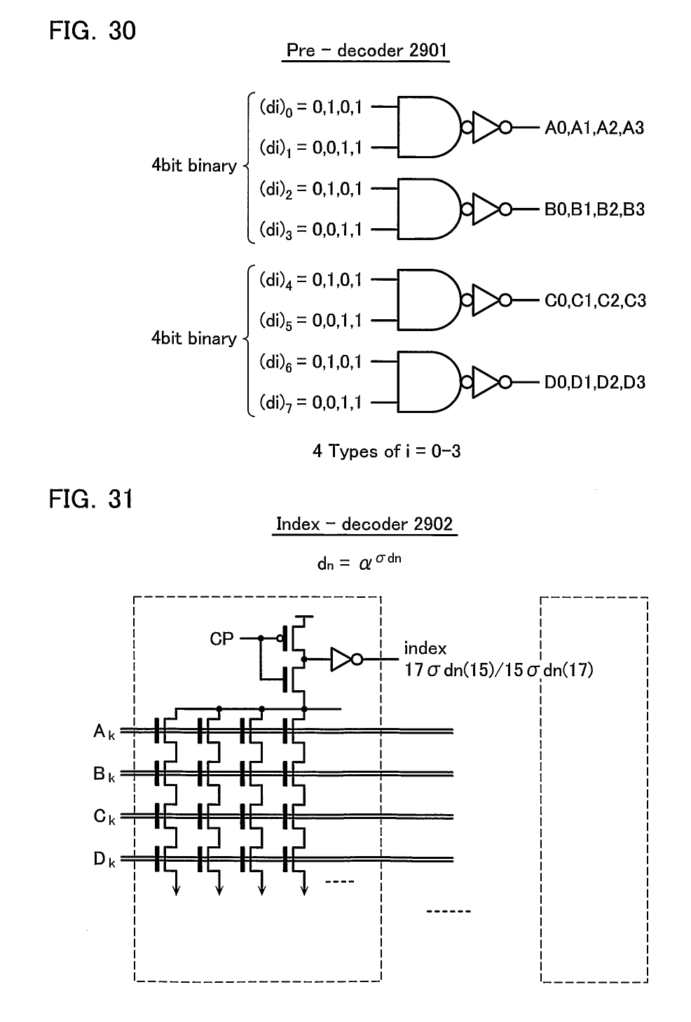

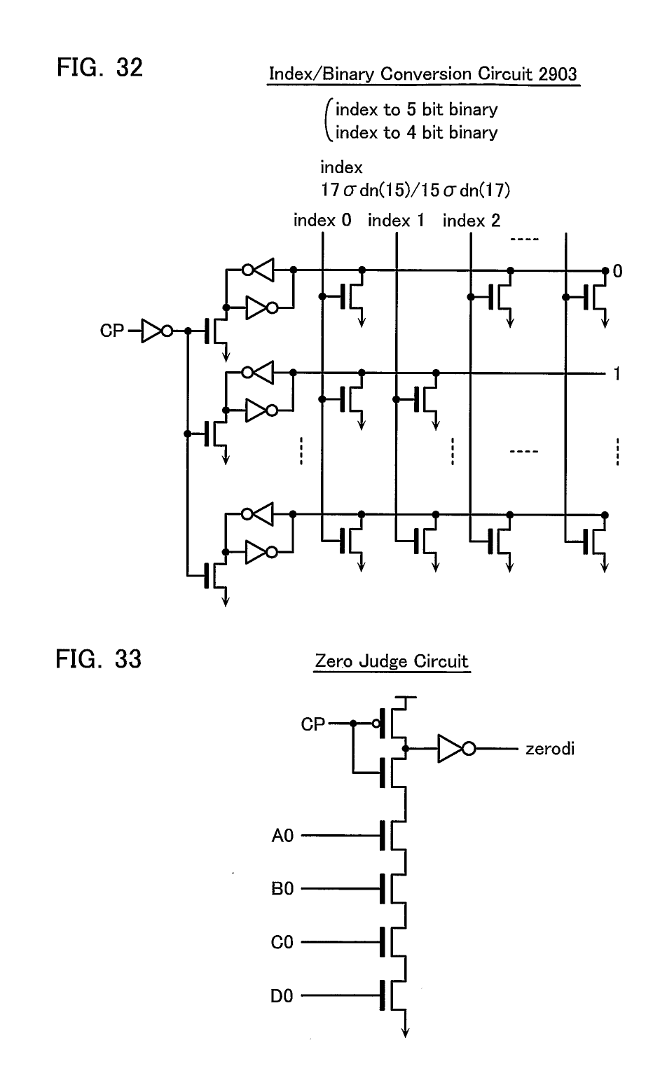

FIG. 32 shows a configuration example of the index/binary conversion circuit 2903 at the same input section. This circuit converts the index into a 5-binary or 4-binary representation in synchronization with the clock CP. Namely, an index component modulo 17 is converted into binary data of 5 bits, and an index component modulo 15 into binary data of 4 bits.

FIG. 33 shows a configuration of a zero judge circuit attached to the index/binary conversion circuit 2903. If data is a zero element, then A0, B0, C0, D0 are “H”. Accordingly, their NAND generates zerodi=“H”. In the case of the zero element, as the index decoder circuit has no associated decoding, the index becomes all “0”.

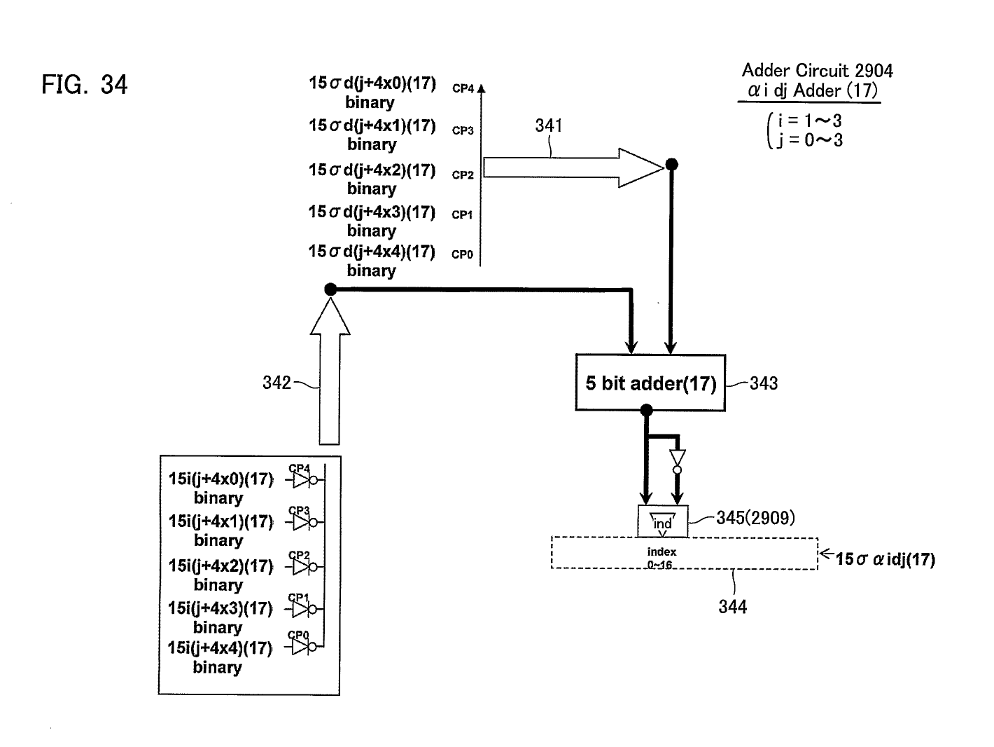

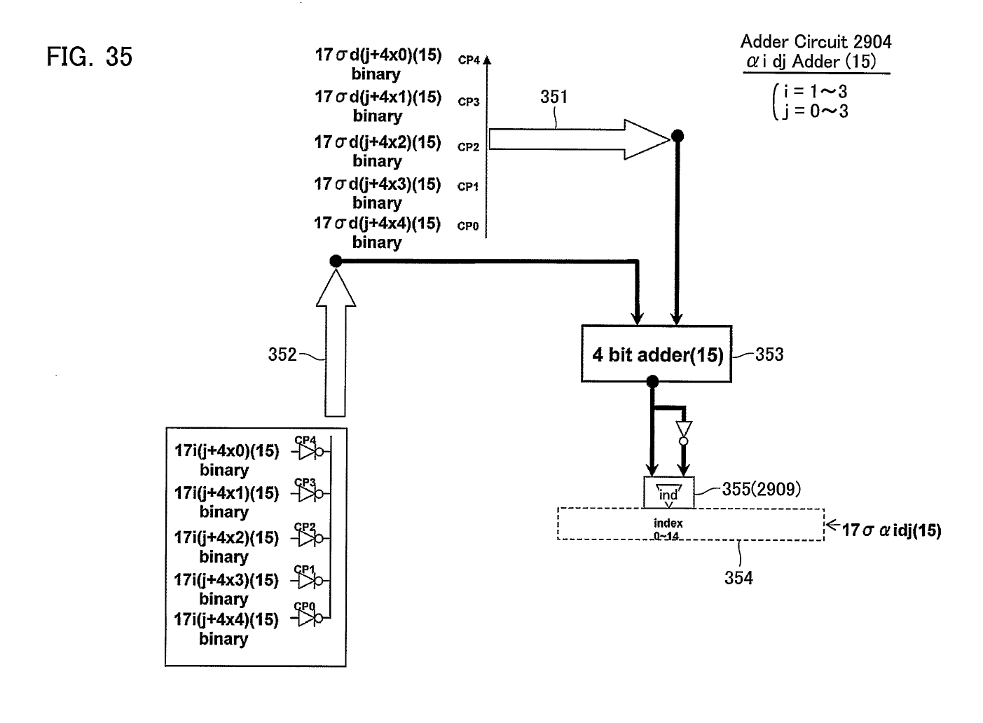

FIGS. 34 and 35 show configuration examples of the adder circuit 2904 in the syndrome computing system.

FIG. 34 shows an αidj adder (17) or an adder circuit for an expression index modulo 17 for use in calculation of ν(α¹) from the input of data with k≡j mod 4 with respect to a k-th order coefficient dk of data ν(x) read out of the memory. In this case, j is equal to 0-3, and 4 in total, and i is equal to 1-3, and 3 in total. Accordingly, the adders of this type are provided as many as 12.

One data input 341 includes a binary representation of 15σd(j+4×4)(17), a binary representation of 15σd(j+4×3)(17), a binary representation of 15σd(j+4×2)(17), a binary representation of 15σd(j+4×1)(17), and a binary representation of 15σd(j+4×0)(17), which are input in synchronization with respective cycles CP0-CP4 of the clock CP in 5 cycles.

Another data input 342 includes a binary representation of 15i(j+4×4)(17), a binary representation of 15i(j+4×3)(17), a binary representation of 15i(j+4×2)(17), a binary representation of 15i(j+4×1)(17), and a binary representation of 15i(j+4×0)(17), which are input as sequentially switched with the clocks CP0-CP4. The circuitry of this input section is described later in detail.

These pieces of input data are received at a 5-bit adder (17) 343 to calculate a sum thereof. An output 344 is converted into an expression index component 15σαidj (17) at a binary/index conversion circuit 345 (that is, 2909) at the output section.

FIG. 35 shows an αidj adder (15) or an adder circuit for an expression index component modulo 15 for use in calculation of ν(αⁱ) from the input of data with k≡j mod 4 with respect to a k-th order coefficient dk of data ν(x) read out of the memory. In this case, j is equal to 0-3, and 4 in total, and i is equal to 1-3, and 3 in total. Accordingly, the adders of this type are also provided as many as 12.

One data input 351 includes a binary representation of 17σd(j+4×4)(15), a binary representation of 17σd(j+4×3)(15), a binary representation of 17σd(j+4×2)(15), a binary representation of 17σd(j+4×1)(15), and a binary representation of 17σd(j+4×0)(15), which are input in synchronization with respective cycles CP0-CP4 of the clock CP in 5 cycles.

Another data input 352 includes a binary representation of 17i(j+4×4)(15), a binary representation of 17i(j+4×3)(15), a binary representation of 17i(j+4×2)(15), a binary representation of 17i(j+4×1)(15), and a binary representation of 17i(j+4×0)(15), which are input as sequentially switched with the clocks CP0-CP4. The circuitry of this input section is described later in detail.

These pieces of input data are received at a 4-bit adder (15) 353 to calculate a sum thereof. An output 354 is converted into an expression index component 17σαidj (15) at a binary/index conversion circuit 355 (that is, 2909) at the output section.

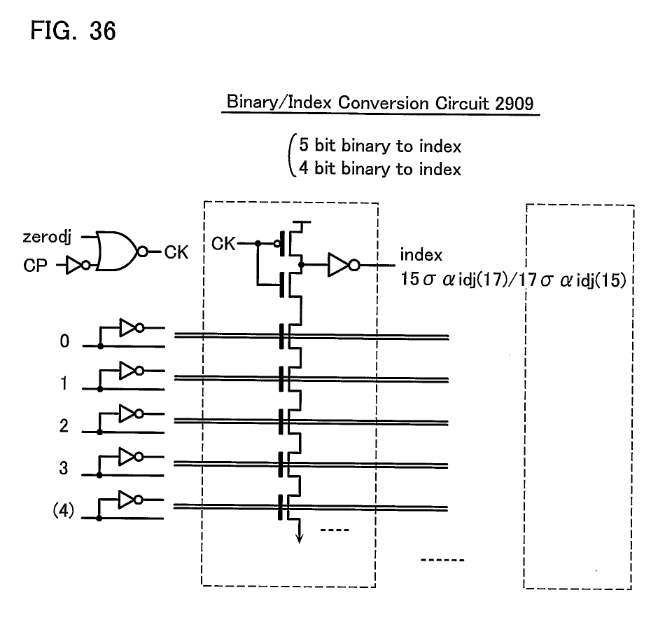

FIG. 36 shows a decoder circuit, which serves as the binary/index conversion circuit 345, 355 (that is, 2909 in FIG. 29) for use in the adder output section of FIG. 34 or FIG. 35. The calculated result from the adder is an index in binary representation and accordingly it must be converted into an index signal available in a calculation between expression indexes at the next stage.

A node precharged with the clock CK synchronized with the clock CP is discharged with a binary representation-decoded NAND logic to provide an index. If the data input to the adder is a zero element, the signal zerodi keeps the clock CK at “L” and the index becomes all “0”.

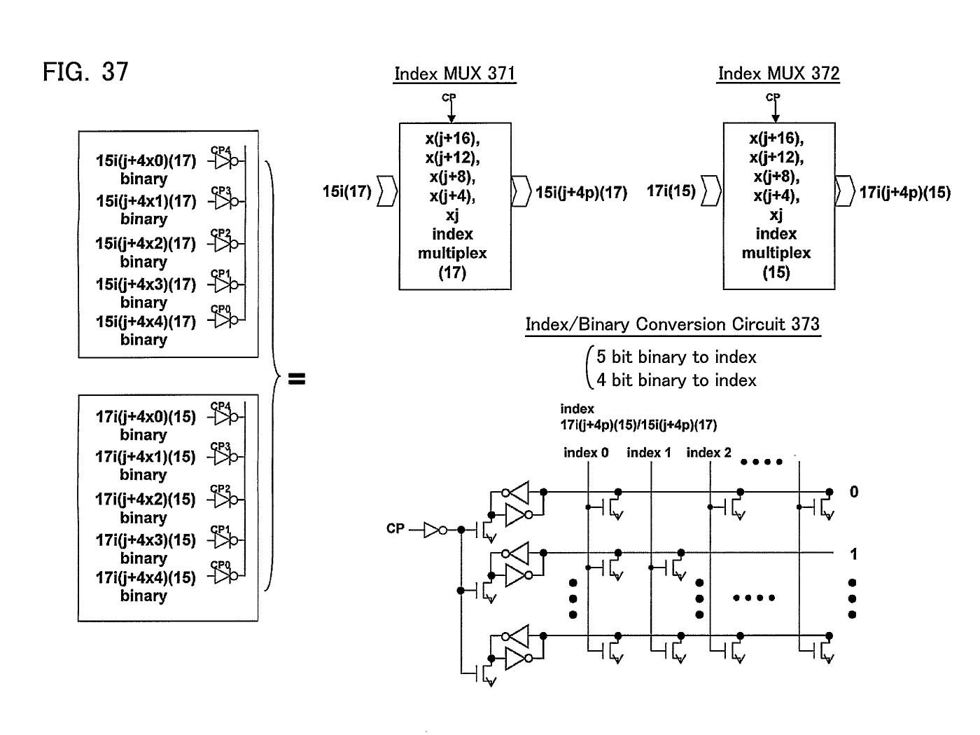

FIG. 37 shows a configuration of the index input section of a in the above-described αidj adder. As for an element in GF(256) represented by an index of α, an element of the power can be obtained through a conversion of an expression index component as described later. With the use of this fact, connections of the index may be switched at every cycle of the clock CP to obtain an index as a substituted result on the term x^{m} on substitution of αⁱ into ν(x).

Specifically, the αidj adder requires an expression index component of an index i (j+16) in the first cycle CP0 of the clock CP, an expression index component of an index i(j+12) in CP1, an expression index component of an index i(j+8) in CP2, an expression index component of an index i(j+4) in CP3, and an expression index component of an index ij in CP4. These wiring connections are switched at index MUXs 371, 372 in synchronization with the clock CP.

The expression index components 15i(j+4p)(17) and 17i(j+4p)(15) (where p=0-4) output from these index MUXs are converted into binary number representations of the index components at an index/binary conversion circuit 373 and supplied to the adders.

Next, with respect to multiples of n, how to convert expression indexes and residues thereof is described. An expression index corresponding to an index n of αⁿ is represented by {15n(17), 17n(15)} as a pair of expression indexes mod 17 and mod 15. The present system includes the following three cases (a), (b), (c) with 15n(17)=σ₁₇, 17n(15)=σ₁₅.

(a) The expression indexes α₁₇, σ₁₅ are used to derive therefrom an expression index of a multiple mn of a number m mutually prime to a modulus 15. As 17 is a prime number, it is mutually prime to any m.

As m is mutually prime to the modulus, both sides of a congruence can be divided by m without changing the modulus even if n is multiplied by m. Therefore, the residues themselves do not vary and the configurations of elements contained therein remain unchanged. An expression index is multiplied by m and changed from {σ₁₇(mod 17), σ₁₅(mod 15)} to {mσ₁₇(mod 17), mσ₁₅(mod 15)}.

The modulus 17 is a prime number and accordingly has no factor while the modulus 15 has 3 and 5 as factors. In this case, σ₁₅ is used to derive therefrom an expression index of the multiple mn of the number m which is a factor of the modulus 15.

If mn and mn′ belong to the same residues, then 17m(n−n′)≡(mod 15) is established. As m is a factor of 15, accordingly, on division of both sides of the congruence, the modulus is also divided by the absolute value thereof as in n≡n′(mod 15/|m|). Therefore, elements of residues having a difference of 15/|m| therebetween are regarded as elements of the same residues. Thus, previously separated residues are combined together into new larger residues. The expression indexes are converted through these combinations into those having an identical expression index.

For example, if m=−3, then n≡n′(mod 5), and three residues modulo 15 are combined together to group 15 residues into 5 residues.

The conversion calculation of the expression index itself is similar to the case (a).

(c) The expression index of n is used to derive therefrom an expression index of n/m, which is a number m mutually prime to the modulo 15 divided by m.

As m is mutually prime to the modulus, both sides of a congruence can be multiplied by m even if n is multiplied by 1/m. Therefore, the residues themselves do not vary and the configurations of elements contained therein remain unchanged. The expression index is converted into a number having a factor of m by adding an appropriate multiple of the modulus to an expression index to be converted (this is possible because the modulus and m are mutually prime), and obtained as a residue of the modulus by dividing the number by m.

For example, when m=2, if σ₁₇ is an even number, then there in an integer b₁₇ that satisfies b₁₇=σ₁₇/2, and if it is an odd number, then there in an integer b₁₇ that satisfies b₁₇=(σ₁₇+17)/2. Similarly, if σ₁₅ is an even number, then there in an integer b₁₅ that satisfies b₁₅=σ₁₅/2, and if it is an odd number, then there in an integer b₁₇ that satisfies b₁₅=(σ₁₅+15)/2. Therefore, an expression index of {b₁₇(mod 17), b₁₅(mod 15)} can be obtained.

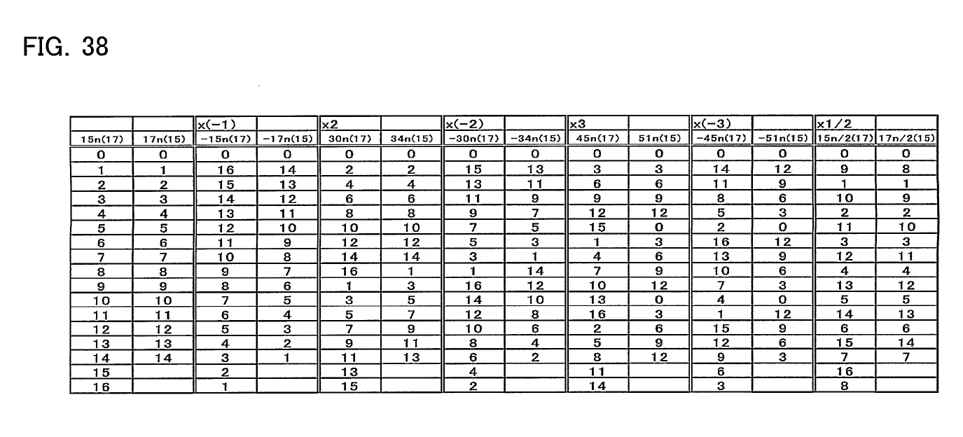

FIG. 38 shows an example of relations between expression indexes, in which values taken by component indexes of an expression index of n, that is, {15n(17), 17n(15)}, after conversion of n multiplied by m are listed in a table of columns×m(m=−1, 2, −2, 3, −3, 1/2). With combinations of the conversions, all the expression indexes required in the present system can be obtained.

For example, an expression index {3, 8} is converted by −3/2 times. The first expression index component is 15n(17)=3. Accordingly, from the column of x(−3), it is turned into 8, which is newly regarded as 15n(17) and turned into 4 from the column of x1/2.

The second expression index component is 17n(15)=8. Accordingly, from the column of x(−3), it is turned into 6, which is newly regarded as 17n(15) and turned into 3 from the column of x1/2. Thus, {3, 8} is converted by x(−3/2) into {4, 3}.

This conversion process reaches the same result if it applies x1/2 first and then x(−3).

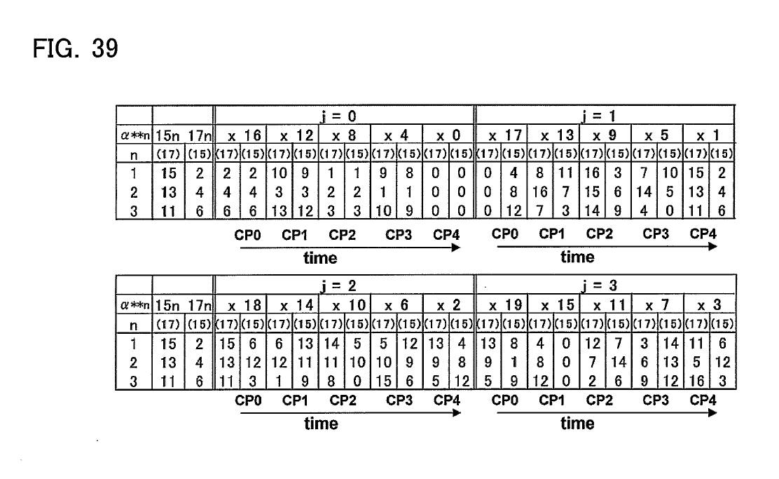

FIG. 39 shows α¹, α², α³ substituted into ν(x) as relations between components of the expression index of αⁿ used in the αidj adder, and values of expression indexes of x(j+4p) (where p=4, 3, 2, 1, 0) used in the adders of j=0, 1, 2, 3, which are listed in a table. In accordance with this table, index signals are switched at the above index MUX in synchronization with the clock CP.

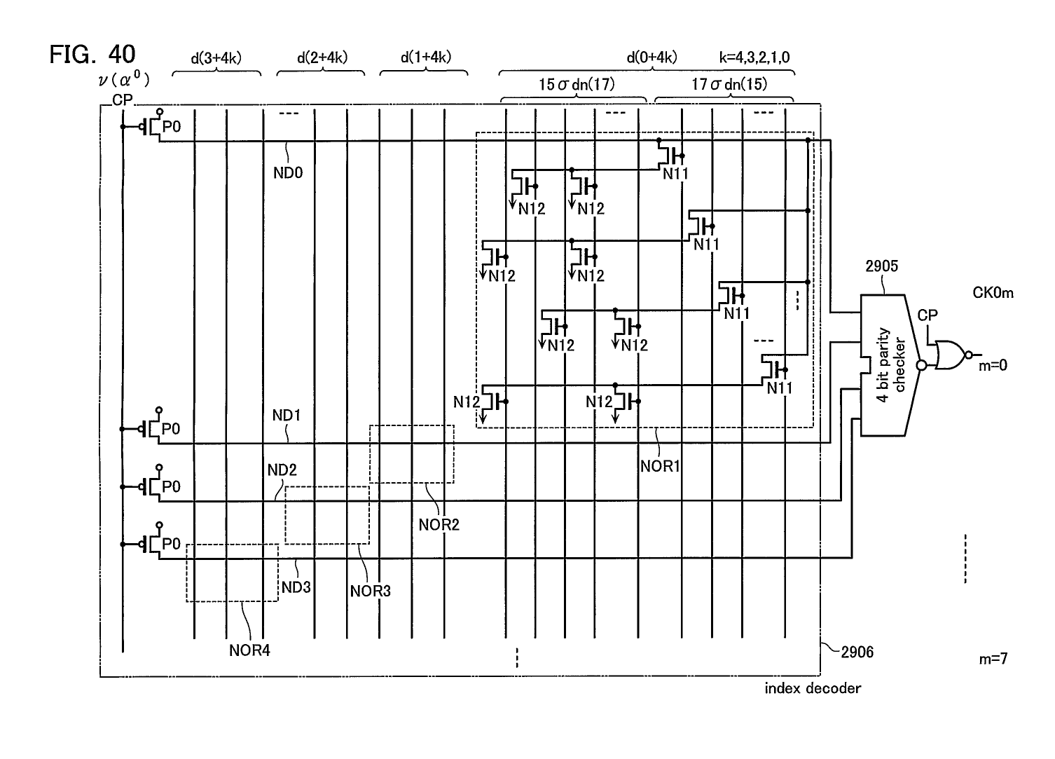

FIG. 40 shows a configuration example of an index decoder 2906 at the input section of the 4-bit parity checker 2905 operative to derive a sum of outputs from the adders in the syndrome calculation with respect to ν(α⁰). At ν(α⁰), it directly receives an expression index of data from not the adder but the decoder at the data input section.

Input signals include data elements d(3+4k), d(2+4k), d(1+4k), d(0+4k), and k=4, 3, 2, 1, 0 are fed into the index decoding unit 2906 as expression indexes in synchronization with the clock CP in 5 cycles. In association with the input data elements, there are nodes ND0-ND3 corresponding to the m-th order coefficients of pn(x) of a sum. The nodes are precharged through PMOS transistors PO driven with the signal CP.

For the common nodes of the elements, NMOS transistors N11 having gates driven by an expression index component 17σdn(15), and NMOS transistors N12 having gates driven by an expression index component 15σdn(17) are provided to configure NOR circuits NOR1, NOR2, NOR3, NOR4. An arrangement of the NMOS transistors N11, N12 can be determined from an association table of coefficients of elements in GF(256) and expression indexes. For each m, 4 nodes ND0-ND3 from each element are subjected to parity check at the 4-bit parity checker 2905 to obtain an m-th coefficient CK0 of a subset sum of one divisional part from 5 parts of a polynomial of ν(α⁰).

In this connection, as the parity checker having even inputs does not change the output even if all inputs have been inverted, the inputs are made inverted inputs of which logic can be made easier because input decoding is achieved by node discharging. The output from the 4-bit parity checker 2905 is inverted and output in synchronization with the clock CP.

FIG. 41 shows a configuration example of an index decoder 2906 at the input section of the 4-bit parity checker 2905 operative to derive a sum of outputs from the adders in the syndrome calculation for ν(αⁱ) (i=1, 2, 3). In this case, it receives an expression index output from the adder as an input signal.

Input signals include elements αid3, αid2, αid1, αid0, which are fed into the decoder unit 2906 as expression indexes in synchronization with the clock CP in 5 cycles. In association with the input data elements, there are nodes ND0-ND3 corresponding to the m-th order coefficients of pn(x) of a sum. The nodes are precharged through PMOS transistors PO driven with the signal CP.

For the common nodes of the elements, NMOS transistors Nil having gates driven by an expression index component 17σαidi(15), and NMOS transistors N12 having gates driven by an expression index component 15σαidi(17) are provided to configure NOR circuits NOR1, NOR2, NOR3, NOR4. A connection to a transistor gate can be determined from an association table of coefficients of elements in GF(256) and expression indexes.

For each m, 4 nodes from each element are subjected to parity check at the 4-bit parity checker 2905 to obtain an m-th coefficient CKim of one divisional part from 5 parts of a subset sum of a polynomial of ν(αⁱ).

### (First-Stage Adder Circuit for Error Search)

The following description is given to a section for calculating a product or quotient between syndromes, or a first stage for error search after the syndrome calculation, that is, the section of the adder circuits 22, 23, 24, 25 and 29 in FIG. 3. First, the section of the first 4 adders 22, 23, 24 and 25 operative to execute product operations S₀S₂, S₀S₃, S₁S₂ and S₁S₃ is described collectively as an “SmSn adder”.

The outputs S₀, S₁, S₂, S₃ from the serial parity checkers in the syndrome computing system are obtained as seventh polynomials and match either element in GF(256), or pn(x). Then, the polynomials are converted into expression indexes, which are represented by indexes mod 17 and mod 15 of roots α of m₁(x) for use in the following calculations.

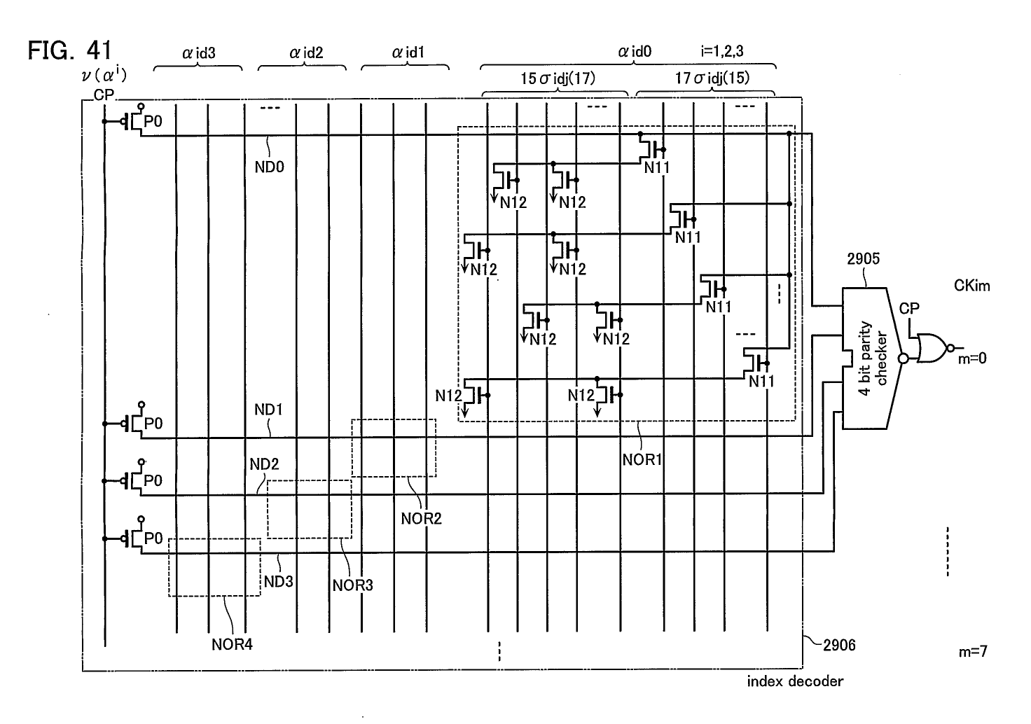

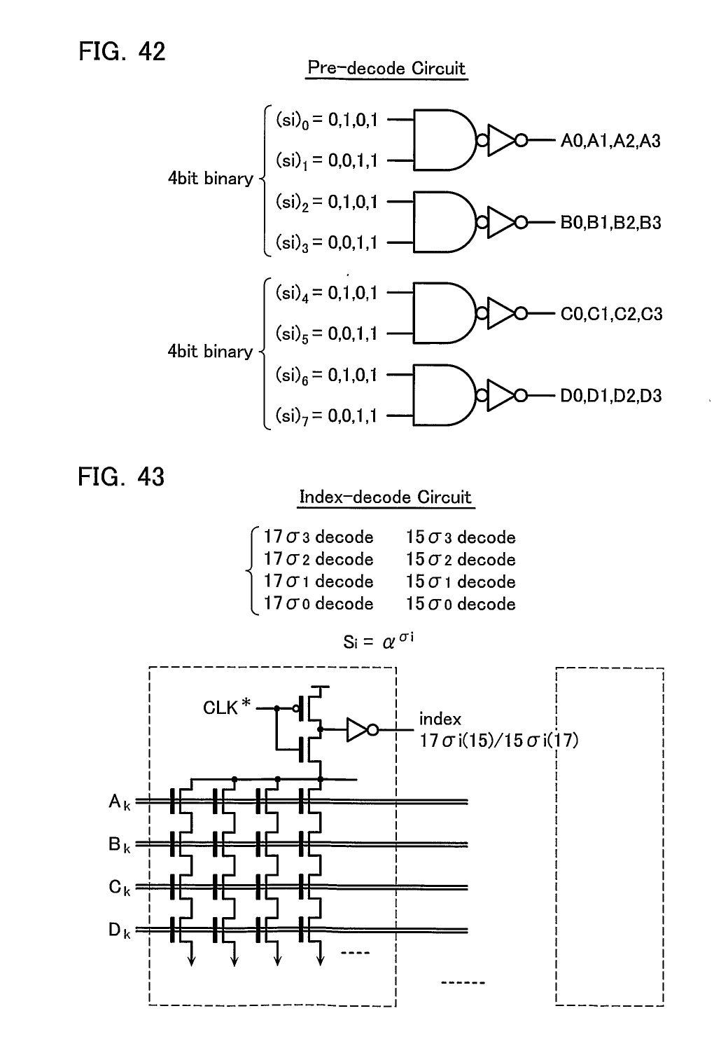

Namely, the decoding circuits provided at the input section of the SmSn adder for that conversion include a pre-decoding circuit shown in FIG. 42 and an index decoding circuit shown in FIG. 43.

The pre-decoding circuit in FIG. 42 is a conversion circuit operative to represent 256 binary signal states represented by 8-bit pn(x) coefficients as combinations of Ai, Bi, Ci, Di (i=0-3), and includes NAND circuits. An 8-bit binary signal is divided by 2 bits from the lowest digit into those represented by quaternary numbers, which are denoted with Ai, Bi, Ci, Di.

The orders m=0, 1 of coefficients of terms in polynomials representative of S0, S1, S2, S3 are converted into Ai, m=2, 3 into Bi, m=4, 5 into Ci, and m=6, 7 into Di. With this pre-decoding, the number of transistors in the units contained in the index decoding circuit at the next stage can be reduced from 8 to 4.

The index decoding circuit in FIG. 43 includes 8 circuits 17σ₃ decode, 15σ₃ decode, 17σ₂ decode, 15σ₂ decode, 17σ₁ decode, 15σ₁ decode, 17σ₀ decode and 15σ₀ decode, which are configured same but different only in input signal.

These decoding circuits divide the pre-decoded signals into groups of residues and provide outputs of indexes thereof. The signals Ak, Bk, Ck, Dk are coupled using decoding NAND connections representative of elements of residues and NOR connections representative of sets of these elements to discharge the precharged nodes with the clock CLK* and provide outputs of inverted index signals of residues. These circuits are required as many as the number of residues.

These indexes are made for mod 17 and mod 15 and used as a pair of expression indexes. The clock CLK* is a clock generated with a delay from the clock CLK at the time of completion of the syndrome calculation.

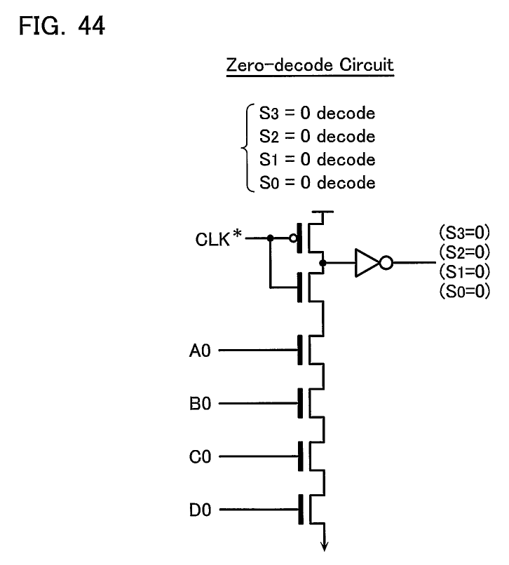

In the case of pn(x)=0, it can not be represented by an index of α and no expression index can be obtained. A signal indicative of this state may be required later. For such the case, a zero decoding circuit shown in FIG. 44 is provided as a state signal generator.

Specifically, as S₃=0 decode, S₂=0 decode, S₁=0 decode, S₀=0 decode, it generates signals (S3=0), (S2=0), (S1=0), (S0=0) in the case of A0=B0=C0=D0=“1” respectively.

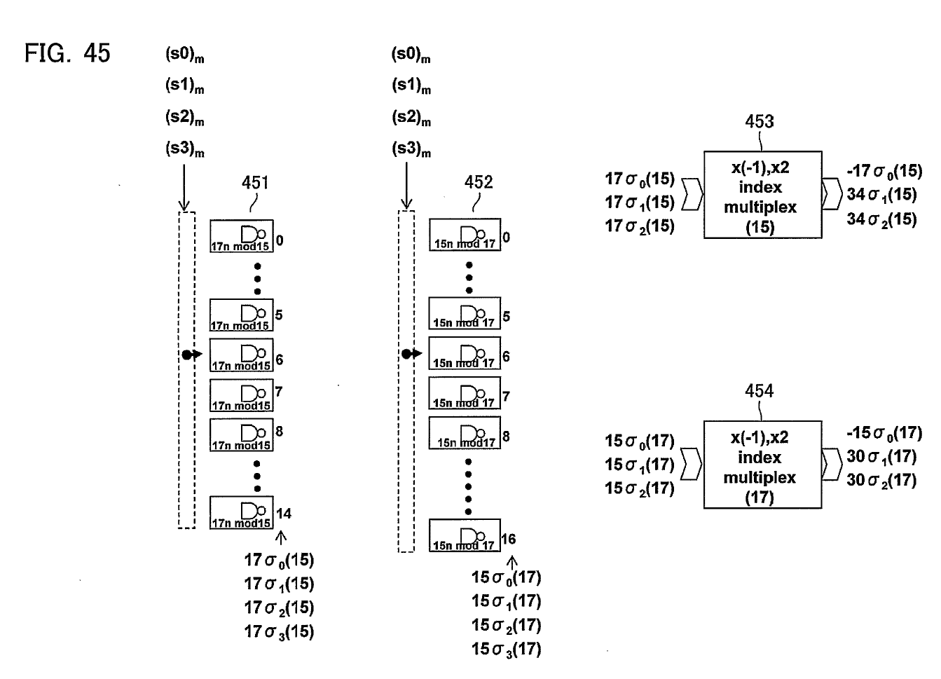

FIG. 45 shows a circuit block operative to convert syndrome polynomials into expression indexes of the syndromes S₀, S₁, S₂, S₃ and obtain the −1 power and the second power of these expression indexes through x(−1) and x2 conversions. These elements are required in later calculations at the adders.

Decoding units 451, 452 in FIG. 45 include the pre-decoding circuits and the index decoding circuits both shown above to generate index components of expression indexes {15σ₀(17), 17σ₀(15)}, {15σ₁(17), 17σ₁(15)}, {15σ₂(17), 17Σ₂(15)}, {15σ₃(17), 17σ₃(15)} of the syndromes S₀, Sᵢ, S₂, S₃.

The index components of these expression indexes are converted at multiplexers 453, 454 in accordance with the conversion table of relational examples between the preceding expression indexes and utilized later in calculations at the adder circuits. The multiplexer circuits 453, 454 are branch circuits only operative to distribute signals in accordance with the association table between the indexes.

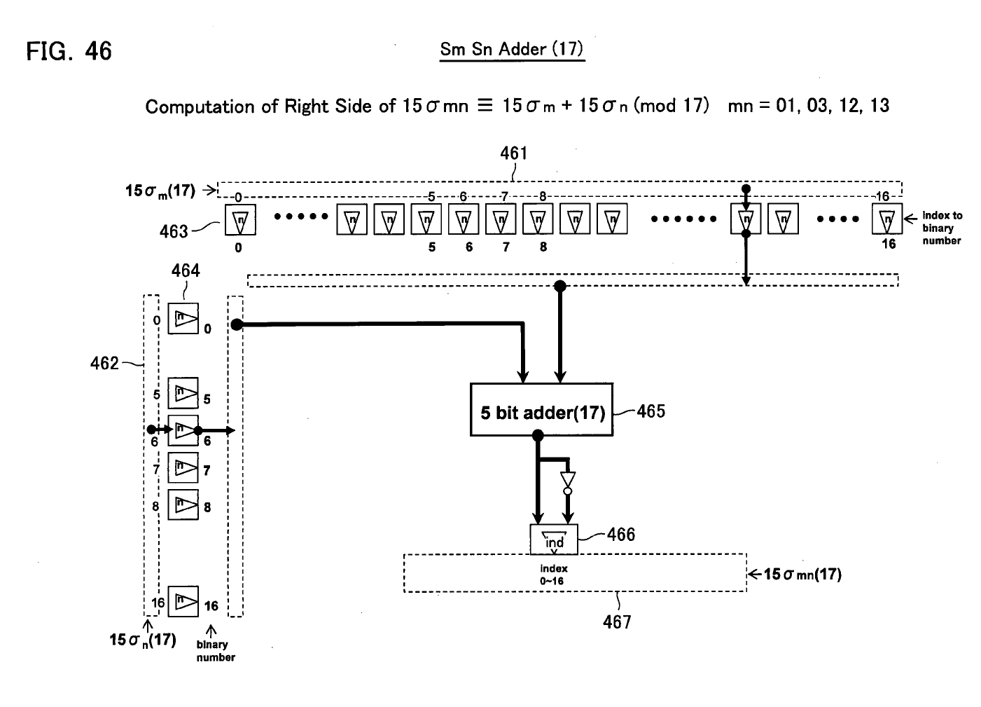

FIG. 46 shows a configuration of an SmSn adder (17) operative to calculate an expression index modulo 17 of SmSn. Namely, it is an adder operative to execute one of two separated congruences shown in Expressions 19-22, or a computation of the right side of a congruence mod 17. In practice, adders are prepared for (m, n)=(0, 1), (0, 3), (1, 2), (1, 3).

Inputs 461, 462 are expression index components 15σₘ(17) and 15σₙ(17), respectively. Before these are summed at a 5-bit adder (17) 465, the indexes are converted into binary representations at index/binary conversion circuits 463, 464. The summed results are returned to indexes at a binary/index conversion circuit 466 and provided as an output 467 of an expression index component 15σₘₙ(17).

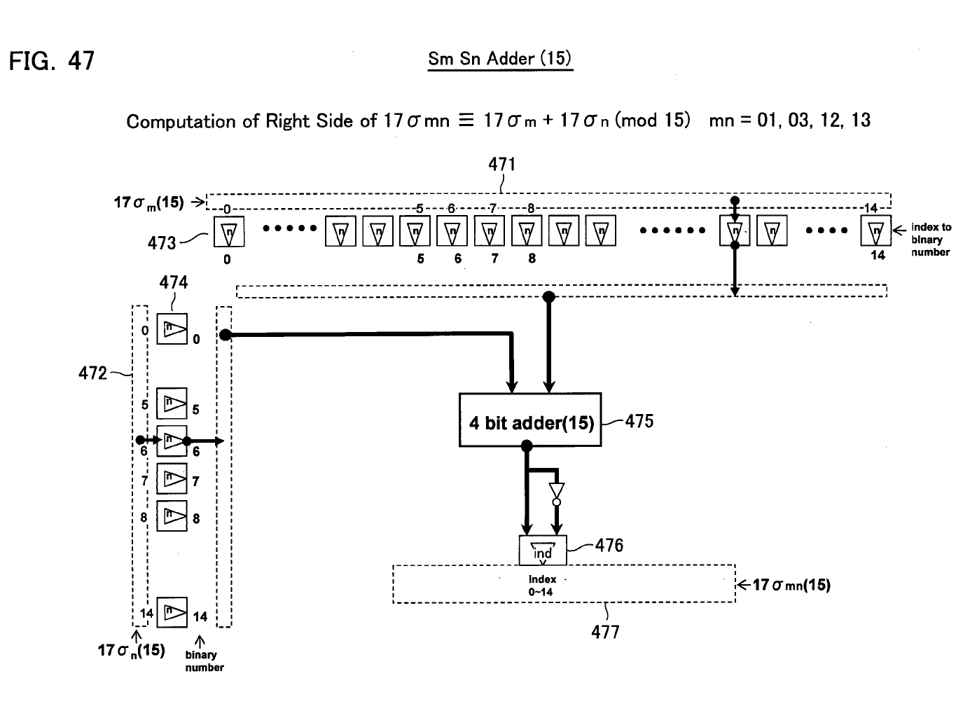

FIG. 47 shows an SmSn adder (17) operative to execute the right side of the other congruence in Expressions 19-22 or a congruence mod 15. In practice, adders are prepared for (m, n)=(0, 1), (0, 3), (1, 2), (1, 3).

Inputs 471, 472 are expression index components 17σₘ(15) and 17σₙ(15), respectively. Before these are summed at a 4-bit adder (17) 475, the indexes are converted into binary representations at index/binary conversion circuits 473, 474. The summed results are returned to indexes at a binary/index conversion circuit 476 and provided as an output 477 of an expression index component 17σₘₙ(15).

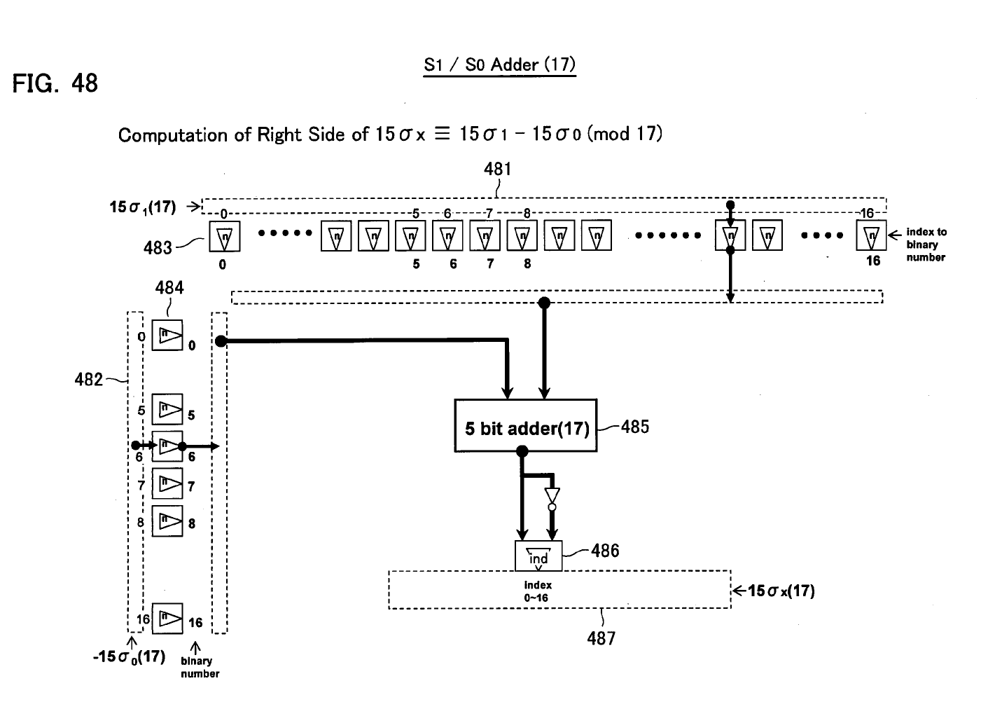

FIG. 48 shows an S₁/S₀ adder (17) of the adder circuit 29 in FIG. 3, which is operative to calculate an expression index modulo 17 of a finite field element S₁/S₀, or an adder operative to execute a computation of the right side of 15σx≡15σ₁−15σ₀(mod 17). Inputs 481, 482 are 15σ₁(17) and −15σ₀(17), which are x(−1)-converted from the expression index component 15σ₀(17).

Before these are summed at a 5-bit adder (17) 485, the indexes are converted into binary representations at index/binary conversion circuits 483, 484. After a calculation as a residue modulo 17, the output is converted again to an index at a binary/index conversion circuit 486 and provided as an output 487 of an expression index component 15σₓ(17).

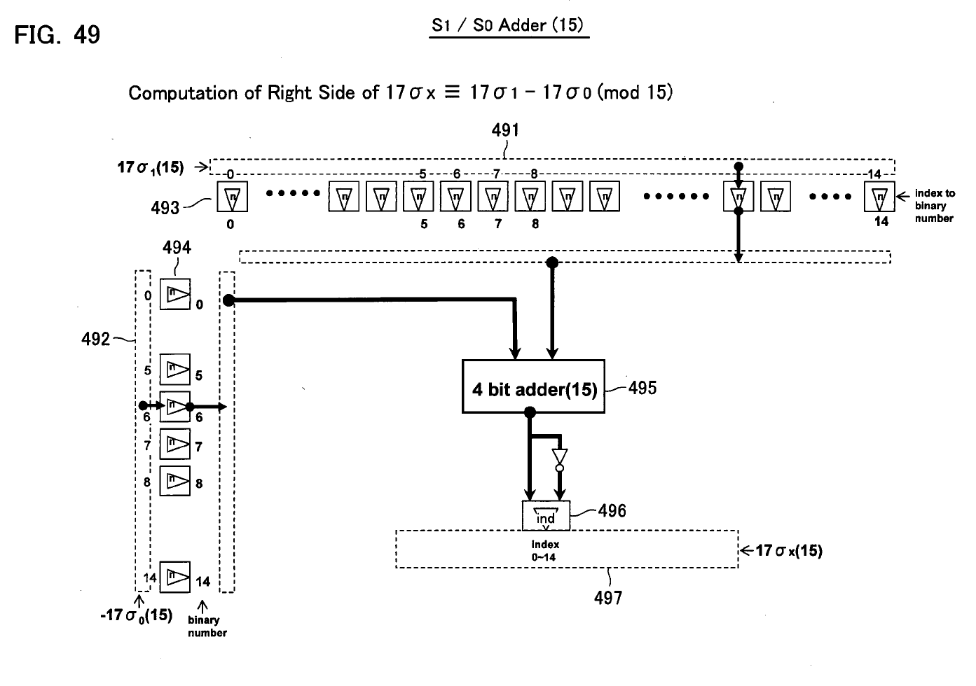

FIG. 49 shows an S₁/S₀ adder (15) of the adder circuit 29 in FIG. 3, which is operative to calculate an expression index modulo 15 of the finite field element S₁/S₀, or an adder operative to execute a computation of the right side of 17σₓ≡17σ₁−17σ₀(mod 15). Inputs 491, 492 are 17σ₁(15) and −17σ₀(15), which are x(−1)-converted from the expression index component 17σ₀(15).

Before these are summed at a 4-bit adder (17) 495, the indexes are converted into binary representations at index/binary conversion circuits 493, 494. After a calculation as a residue modulo 15, the output is converted again to an index at a binary/index conversion circuit 496 and provided as an output 497 of an expression index component 17σₓ(15).

### (First-Stage Parity Check Unit for Error Search)

Next, a first-stage parity check unit for use in error search, that is, the section of parity checkers 26, 27 and 28 in FIG. 3 is described. These are sections of calculating A=S₀S₂+S₁², B=S₀S₃+S₁S₂ and C=S₁S₃+S₂².

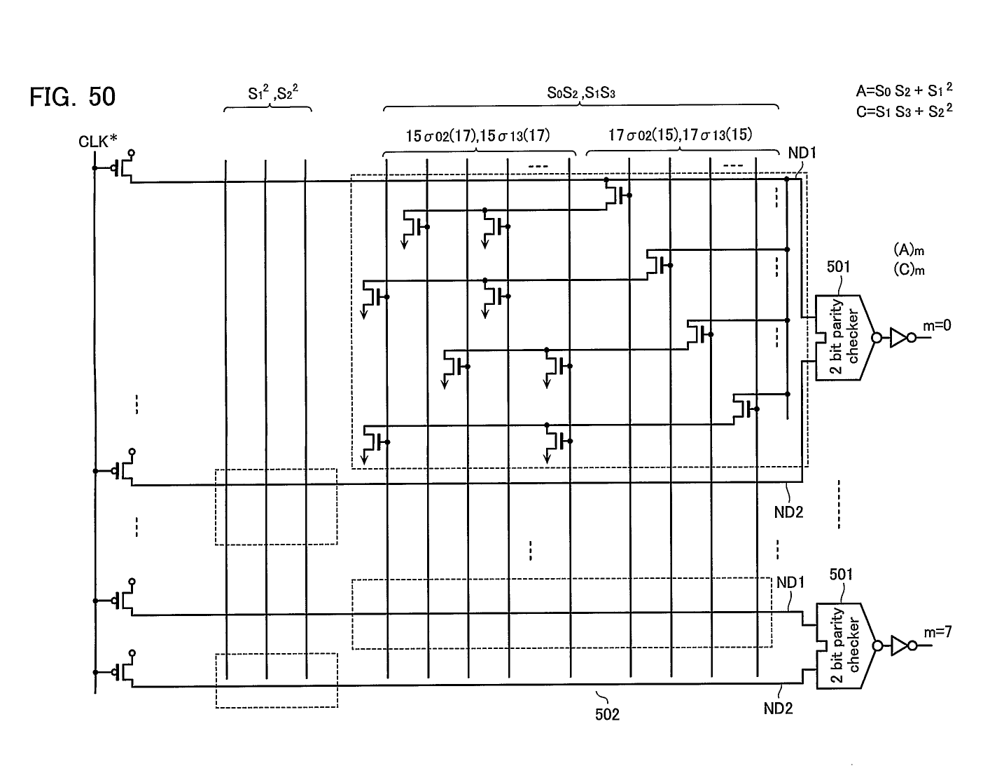

FIG. 50 shows a configuration of the parity checkers 26, 27, which includes parity checkers 501 operative to calculate A=S₀S₂+S₁² and C=S₁S₃+S₂² and associated input decoding circuits 502.

Input signals are expression indexes of elements S₀S₂ and S₁² with respect to A and elements S₁S₃ and S₂² with respect to C. For these elements, there are nodes ND1, ND2 corresponding to the m-th order coefficients. The nodes are precharged with the signal CLK*. A connection of an expression index signal on the m-th order node of each element to a transistor gate can be determined from the above association table between coefficients of elements in GF(256) and expression indexes.

For each m, two nodes ND1, ND2 from each element are subjected to parity check at a 2-bit parity checker 501 to obtain the m-th coefficients of A and C, that is, (A)ₘ and (C)ₘ. In this connection, as the parity checker 501 does not change the output even if all inputs have been inverted, the inputs are made inverted inputs of which logic can be made easier because input decoding is achieved by node discharging.

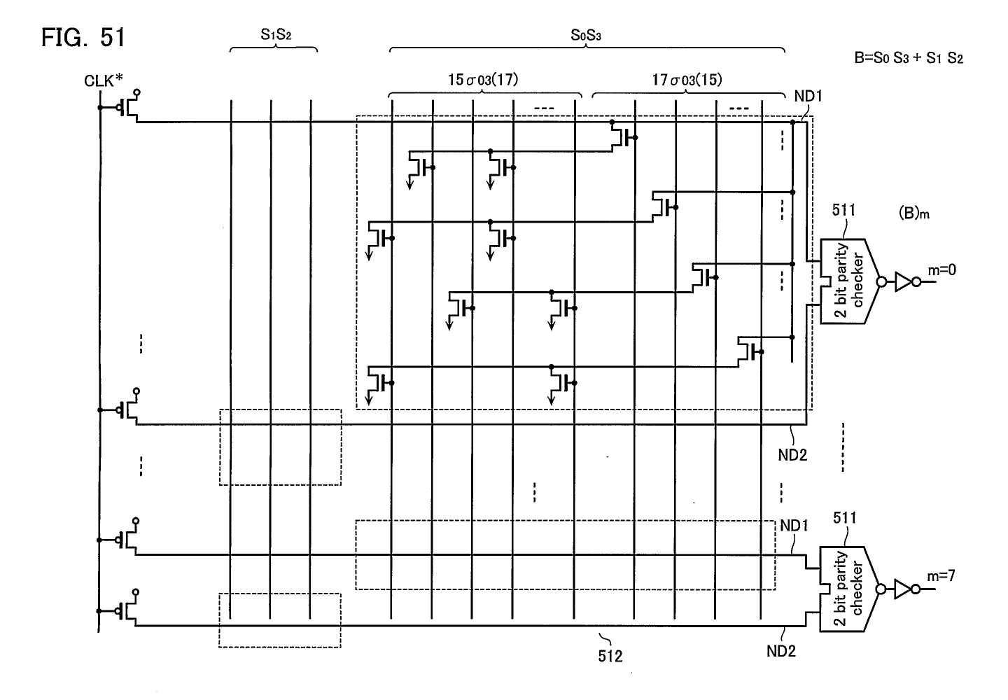

FIG. 51 shows a configuration of the parity checker 27 in FIG. 3, which includes a parity checker 511 operative to calculate B=S₀S₃+S₁S₂ and an associated input decoding unit 512.

Input signals are expression indexes of elements S₀S₃ and S₁S₂. For these elements, there are nodes ND1, ND2 corresponding to m-th order coefficients. The nodes are precharged with the signal CLK*. A connection of an expression index signal on an m-th order node of each element to a transistor gate can be determined from the above association table between coefficients of elements in GF(256) and expression indexes.

For each m, two nodes ND1, ND2 from each element are subjected to parity check at a 2-bit parity checker 511 to obtain the m-th coefficient of B, that is, (B)ₘ.

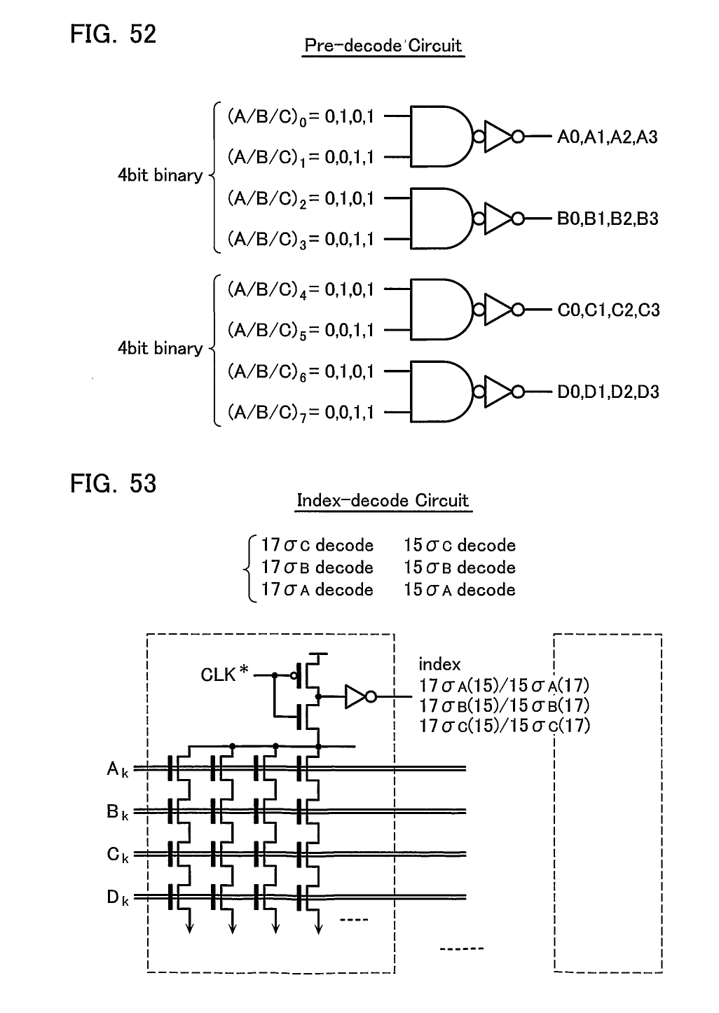

A, B, C can be obtained as seventh polynomials and match either element in GF(256), or pn(x). Then, the polynomials are converted into expression indexes, which are represented by indexes mod 17 and mod 15 of roots α of m₁(x) for use in the following calculations. Decoding circuits available in the conversion are shown in FIGS. 52-54.

The pre-decoding circuit in FIG. 52 is a conversion circuit operative to represent 256 binary signal states as combinations of Ai, Bi, Ci, Di (i=0-3) represented by 8-bit pn(x) coefficients, and includes NAND circuits. An 8-bit binary signal is divided by 2 bits from the lowest digit into those represented as quaternary numbers, which are denoted with Ai, Bi, Ci, Di.

The orders m=0, 1 of A, B, C are converted into Ai, m=2, 3 into Bi, m=4, 5 into Ci, and m=6, 7 into Di. With this pre-decoding, the number of transistors in the units contained in the index decoding circuit at the next stage shown in FIG. 53 can be reduced from 8 to 4.

The index decoding circuit in FIG. 53 includes 6 types of 17σ_{A} decode, 15σ_{A} decode, 17σ_{B} decode, 15σ_{B} decode, 17σ_{C} decode and 15σ_{C} decode, which are different only in input signal. This circuit divides the pre-decoded signals into groups of residues and provides outputs of indexes thereof.

Namely, the signals Ai, Bi, Ci, Di are coupled using decoding NAND connections representative of elements of residues and NOR connections representative of sets of these elements to discharge the precharged nodes with the clock CLK* and provide outputs of inverted index signals of residues. These circuits are required as many as the number of residues. These indexes are made for mod 17 and mod 15 and used as a pair of expression indexes.

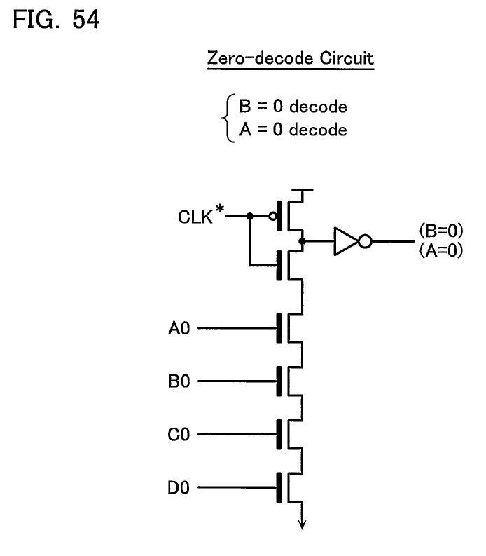

In the case of pn(x)=0, it can not be represented by an index of α and no expression index can be obtained. A signal indicative of this state may be required later. For such the case, a zero decoding circuit shown in FIG. 54 is provided. Specifically, as A=0 decode, B=0 decode, it generates signals (A=0), (B=0) in the case of A0=B0=C0=D0=“1” respectively.

### (Second-Stage Adder Circuit for Error Search)

The following description is given to a configuration of the section of the second-stage adder circuits 30, 31 in FIG. 3. These circuits use A, B, C obtained at the parity checkers 26-28 to compute a product AC and a=B/A.

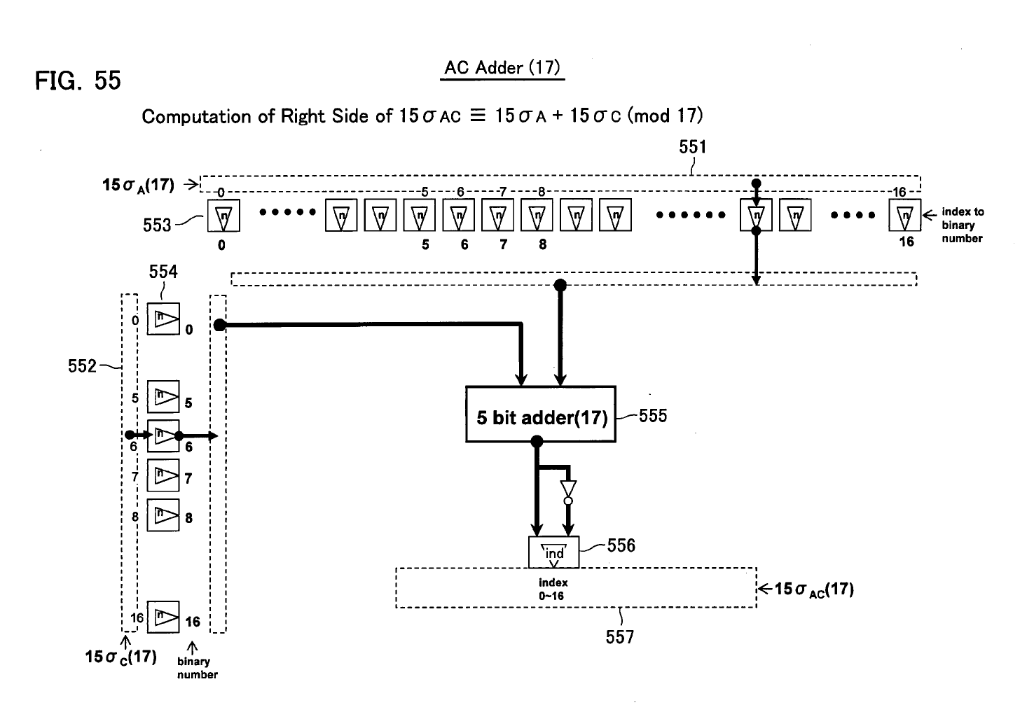

FIG. 55 shows one of the adder circuits 30 in FIG. 3, that is, an AC adder (17) operative to calculate an expression index modulo 17 of a finite field element AC. Inputs 551, 552 are expression index components 15σ_{A}(17) and 15σ_{C}(17). Before these are summed at a 5-bit adder (17) 555, they are passed through index/binary conversion circuits 553, 554 to convert the indexes into binary representations.

Thus, the adder 555 calculates them as residues modulo 17. The output therefrom is converted again into an index at a binary/index conversion circuit 556 and provided as an output 557 of an expression index component 15σ_{AC}(17).

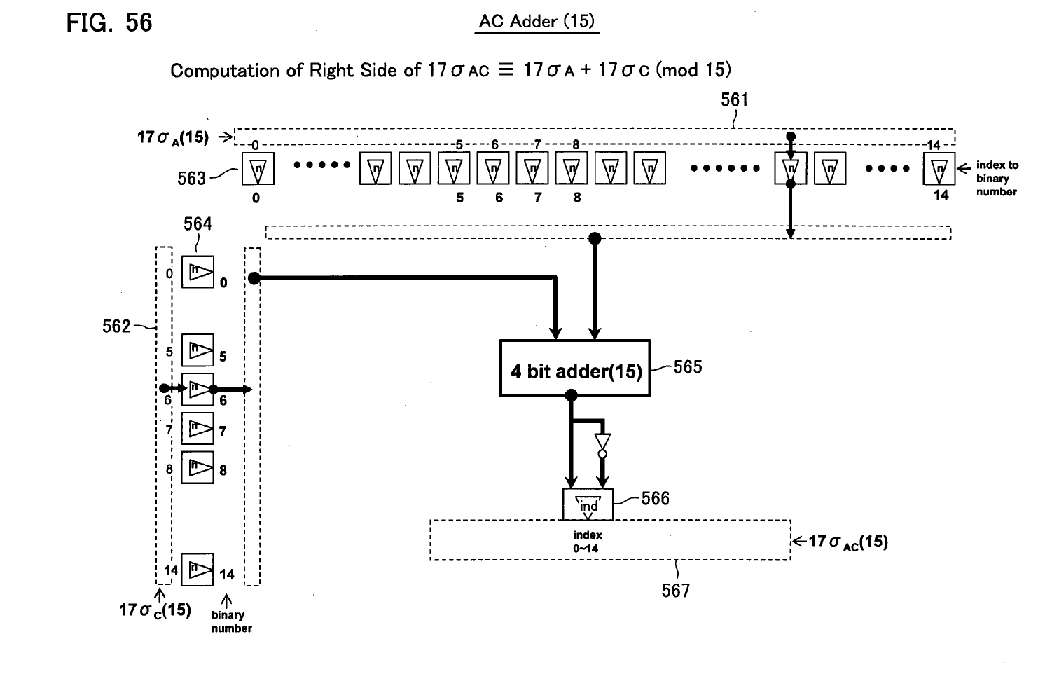

FIG. 56 shows another one of the adder circuits 30 in FIG. 3, that is, an AC adder (15) operative to calculate an expression index modulo 15 of the finite field element AC. Inputs 561, 562 are expression index components 17σ_{A}(15) and 17σ_{C}(15). Before these are summed at a 4-bit adder (15) 565, they are passed through index/binary conversion circuits 563, 564 to convert the indexes into binary representations.

Thus, the adder 565 executes a calculation as a residue modulo 15. The output therefrom is converted again into an index at a binary/index conversion circuit 566 and provided as an output 567 of an expression index component 17σ_{AC}(15).

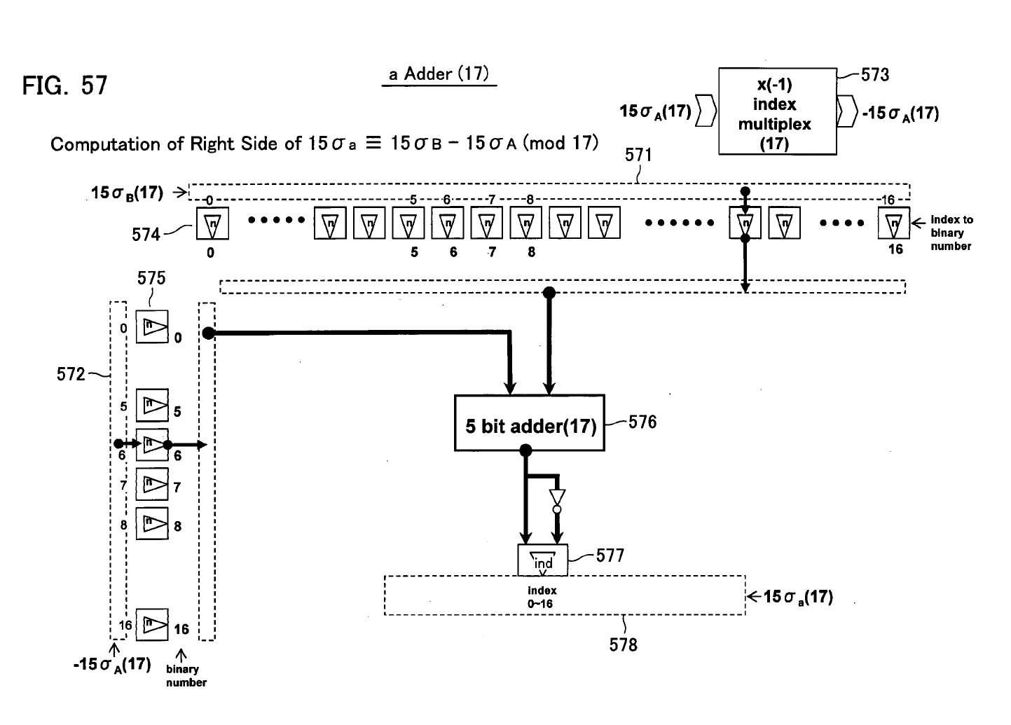

FIG. 57 shows one of the adder circuits 30 in FIG. 3, that is, an a adder (17) operative to calculate an expression index modulo 17 of a finite field element a=B/A. One input 571 is an expression index component 15σ_{B}(17) and the other input is −15σ_{A}(17) which is x(−1)-converted from 15σ_{A}(17) at a multiplexer 573.

Before these are summed at a 5-bit adder (17) 576, they are passed through index/binary conversion circuits 574, 575 to convert the indexes into binary representations. Thus, the adder 575 calculates them as residues modulo 17. The output therefrom is converted again into an index at a binary/index conversion circuit 577 and provided as an output 578 of an expression index component 15σₐ(17).

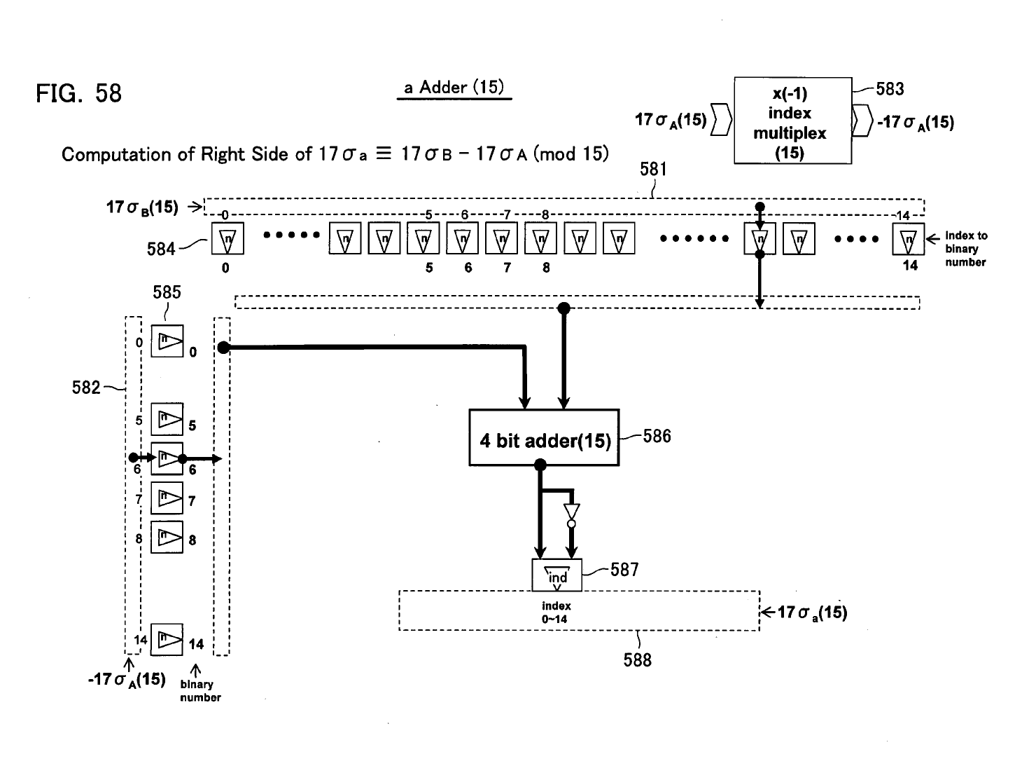

FIG. 58 shows another one of the adder circuits 30 in FIG. 3, that is, an a adder (15) operative to calculate an expression index modulo 15 of the finite field element a=B/A. One input 581 is an expression index component 17σ_{B}(15) and the other input is −17σ_{A}(15), which is x(−1)-converted from 17σ_{A}(15) at a multiplexer 583.

Before these are summed at a 4-bit adder (17) 586, they are passed through index/binary conversion circuits 584, 585 to convert the indexes into binary representations. Thus, the adder 586 executes a calculation as a residue modulo 15. The output therefrom is converted again into an index at a binary/index conversion circuit 587 and provided as an output 588 of an expression index component 17σₐ(15).

### (Third-Stage Adder Circuit for Error Search)

The following description is given to a configuration of the section of the second-stage adder circuits 32, 33 in FIG. 3. These circuits compute D=AC/B² and S₁/a.

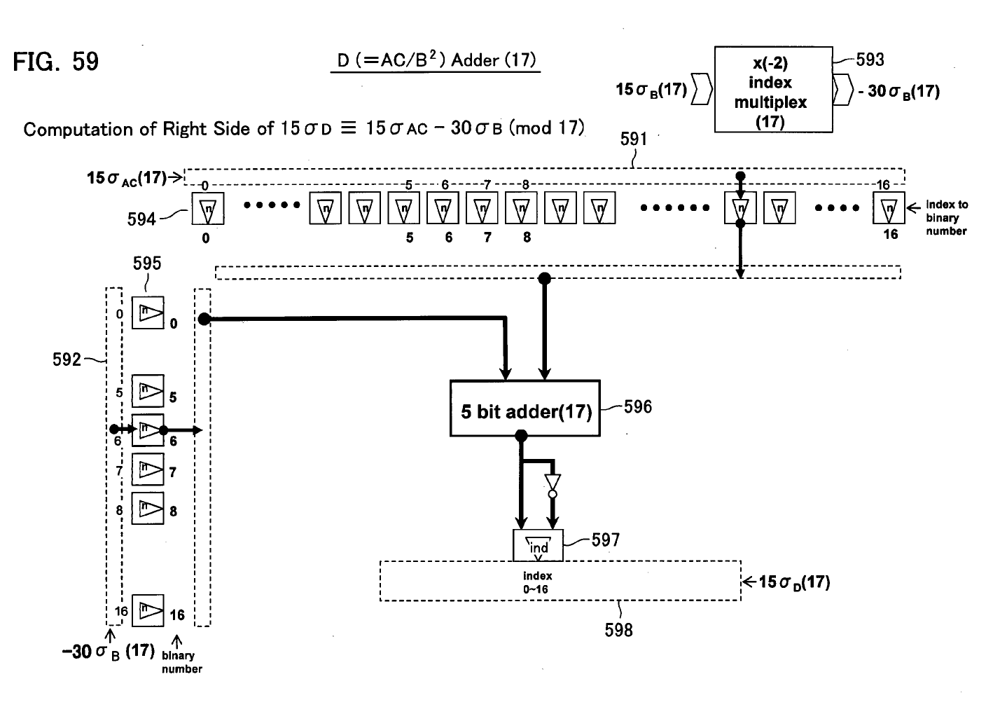

FIG. 59 shows one of the adder circuits 32, that is, a D adder (17) operative to calculate an expression index modulo 17 of a finite field element D=AC/B². One input 591 is an expression index component 15σ_{AC}(17) and the other input 592 is −30σ_{B}(17), which is x(−2)-converted from 15σ_{B}(17) at a multiplexer 593.

Before these are summed at a 5-bit adder (17) 596, the indexes are converted into binary representations at index/binary conversion circuits 594, 595. The calculated result from the adder 596 is converted again into an index at a binary/index conversion circuit 597 and provided as an output 598 of an expression index component 15σ_{D}(17).

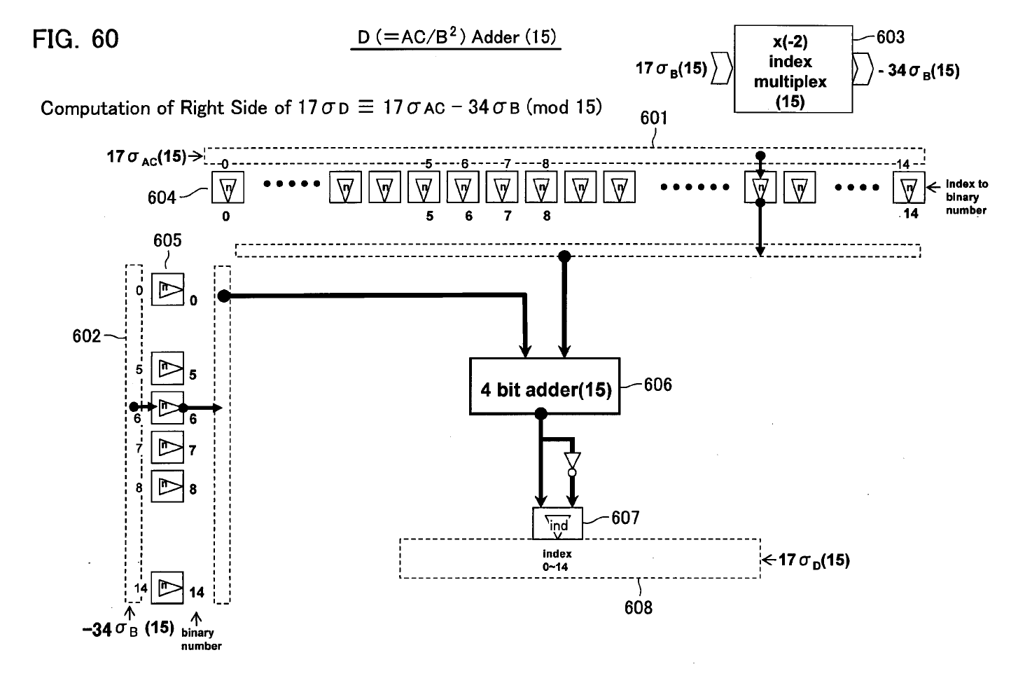

FIG. 60 shows another one of the adder circuits 32, that is, a D adder (15) operative to calculate an expression index modulo 15 of the finite field element D=AC/B². One input 601 is an expression index component 17σ_{AC}(15) and the other input 602 is −34σ_{B}(15), which is x(−2)-converted from 17σ_{B}(15) at a multiplexer 603.

Before these are summed at a 4-bit adder (15) 606, the indexes are converted into binary representations at index/binary conversion circuits 604, 605. The calculated result from the adder 606 is converted again into an index at a binary/index conversion circuit 607 and provided as an output 608 of an expression index component 17σ_{D}(15).

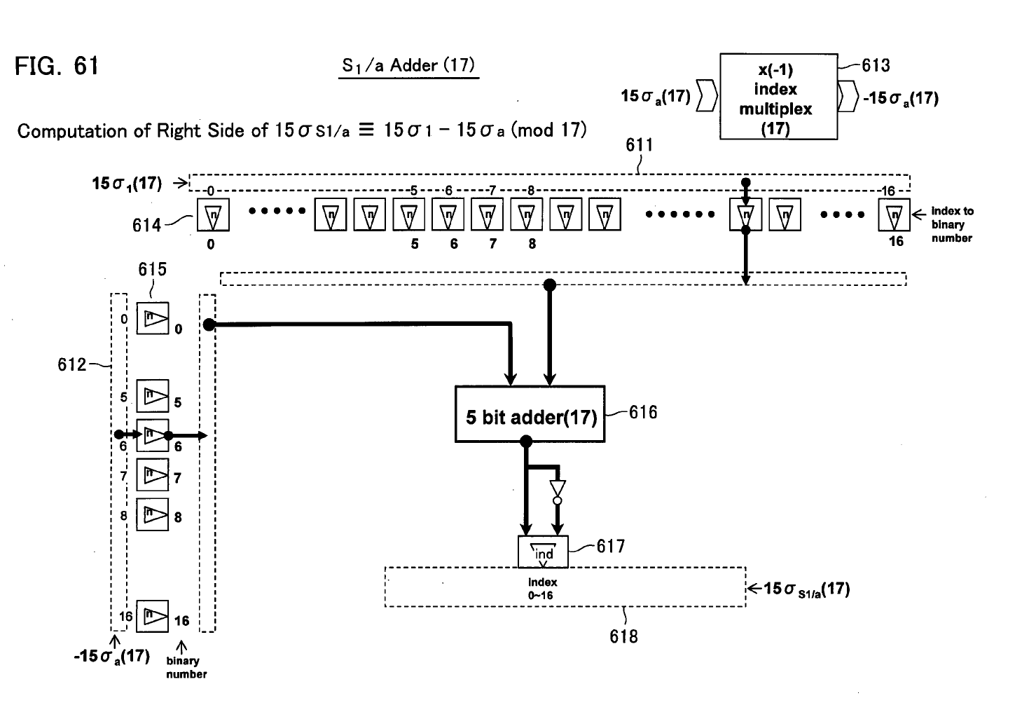

FIG. 61 shows one of the adder circuits 33, that is, an S₁/a adder (17) operative to calculate an expression index modulo 17 of a finite field element S₁/a. One input 611 is an expression index component 15σ₁(17) and the other input 612 is −15σₐ(17), which is x(−1)-converted from 15σₐ(17) at a multiplexer 613.

Before these are summed at a 5-bit adder (17) 616, the indexes are converted into binary representations at index/binary conversion circuits 614, 615. The calculated result from the adder 616 is converted again into an index at a binary/index conversion circuit 617 and provided as an output 617 of an expression index component 15σ_{S1/a}(17).

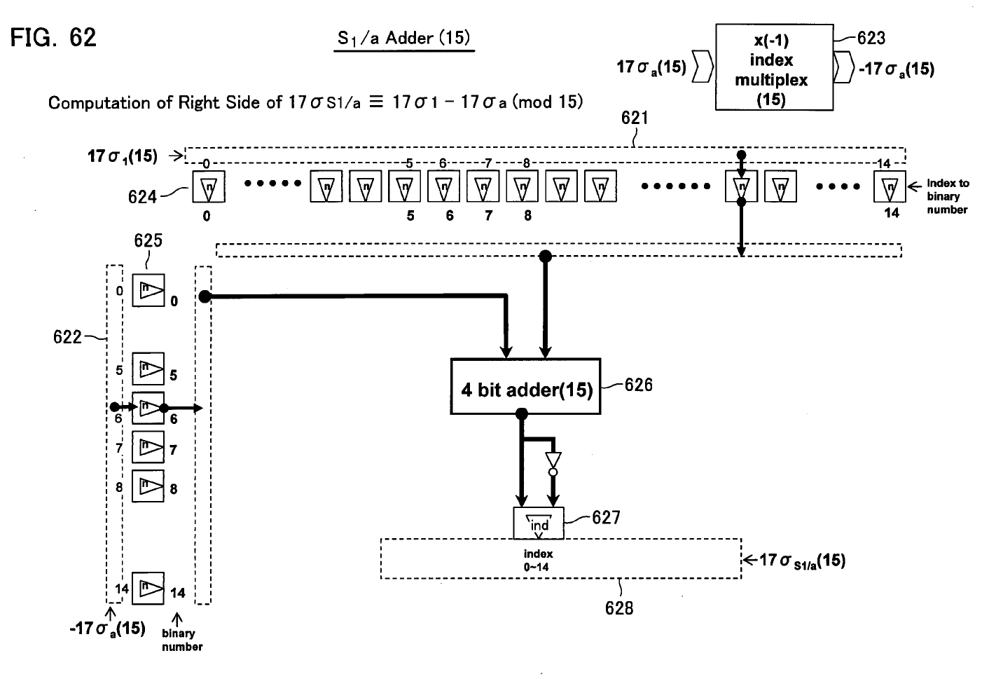

FIG. 62 shows another one of the adder circuits 33, that is, an S₁/a adder (15) operative to calculate an expression index modulo 15 of the finite field element S₁/a. One input 621 is an expression index component 17σ₁(15) and the other input 622 is −17σₐ(15), which is x(−1)-converted from 17σₐ(15) at a multiplexer 623.

Before these are summed at a 4-bit adder (15) 626, the indexes are converted into binary representations at index/binary conversion circuits 624, 625. The calculated result from the adder 626 is converted again into an index at a binary/index conversion circuit 627 and provided as an output 628 of an expression index component 17σ_{S1/a}(15).

### (Final-Stage Adder Circuit for Error Search)

The following description is given to the final-stage adder circuits 34, 35. The adder circuit 34 is used to find locations n of two symbol errors and the adder circuit 35 is used to calculate S₀y required in computations for correcting the symbol errors.

A search for error locations of 2 errors requires a solution of y²+y=D. In this case, when an index of y²+y is denoted with yₖ, and an index of y with k, a relation between k and yₖ is determined as α^{2k}+α^{k}=α^{yk}.

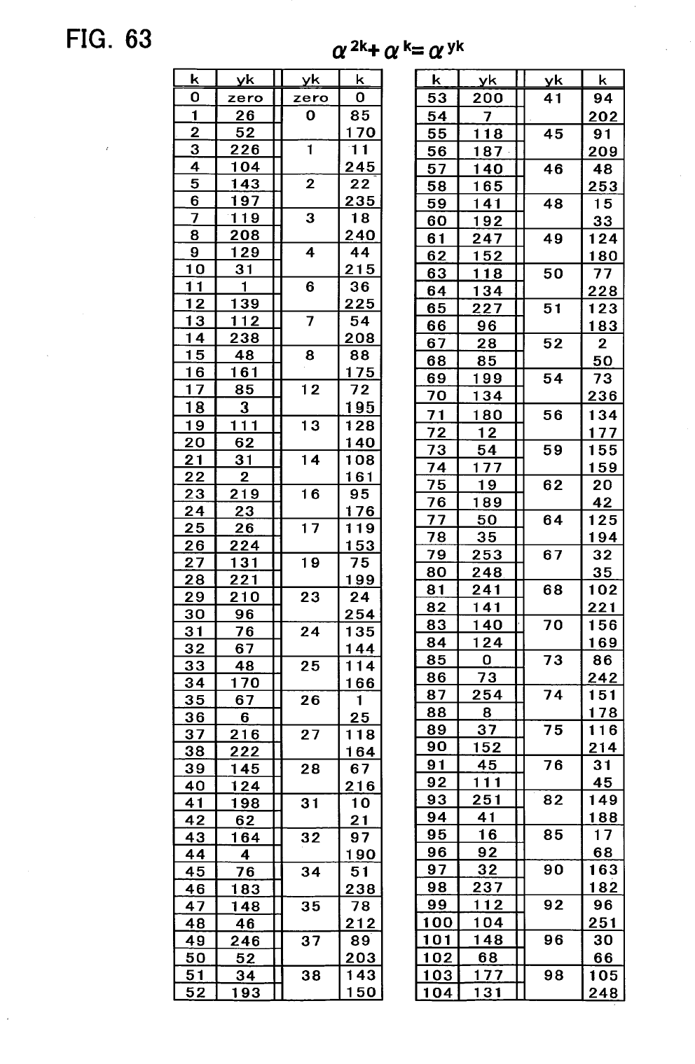

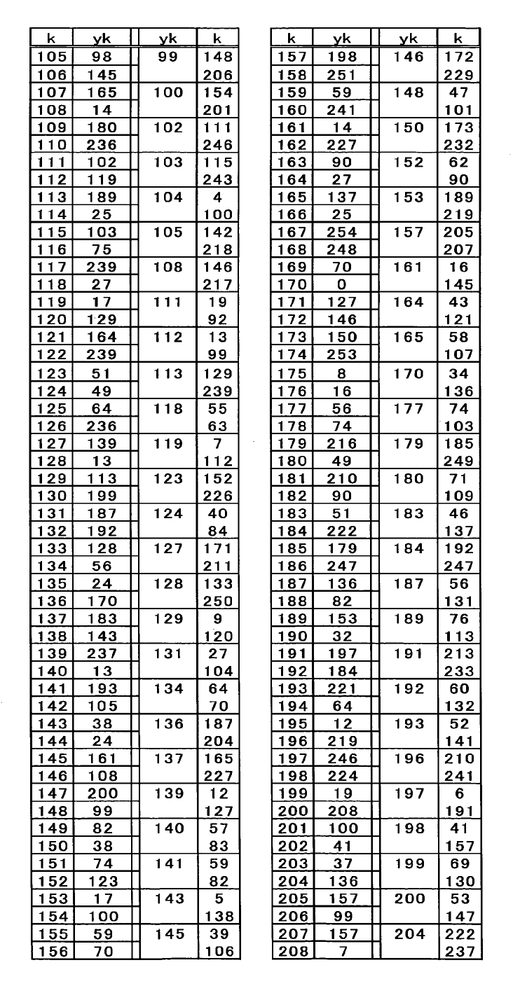

FIG. 63 is a table showing associative relations between the indexes k and yₖ collectively for configuring the decoder in the adder circuit input section. Those with yₖ arranged in order of k and those with k arranged in order of yₖ are shown together. It shows that the same yₖ corresponds to two k's except the case of k=0. In the case of k=0, yₖ corresponds to a zero element and corresponds to 1 bit error. The values of yk do not cover all 255 residues as can be found. If no associated yk is present, this case is not related to 2 errors.

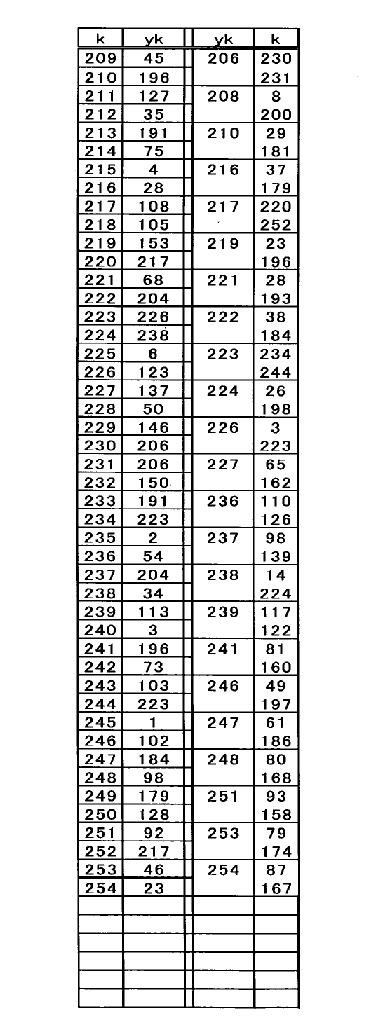

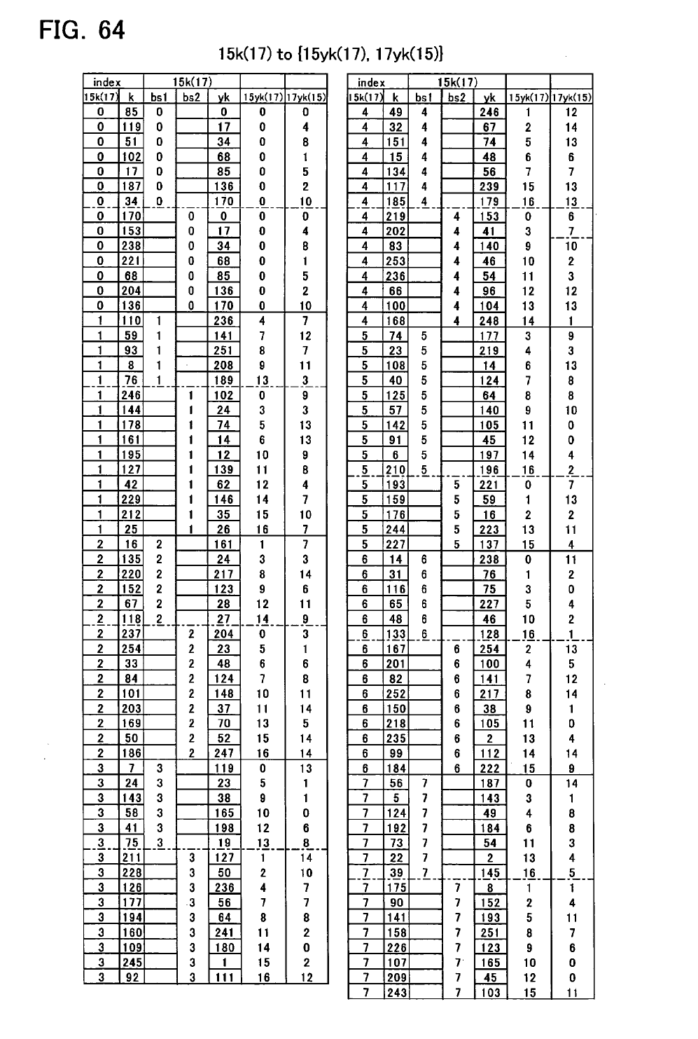

FIG. 64 is a table showing relations between expression indexes of yₖ, that is, {15yₖ(17), 17yₖ(15)} and expression index components of k, that is, 15k (17), and also showing relations with bus configurations on decoding.

The table makes a group collected on each value of 15k (17). If a decoder is made from this table for an expression index of yₖ derived from D=y²+y through a calculation of α_{D}≡yₖ(255), an expression index component of k, that is, 15k (17) can be obtained. As the same yₖ corresponds to two k's, however, the decoded output is divided in two such that two buses bs1, bs2 are provided to prevent data outputs from colliding with each other per k.

For example, if yₖ=17 corresponds to k=119, 153, then the buses are divided in such a manner that k=119 corresponds to the bus bs1 and k=153 to the bus bs2.

An actual decoder uses expression indexes. Therefore, each expression index of yₖ is associated with a value of the expression index component of k, that is, 15k(17) output to each bus bs1, bs2. If there is no association between expression indexes, the case is not related to 2 errors.

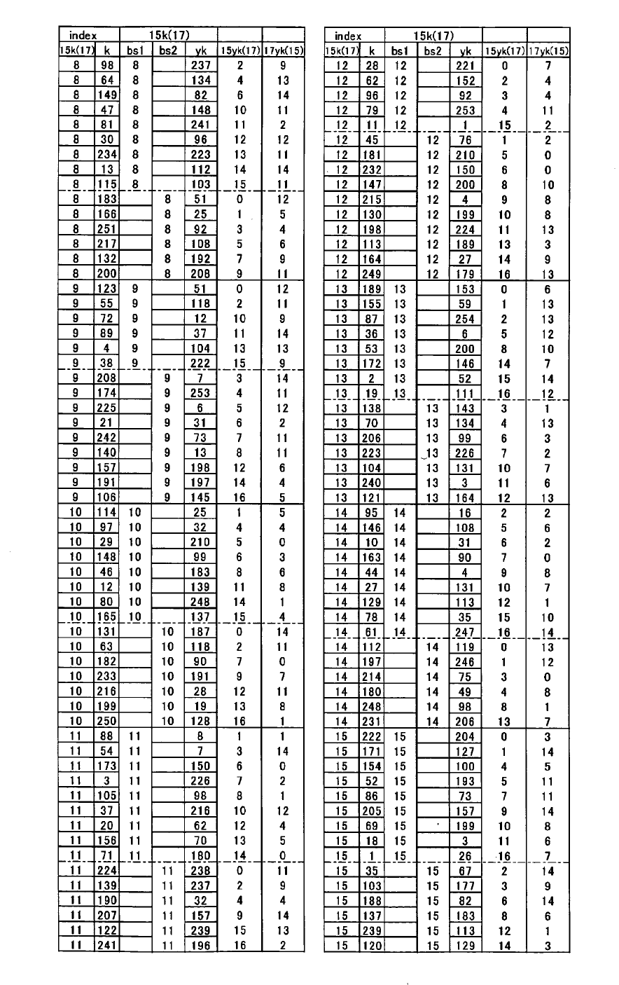

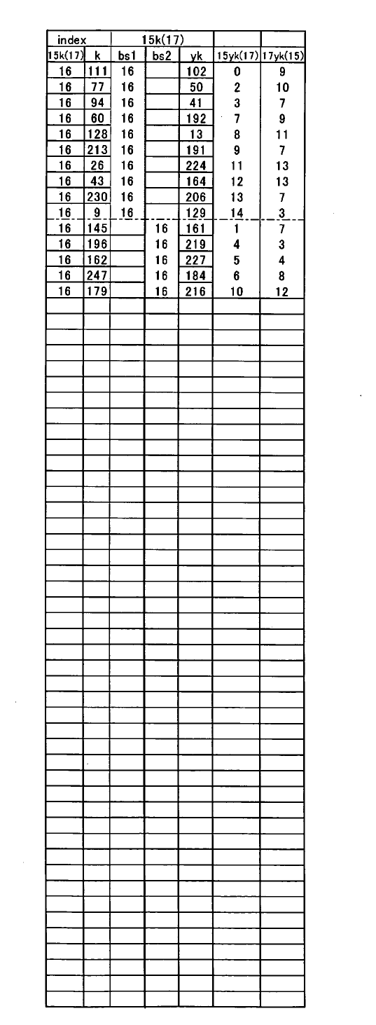

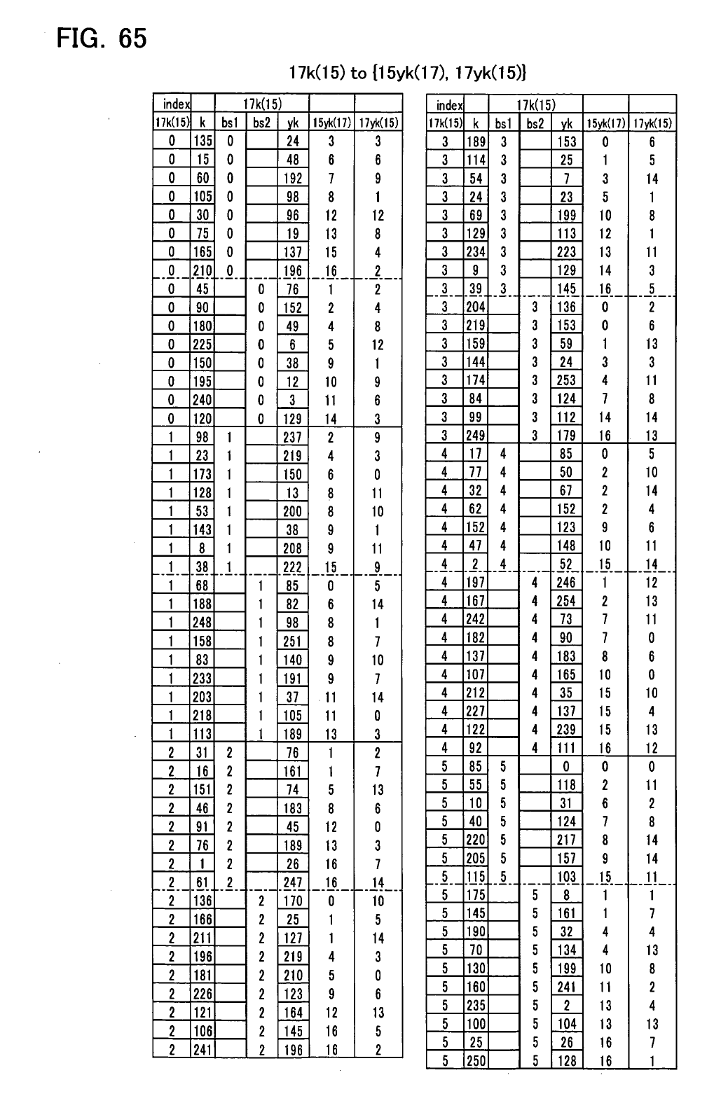

FIG. 65 is a table showing relations between expression indexes of yₖ, that is, {15yₖ(17), 17yₖ(15)} and expression index components of k, that is, 17k(15) and also showing relations with bus configurations on decoding.

The table makes a group collected on each value of 17k (15). If a decoder is made from this table for an expression index of yₖ derived from D=y²+y through a calculation of α_{D}=yₖ(255), an expression index component of k, that is, 17k(15) can be obtained. As the same yₖ corresponds to two k's, however, the decoded output is divided in two such that two buses bs1, bs2 are provided to prevent data outputs from colliding with each other per k.

For example, if yₖ=17 corresponds to k=119, 153, then the buses are divided in such a manner that k=119 corresponds to the bus bs1 and k=153 to the bus bs2.

An actual decoder uses expression indexes. Therefore, each expression index of yₖ is associated with a value of the expression index component of k, that is, 17k (15) output to each bus bs1, bs2. If there is no association between expression indexes, the case is not related to 2 errors.

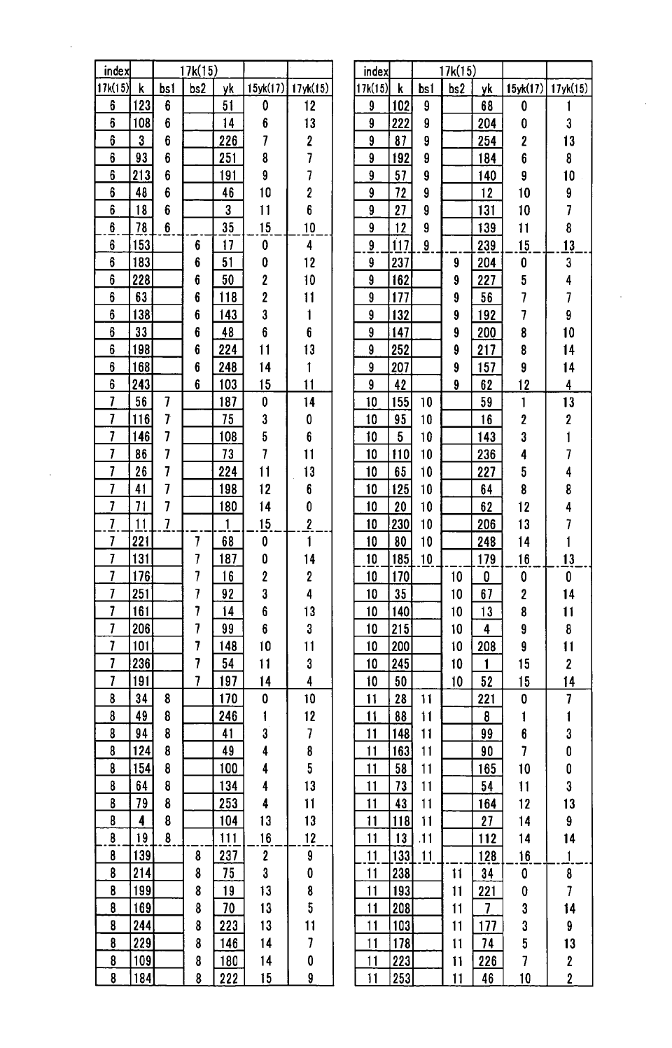

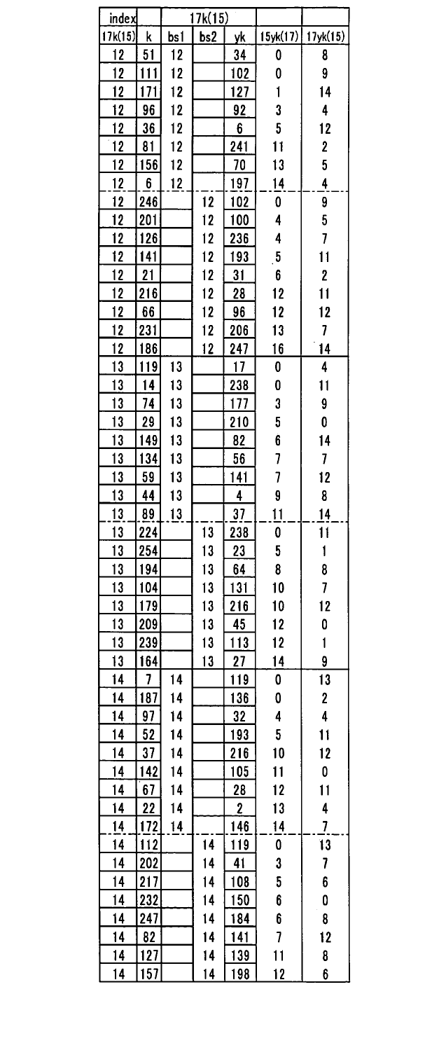

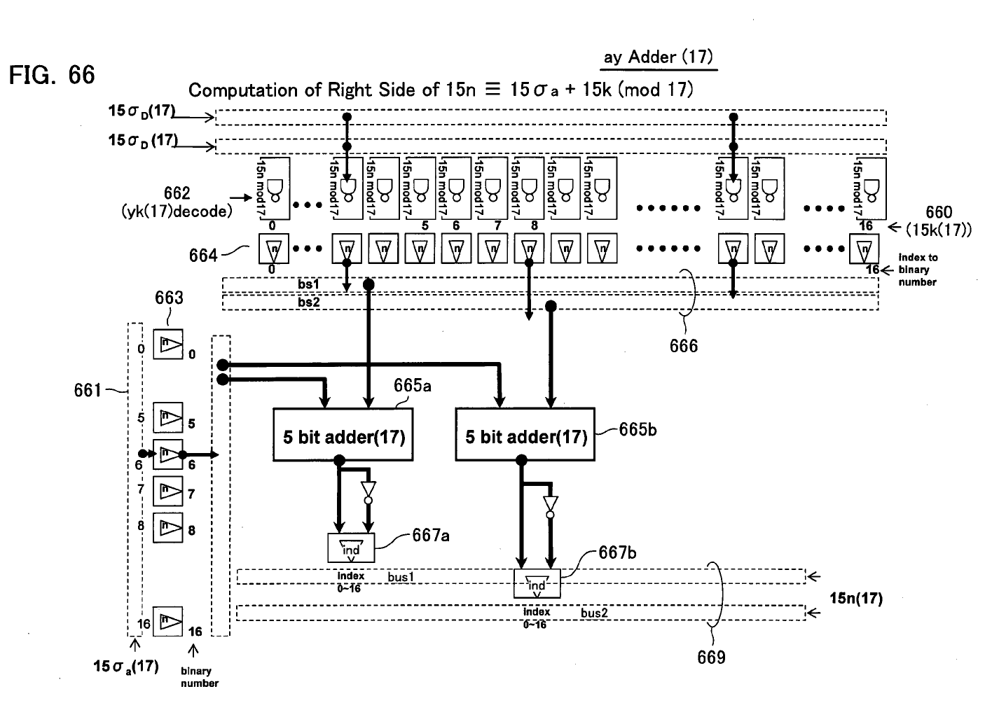

FIG. 66 shows one of the adder circuits 34, that is, an ay adder (17) operative to search two error locations through decoding in accordance with the above association table of indexes and calculate an expression index modulo 17, that is, 15n(17) to find a finite field element x=ay at an actual error location.

One input 661 is an expression index component 15σₐ(17). The other input 660 is an expression index component 15k(17) associated with the expression index of yₖ at a decoder 662 configured in accordance with the above table.

15σₐ(17) is converted into a binary representation at an index/binary conversion circuit 663. 15k(17) is converted into a binary number representation at an index/binary conversion circuit 664 and supplied onto buses (bs1, bs2) to obtain a sum at two 5-bit adders (17) 665a, 665b corresponding to 2 errors, respectively.

The inputs converted into binary numbers are calculated as residues modulo 17 at the adders 665a, 665b and the outputs therefrom are converted again into indexes at binary/index conversion circuits 667a, 667b and supplied onto the output buses (bs1, bs2) 669 as the expression index components 15n(17).

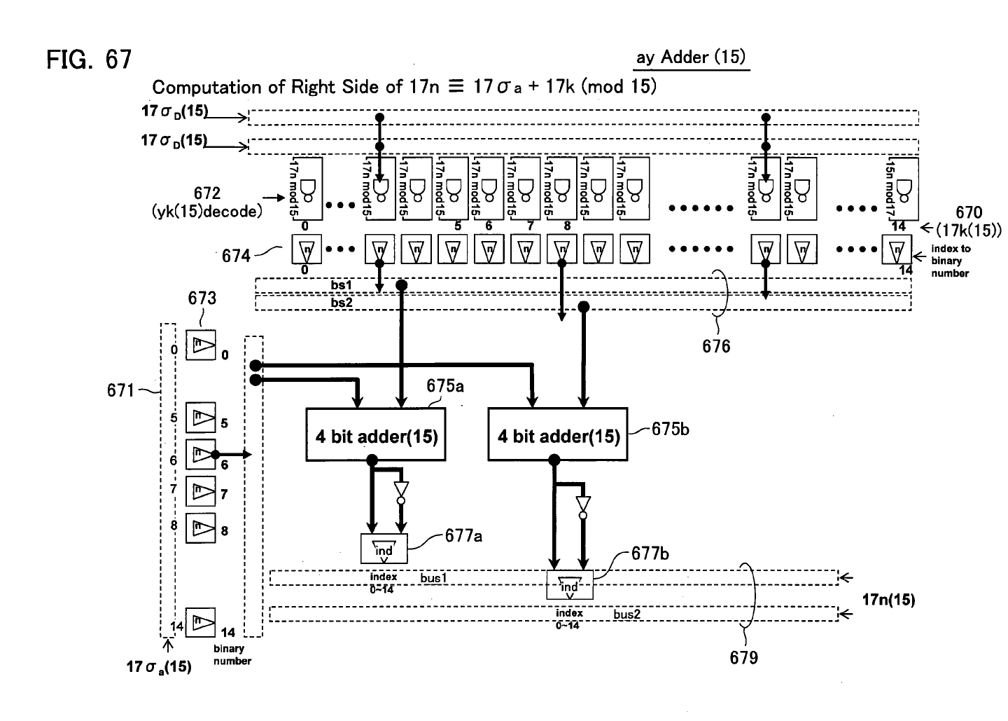

FIG. 67 shows another one of the adder circuits 34, that is, an ay adder (15) operative to search two errors y through decoding in accordance with the above association table of indexes and calculate an expression index modulo 15, that is, 17n(15) to find a finite field element x=ay at an actual error location.

One input 671 is an expression index component 17σₐ(15). The other input 670 is an expression index component 17k(15) associated with the expression index of yₖ at a decoder 672 configured in accordance with the above table. 17σₐ(15) is converted into a binary representation at an index/binary conversion circuit 673. 17k (15) is converted into a binary representation at an index/binary conversion circuit 674 and supplied onto buses (bs1, bs2) 676 to obtain a sum at two 5-bit adders (17) 675a, 675b corresponding to 2 errors, respectively.

The inputs converted into binary numbers are calculated as residues modulo 15 at the adders 675a, 675b and the outputs therefrom are converted again into indexes at binary/index conversion circuits 677a, 677b and supplied onto the output buses (bs1, bs2) 679 as the expression index components 17n(15).

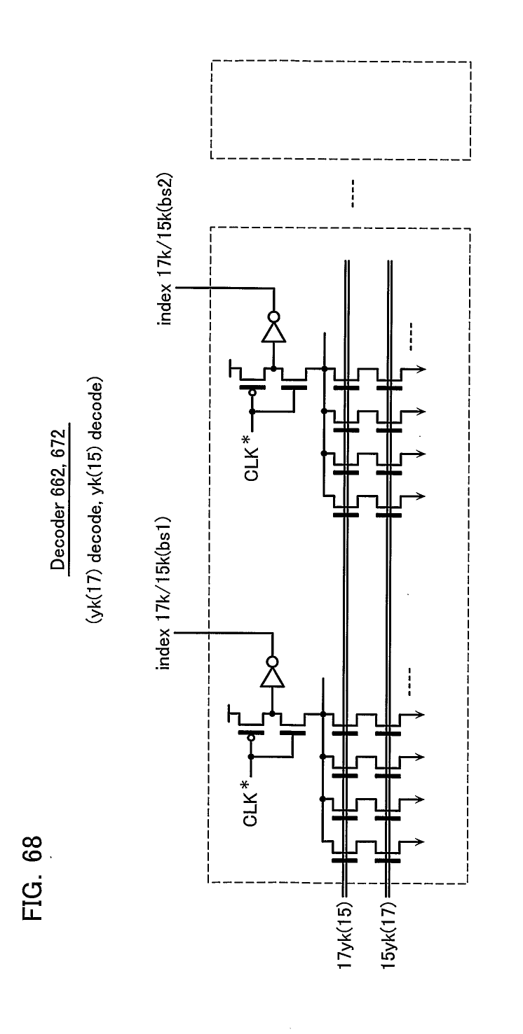

FIG. 68 shows a configuration of the decoders 662, 672 used in FIGS. 66 and 67. These are operative to convert an expression index of yₖ into an associated expression index of k and include a yₖ(17) decoding circuit and a yₖ(15) decoding circuit. As one yₖ corresponds to two k's, expression indexes of the k's are supplied onto the buses bs1, bs2.

An NAND connection having gate inputs of expression index components of yₖ, that is, 15yₖ(17), 17yₖ(15) is used to discriminate these expression indexes. In accordance with the above association table, they are NOR-connected in groups corresponding to the expression index components of the same k to discharge the nodes precharged with CLK* and inverted to generate expression index components of k, that is, 15k (17), 17k(15) on the buses.

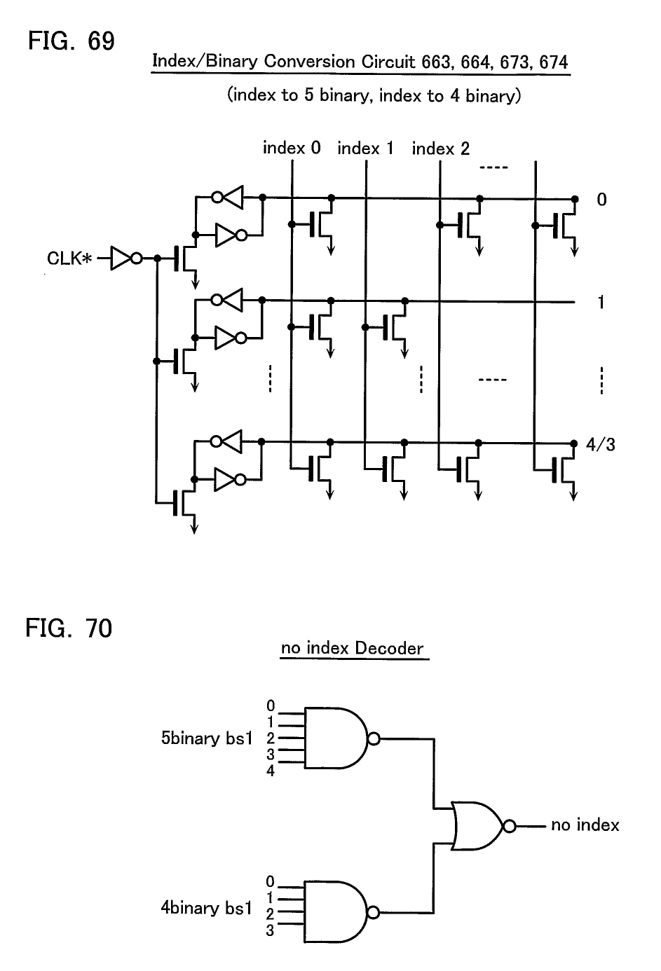

FIG. 69 shows a conversion circuit operative to convert a sum of expression indexes into a binary number representation suitable for a calculation in an adder, which is same as that described earlier.

FIG. 70 shows a decoder operative to generate a signal “no index” if there is no k associated with yₖ or if no solution can be obtained as one or two errors. If there is no association between indexes, then the index/binary conversion circuit provides an output of all “1”. Accordingly, it can be configured with an NAND circuit operative to detect this state.

The buses bs1, bs2 are always provided with signals simultaneously generated and accordingly it is sufficient for the decoder to monitor only the state of one bus bs1.

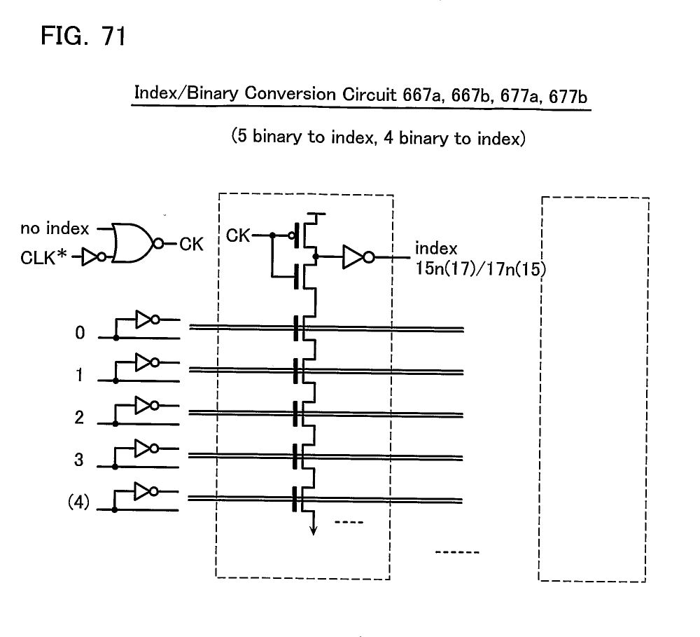

FIG. 71 shows a configuration of binary/index conversion circuits 667a, 667b, 677a, 677b for use in output sections of the adders 665a, 665b, 675a, 675b. The calculated results from the adders are indexes in binary representation and accordingly converted again into index signals in these circuits such that they can be utilized in calculations between indexes at the next stage.

When the signal “no index” is generated at the input, this conversion circuit is not activated and provides the output of all “0” indexes independent of the adder results.

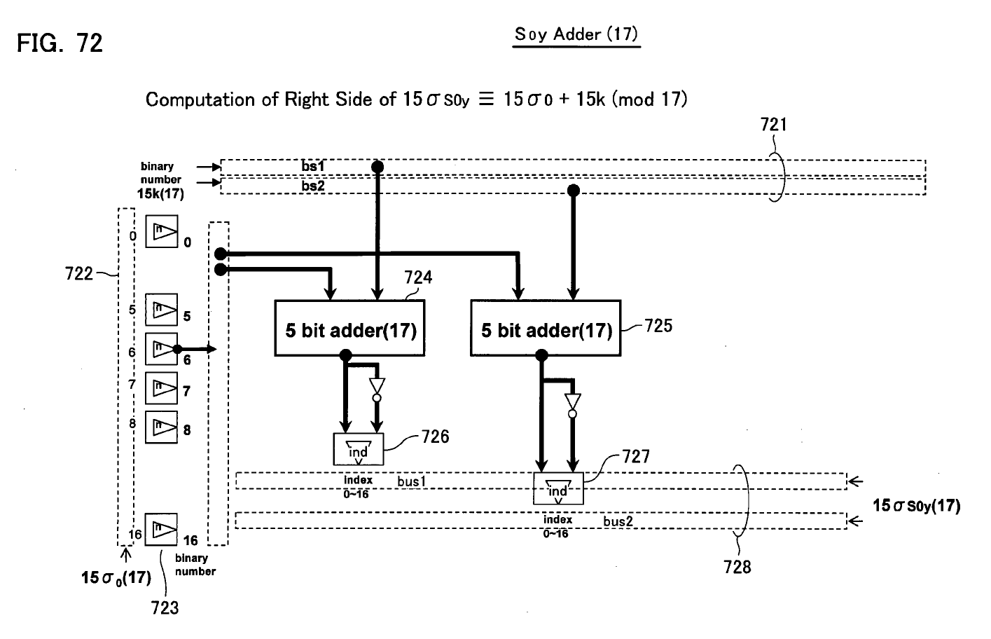

FIG. 72 shows one of the adder circuits 35, that is, an S_{0y} adder (17) operative to calculate an expression index modulo 17 of a finite field element S₀y required in correction of an error symbol.

One input 721 is a binary number representation of an expression index component 15k(17) output from the input decoder 662 used in the adder calculation for error location search and the other input 722 is an expression index component 15σ₀(17). As for the latter, the index is converted into a binary representation at an index/binary conversion circuit 723. 15k(17) is supplied onto the buses (bsl, bs2) 721 for additions at two 5-bit adders (17) 724, 725 corresponding to 2 errors.

These adders 724, 725 calculate them as residues modulo 17. The outputs therefrom are converted back to indexes at binary/index conversion circuits 726, 727 to obtain an expression index component 15σS0y(17), which is supplied onto the output buses (bus1, bus 2) 728.

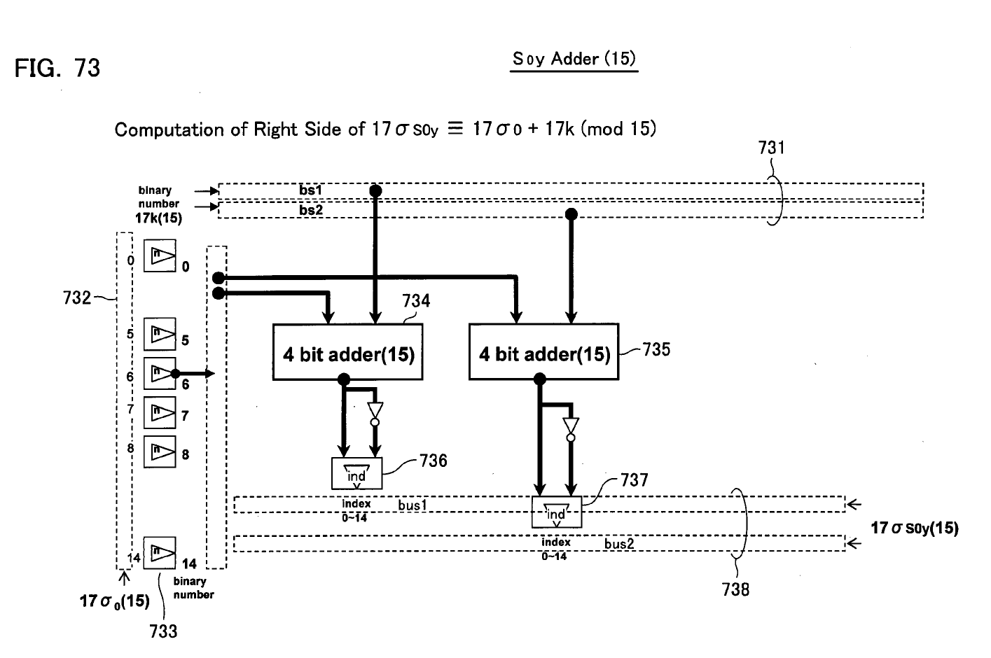

FIG. 73 shows another one of the adder circuits 35 of FIG. 3, that is, an S_{0y} adder (15) operative to calculate an expression index modulo 15 of the finite field element S₀y required in correction of an error symbol.

One input 731 is a binary representation of an expression index component 17k(15) or the output from the decoder 672 at the input section used in the adder calculation for error location search and the other input 732 is an expression index component 17σ₀(15). As for the latter, the index is converted into a binary representation at an index/binary conversion circuit 733. 17k(15) is supplied onto the buses (bs1, bs2) 731 for additions at two 5-bit adders (15) 734, 735 corresponding to 2 errors, respectively.

These adders 734, 735 calculate them as residues modulo 15. The outputs therefrom are converted back to indexes at binary/index conversion circuits 736, 737 to obtain an expression index component 17σS0y(15), which is supplied onto the output buses (bus1, bus2) 738.

### (Parity Check Unit for Symbol Error Calculation)

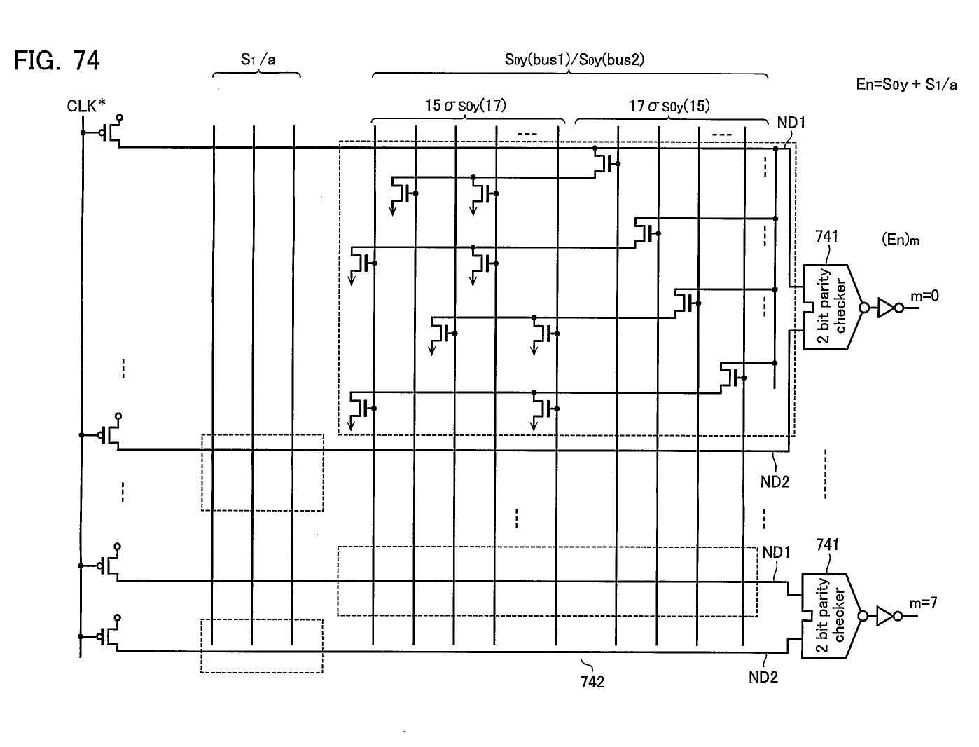

FIG. 74 shows circuitry of the parity checker 36 in FIG. 3, that is, a 2-bit parity checker 741 operative to calculate an symbol error En for correcting a symbol at an error location and an associated input decoder unit 742. The symbol error is represented by En=S₀y+S₁/a, which can be obtained at the 2-bit parity checker 741 by calculating a sum of the elements S₀y and S₁/a obtained at the adders. The calculation can be executed on the bus1, bus2, respectively.

The input signals to the parity checker are expression indexes of the elements S₀y and S₁/a. In association with these elements, there are nodes ND1, ND2 corresponding to m-th order coefficients. The nodes are precharged with the signal CLK*. A connection of an expression index signal on an m-th order node of each element to a transistor gate can be determined from the above association table of coefficients of elements in GF(256) and expression indexes.

For each m, 2 nodes ND1, ND2 from each element are subjected to parity check at the 2-bit parity checker 741 to obtain the m-th coefficient (En)ₘ.

### (Error Signal Generator)

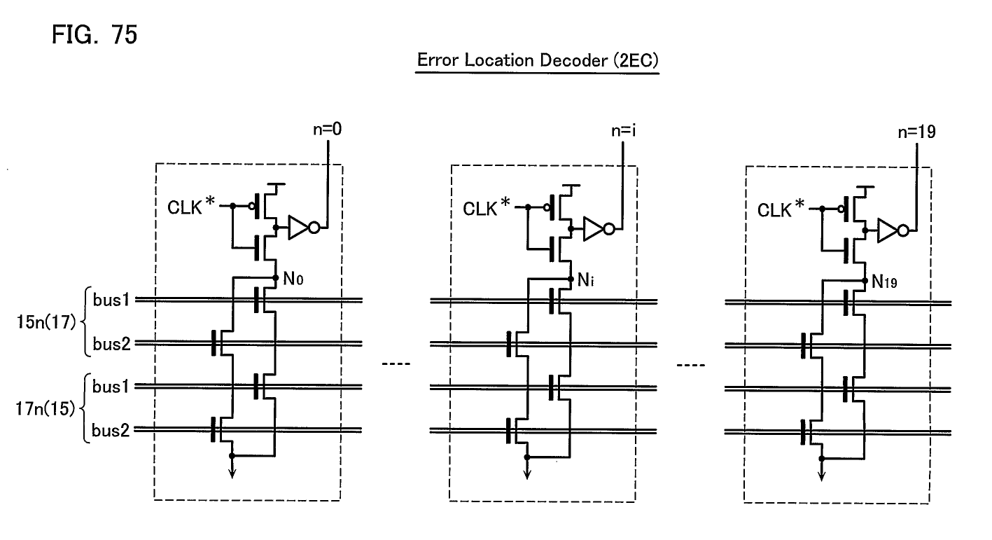

FIG. 75 shows a circuit (error location decoder) operative to generate an error signal at an error location in the case of 2 errors using expression indexes 15n(17), 17n(15) at an error location n obtained for the output buses bus1, bus2. Expression index components of n on the buses are NAND-connected to allow these expression indexes to be selected.

In order to generate a signal n=i (i=0-19) indicative of the occurrence of an error at a bit location i, the expression indexes on the buses bus1, bus2 are NAND-connected to selectively discharge nodes N0, . . . , N1, . . . N19 precharged with the clock CLK*. The state of the node is inverted to provide an output signal.

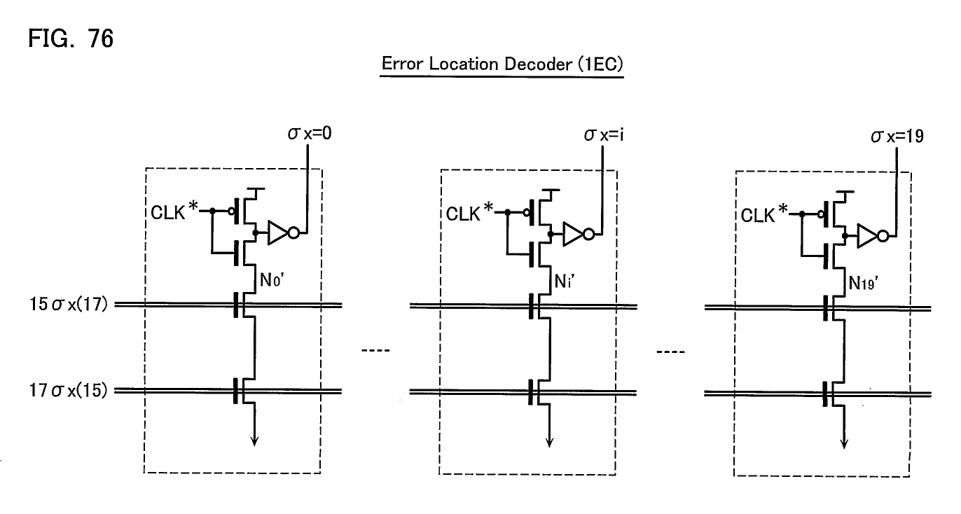

FIG. 76 shows an error location decoder in the case of 1 error. In this case, the error location is an element S₁/S₀ and an index is represented by σx. The expression indexes 15σx(17), 17σx(15) are used to generate a signal at an error location.

In order to generate a signal σx=i (i=0-19) indicative of the occurrence of an error at a bit location i, the expression indexes 15σx(17), 17σx(15) are NAND-connected to selectively discharge nodes N0′, . . . , N1′, . . . N19′ precharged with the clock CLK*. The state of the node is inverted to provide an output signal.

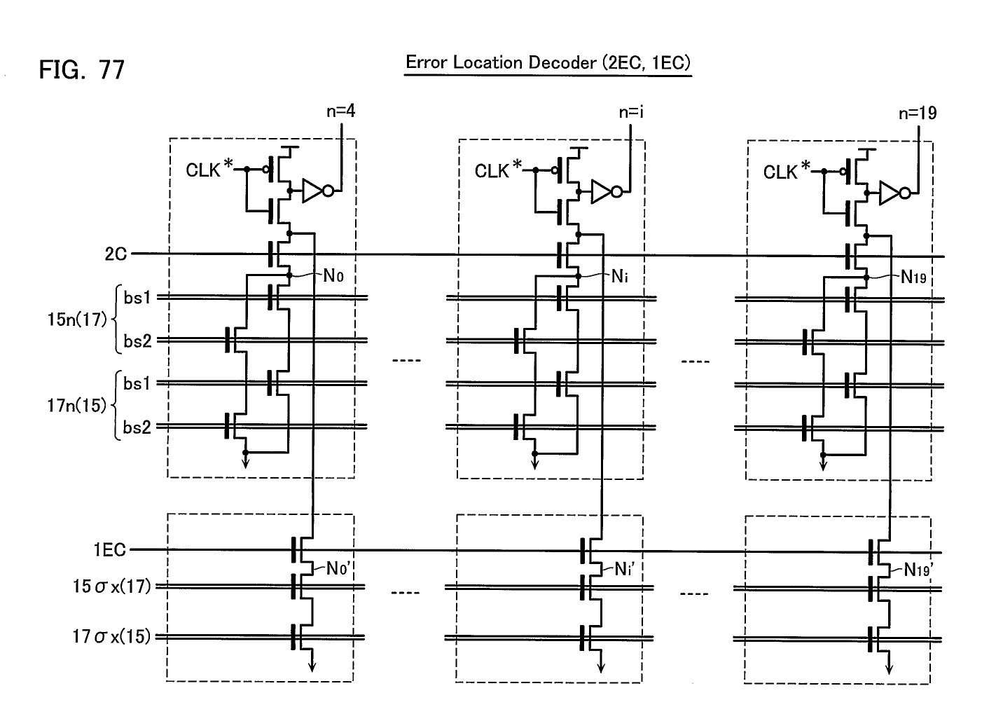

FIG. 77 shows an error location decoder including a combination of the error location decoder in the case of 2 of FIG. 75 with the error location decoder in the case of 1 error of FIG. 76. The error location computing system generates the signal 2C indicative of 2 errors and the signal 1EC indicative of 1 error. Accordingly, the two error location decoders are coupled switchable with these signals.

All the error locations i=0-19 are not required herein. If i=4-19 are used for calculations of information data as described later, then the error location decoders are required only 16.

### (Error-State Detection Circuit)

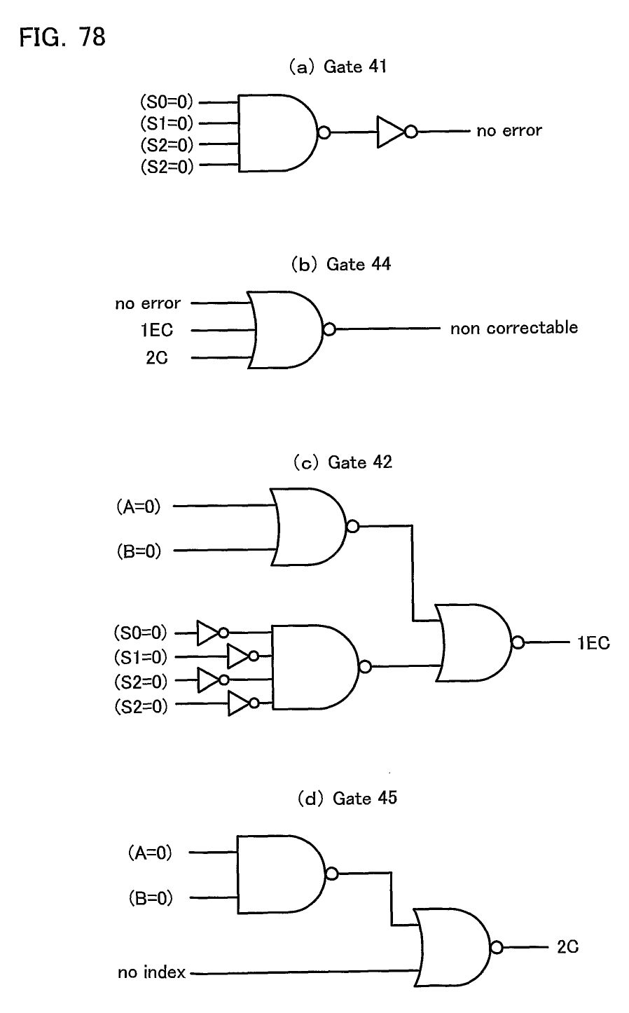

FIGS. 78(a)-(d) show error-state detecting gate circuits collectively.

FIG. 78(a) shows a gate circuit 41 operative to generate a no error signal if signals (S0=0), (S1=0), (S2=0), (S3=0) are all “1”.

FIG. 78(b) shows a gate circuit 44 operative to generate a non-correctable signal indicative of 3 errors or more and the impossibility of correction if the case is not related to no error (no error=“0”), 1 error (1EC=“0”), nor 2 errors (2C=“0”).

FIG. 78(c) shows a gate circuit 42 operative to generate a signal 1EC indicative of 1 error if (S0=0), (S1=0), (S2=0), (S3=0) are all “0” and either (A=0) or (B=0) is “1”.

FIG. 78(d) shows a gate circuit 45 operative to generate a signal 2C indicative of 2 errors if (A=0) and (B=0) are “1” and no index is “0”.

### (Error Code Correction Circuit)

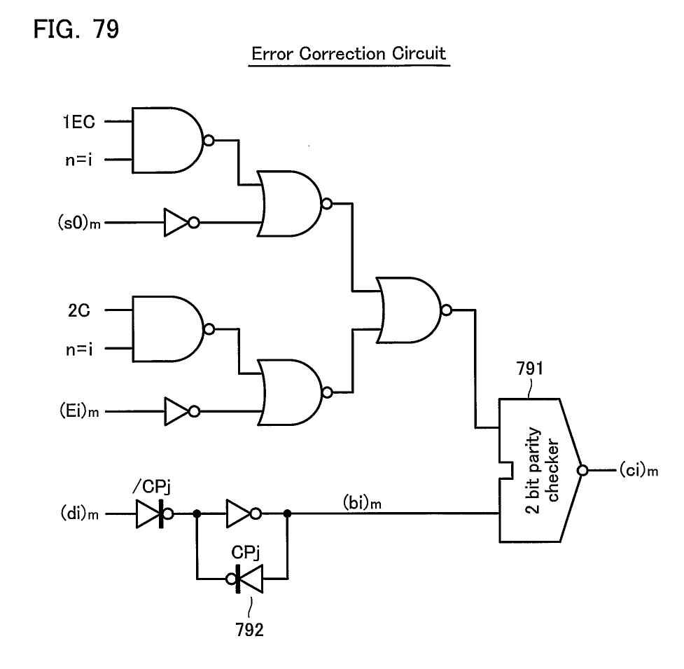

FIG. 79 shows an error code correction circuit operative to correct a code at a symbol location n. This correction circuit corresponds to the XOR gate G3 in the correction circuit 50 of FIG. 3 and includes a 2-bit parity checker 791 of 1 byte (m=0-7) for each error location i.

An error location is selected with a signal n=i (i=4-19). In the case of 1 error, the symbol error is S₀ and an error in each bit in the byte is determined with (s0)ₘ. In the case of 2 errors, a symbol error is determined with a symbol error Ei at an error location i and an error each bit is determined with (Ei)ₘ.

Each bit (di)ₘ contained in the byte of a coefficient symbol of ν(x) read out of the memory is held in a latch 792 with the clock CP in 5 cycles on a syndrome calculation. As the inversion of an exclusive OR of the latched data (bi)ₘ and the inverted data of (s0)ₘ or (Ei)ₘ, it is corrected in the parity checker 791 into a correct code bit (ci)ₘ.

(Reconstruction Method of Information Data Polynomial f(x))

The following description is given to a calculation method for restoring and reconstructing an information data polynomial f(x) from the corrected code polynomial c(x). This calculation corresponds to a reverse computation at the time of data input and utilizes a relation of Expression 6 (Expression 18) between coefficients of a polynomial.

As g₄=1={0, 0}, g₃=α⁷⁵={3, 0}, g₂=α²⁴⁹={12, 3}, g₁=α⁷⁸={14, 6}, g₀=α⁶={5, 12}, g₄ is a constant g₄=1, the following Expression 30 can be obtained.

aᵢ=cᵢ₊₄+g₃aᵢ₊₁+g₂aᵢ₊₂+g₁aᵢ₊₃+g₀aᵢ₊₄ [Expression 30]

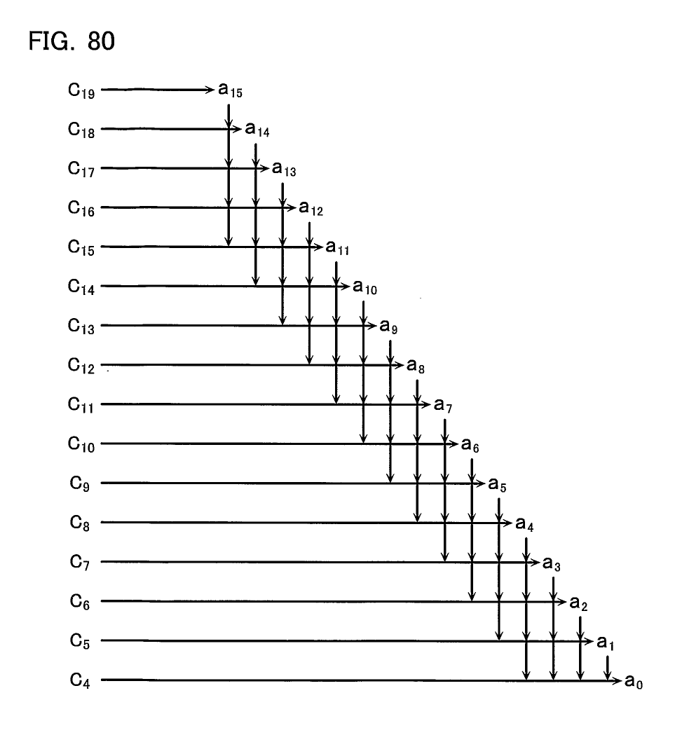

As cᵢ can be obtained in unison at the same time, the calculation method procedure shown in FIG. 80 is applied to derive aᵢ. Namely, aᵢ is sequentially derived beginning from a₁₅ at c₁₉ in descending order of i until all aᵢ can be derived. As a₀ can be derived from c₄, the calculation does not need c₃-c₀.

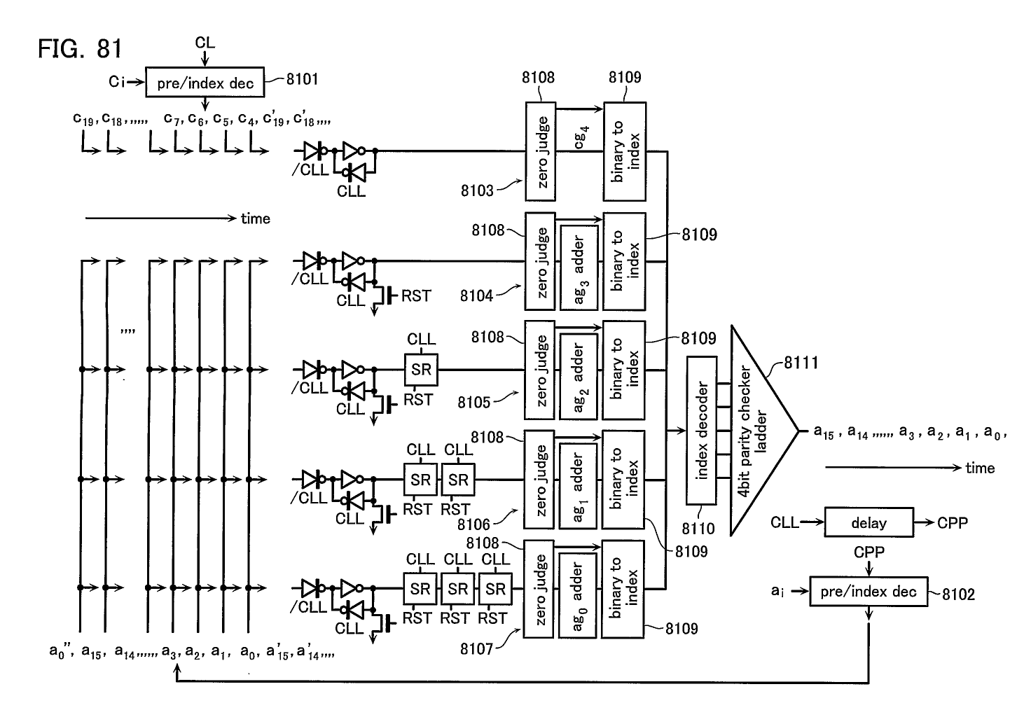

FIG. 81 shows a system for computing coefficients of a specific information polynomial f(x). As the corrected code is represented as a coefficient of pn(x), the code data cᵢ is converted into a binary number representation of an expression index at a pre/index decoder circuit 8101 in synchronization with the clock CL for use in providing data to external.

The order of this conversion is a descending order of i of cᵢ and the converted output is fed into a cg₄ adder system 8103. This system, however, includes no adder present therein because g₄=1.

1-cycle, 2-cycle, 3-cycle, 4-cycle delayed output results from the computing system are converted into expression indexes, which are fed into ag₃, ag₂, ag₁, ag₀ adder systems 8104, 8105, 8106, 8107. For that purpose, shift resisters SR are provided by a required number of stages.

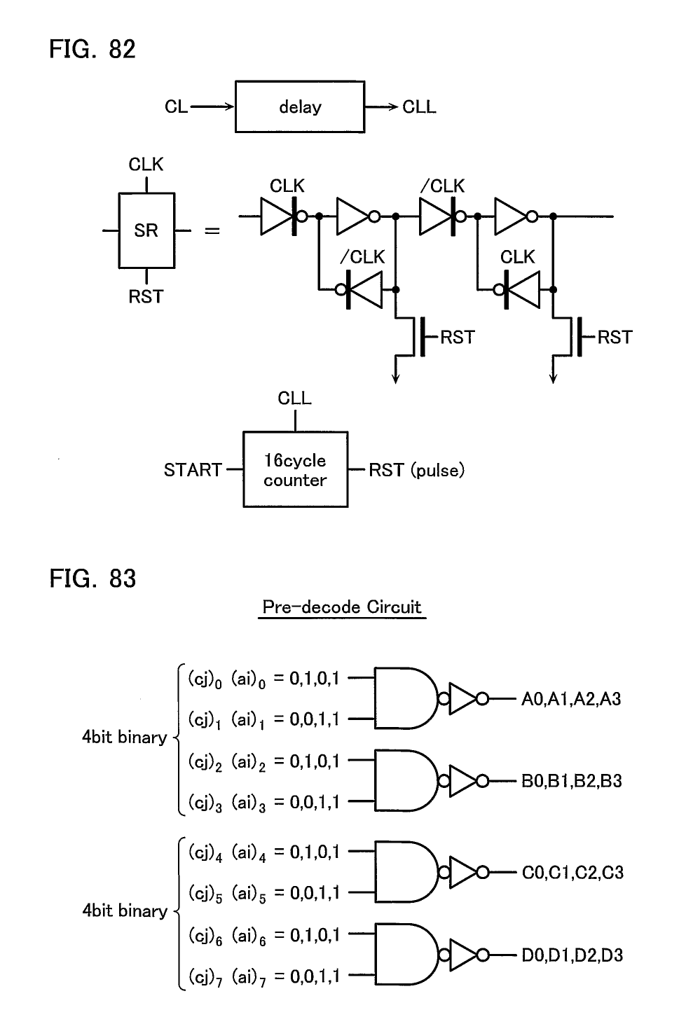

A latch and a computing system are driven with a clock CLL generated from the clock CL with a required delay circuit interposed as shown in FIG. 82. The latch arranged at the input stage is reset with a reset signal pulse RST to hold “0” at every 16 cycles of the clock CLL, for which a 16-cycle counter is prepared. The count of 16 cycles is started with a trigger signal START at the input cycle of c₁₉.

In each agᵢ adder system, a zero judge circuit 8108 judges whether or not the input element is a zero element. If it is a zero element, then independent of the result from the adder, the output index is made “0”. The adder calculates a sum of a binary representation of an input expression index and an expression index component of a constant gᵢ.

As the adder outputs are binary number representations, they are converted into expression indexes at binary/index conversion circuits 8109 and fed via an index decoder 8110 to a 4-bit parity checker 8111, which obtains a sum of the elements. Thus, aᵢ can be calculated in descending order of i.

The calculated aᵢ is fed back to the input of the computing system as a binary number representation of the expression index through a pre/index decoding circuit 8102, which is driven with a clock CPP generated with an appropriate delay from the clock CLL for use in driving the computing system.

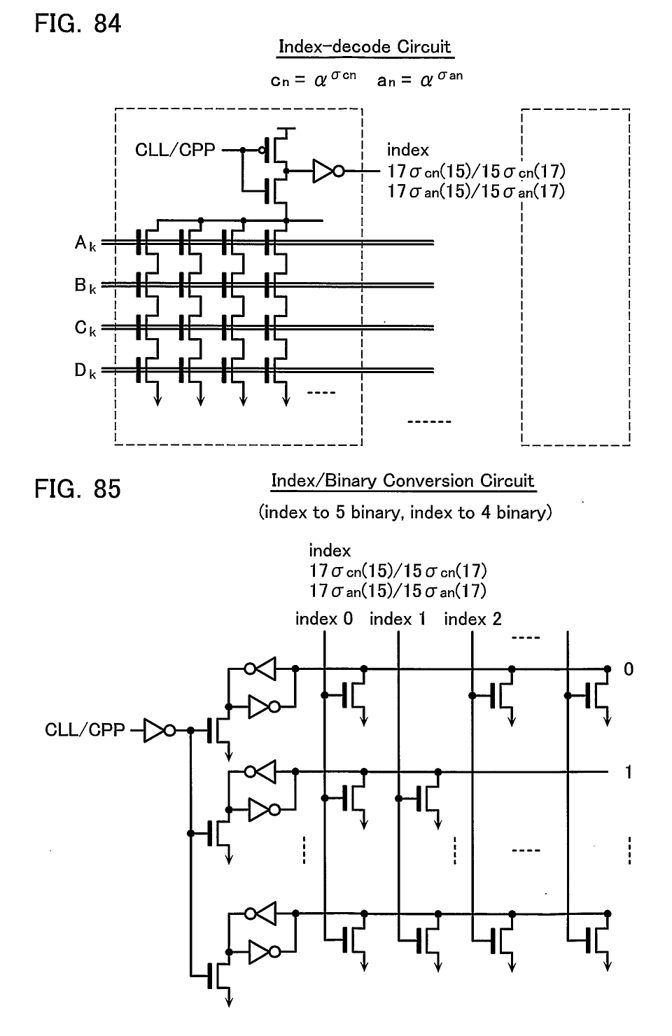

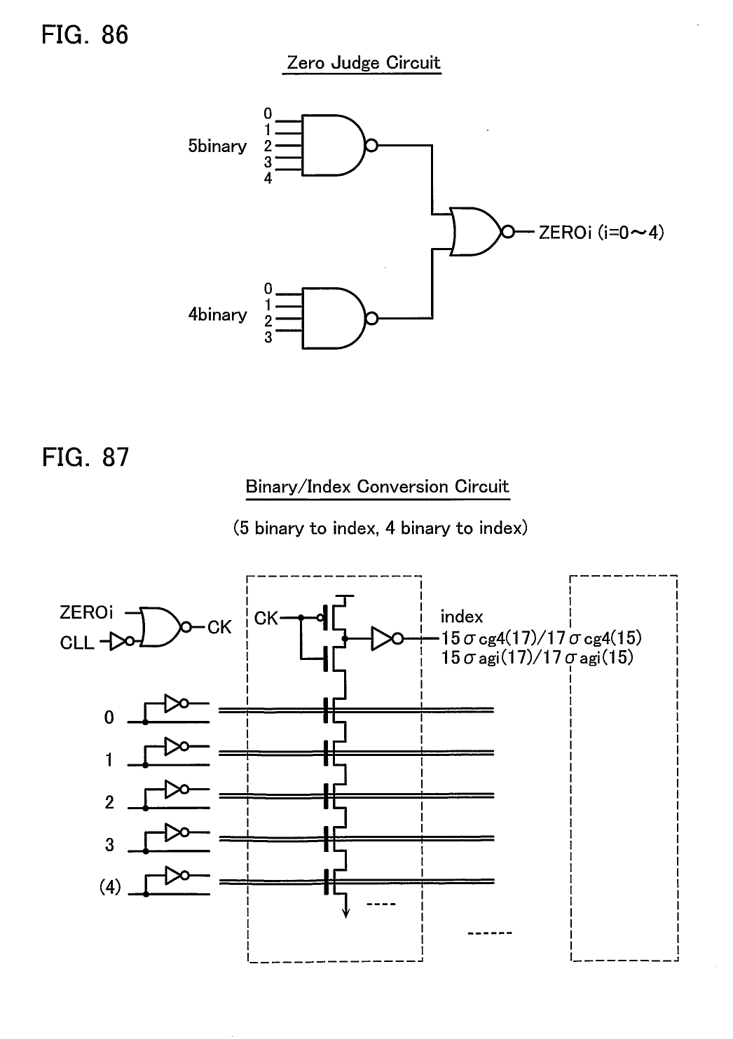

FIG. 83 shows a pre-decoding circuit in the pre/index decoding circuit 8101, 8102 at the input/output section of FIG. 81, FIG. 84 shows an index decoding circuit in the same, and FIG. 85 shows an index/binary conversion circuit operative to convert an index into binary in the same. FIG. 86 shows a specific configuration example of the zero judge circuit 8104 in each adder system.

The pre-decoding circuit in FIG. 83 generates a pre-decoded signal of each cᵢ, aᵢ in accordance with the above association table between coefficients of pn(x) and Ai, Bi, Ci, Di.

The index decoding circuit in FIG. 84 receives Ak, Bk, Ck, Dk, which are NAND-connected in accordance with the table, grouped and NOR-connected to generate each component of an expression index in synchronization with the clock CLL or CPP.

The index/binary conversion circuit in FIG. 85 converts the output from the index decoding circuit into a 4 binary or 5 binary representation in synchronization with the clock CLL or CPP. Namely, a component modulo 17 is converted into binary data of 5 bits, and a component modulo 15 into binary data of 4 bits.

The zero judge circuit in FIG. 86 generates a signal ZEROi if data is a zero element with A0, B0, C0, D0=“H”. In this case, i is equal to 0-4 in association with those of gᵢ. In the case of a zero element, the index decoding circuit also has no associated decoding, the index exhibits all “0”.

FIG. 87 shows a configuration of a binary/index conversion circuit 8109 operative to convert again the binary value output from each adder system into an expression index. If the input to the adder is a zero element, it keeps internal nodes precharged to hold the index at “0” in synchronization with the clock CLL.

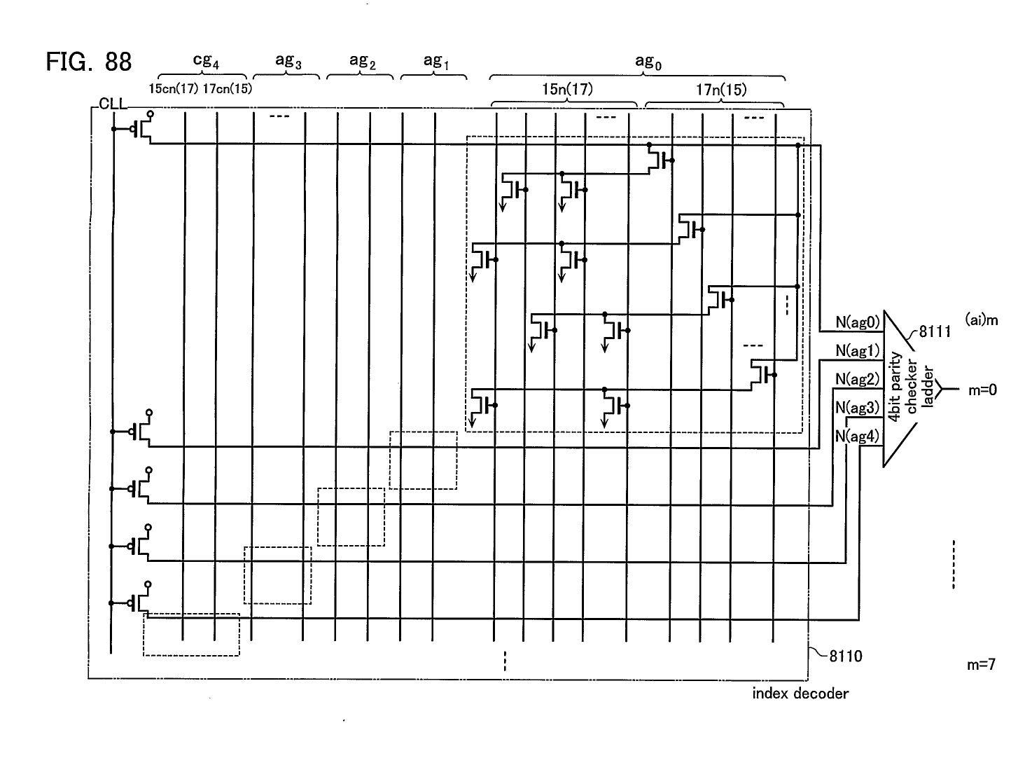

FIG. 88 shows a configuration of an index decoder 8110 at the input section of a 4-bit parity checker/ladder 8111 operative to calculate aᵢ=cᵢ₊₄+g₃aᵢ₊₂+g₂aᵢ₊₂+g₁aᵢ₊₃+g₀aᵢ₊₄ using the above association table between coefficients of elements in GF(256) and expression indexes.

Inputs signals are expression indexes of elements cg₄, ag₃, ag₂, ag₁, ag₀. There are nodes N(cg4), N(ag3), N(ag2), N(ag1), N(ag0) corresponding to m-th order coefficients for the these elements. These nodes are precharged with the signal CLL. A connection of an expression index signal on an m-th order node of each element to a transistor gate can be determined from the table.

For each m, 5 nodes from each element are subjected to parity check at the 4-bit parity checker/ladder 8111 to obtain an m-th order coefficient of aᵢ, that is, (aᵢ)ₘ.

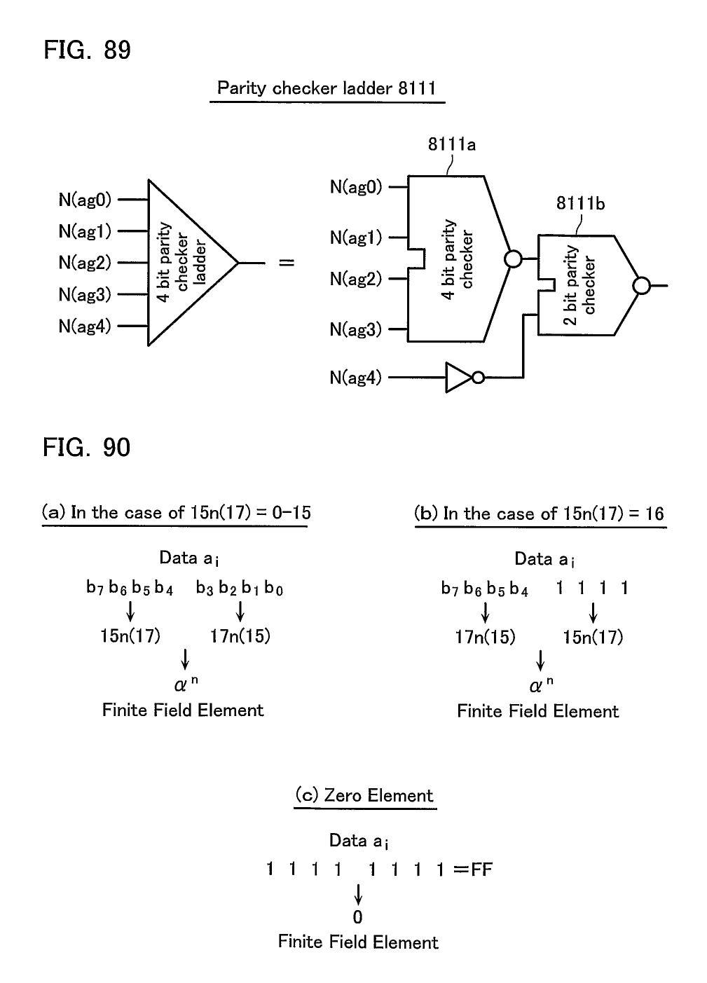

FIG. 89 shows a configuration example of the 4-bit parity checker/ladder 8111 having 5 inputs. 4 inputs from the nodes N(ag0)-N(ag3) are fed to a 4-bit parity checker 8111a and the output therefrom and the inverted output from the node N(cg4) are fed to a 2-bit parity checker 8111b.

### [Description of Case C.2]

The following description is given to the method of the case C.2 for reducing the number of decoding circuits between coefficient representations of pn(x) and index representations, or the part having the largest circuitry scale in the case C.1 previously described. The case C.2 regards external data as binary representations of expression indexes of elements in GF(256) to increase the parts computable without decoding. It stores codes in the memory as binary representations of expression indexes on a byte basis.

Only the parts changed from the case C.1 are described below specifically.

Although it is simple as operational processing, the part with an increased circuitry scale is a circuit for converting representations as coefficients of pn(x) of elements in GF(256) into expression indexes obtained from indexes of α. This part requires 512 or more index decoder circuits at the input section for conversion between 256 pieces of 8-bit data and residues modulo 17 and residues modulo 15.

In order to reduce the number of index decoders, it may be considered to regard information data as expression indexes of finite field elements themselves. Binary representations of expression indexes at every component require 5+4=9 bits though 17 and 16 in binary representation do not use all bits fully. Accordingly, byte data can be associated with a binary representation of an expression index. The associating method is shown in FIG. 90.

As shown in FIG. 90(a) if the expression index component 15n(17) is equal to 0-15, then byte data is divided by 4 bits. In this case, the lower 4-bit part is regarded as a binary representation of the component 17n(15) and the upper 4-bit part as a binary representation of the component 15n(17).

As shown in FIG. 90(b), if the expression index component 15n(17) is equal 16, the component 17n(15) can not exhibit 1111. Accordingly, the roles of the lower part and the upper part are swapped. In this case, if the lower part exhibits 1111, then the upper part is regarded as a binary number representation of the component 17n(15) and the lower part as a binary number representation of the 15n(17).

As an expression index has no binary representation representative of a zero element, a byte FF not associated with the binary representation of the expression index is used as a zero element as shown in FIG. 90(c).

As above, once the information data is associated with the expression index, a simple byte-processing multiplexer can be arranged to greatly reduce the circuitry scale instead of providing the index decoder at the input section.

The code generation calculation is not different from the case C.1. Namely, a coefficient cᵢ of c(x) is used to calculate cᵢ=g₄aᵢ₋₄+g₃aᵢ₋₃+g₂aᵢ₋₂++g₀aᵢ. As described above, aᵢ is represented by an expression index and g₄={0,0} g₃=α⁷⁵={3,0}, g₂=α²⁴⁹={12,3}, g₁=α⁷⁸={14,6}, g₀=α⁶={5,12}, all can be processed through calculations between expression indexes.

α^{m}αⁿ=α^{m+n} may be represented by expression indexes as {15m(17), 17m(15)} {15n(17), 17n(15)}={15(m+n)(17), 17(m+n)(15)}={15m+15n(17), 17m(15)+17n(15)}. Namely, a product can be calculated as a sum of expression indexes. A sum of finite field elements is executed at a parity checker using expression indexes. A cᵢ as a sum can be obtained as a coefficient representation of a residue polynomial pn(x) of a finite field element.

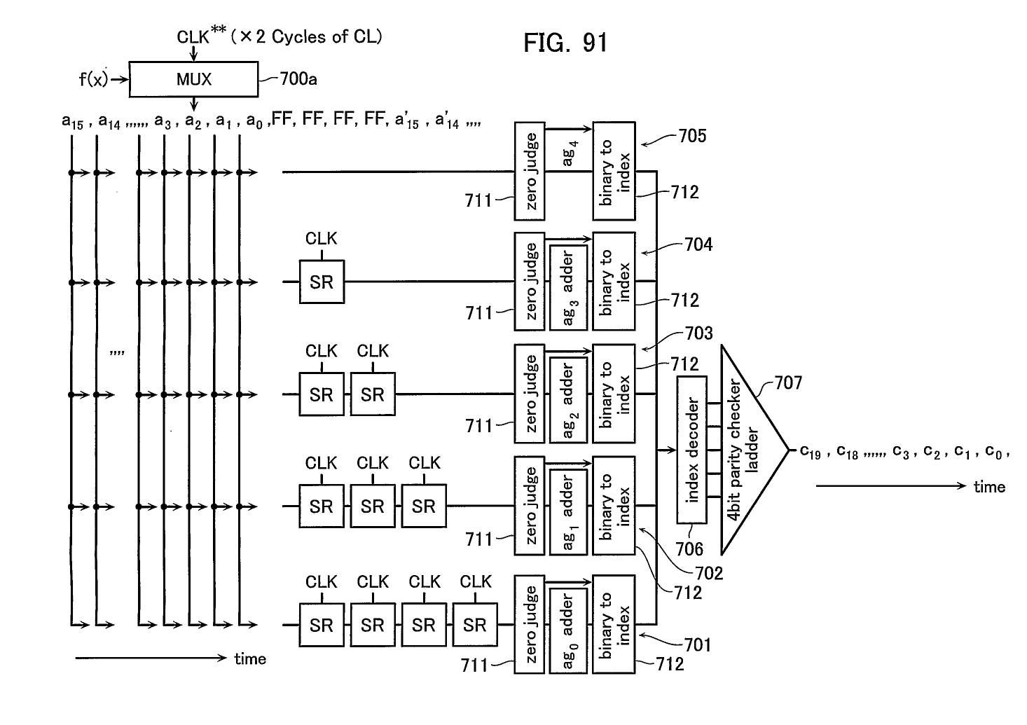

FIG. 91 shows a specific system for code calculation.

External data f(x) is taken in with the clock CL. A clock CLK** with a doubled speed and doubled cycles than the clock CL may be used to operate a multiplexer (MUX) circuit 700a to yield a binary representation of an expression index. This is because taking external data requires 16 cycles while processing in a computing system requires 20 cycles. Namely, it corresponds to the fact that f(x) is a 15th order polynomial while c(x) is a 19th order polynomial.

The computing system in FIG. 91 differs from the code computing system in the case C.1 shown in FIG. 7 in that a MUX circuit 700a is used instead of the pre/index decoder 700 in FIG. 7, and leaves others unchanged from FIG. 7. Therefore, the parts corresponding to those in FIG. 7 are denoted with the same reference numerals and omitted from the following detailed description. The shift resister SR and the clock circuit in FIG. 91 are similar to those in FIG. 8 as well.

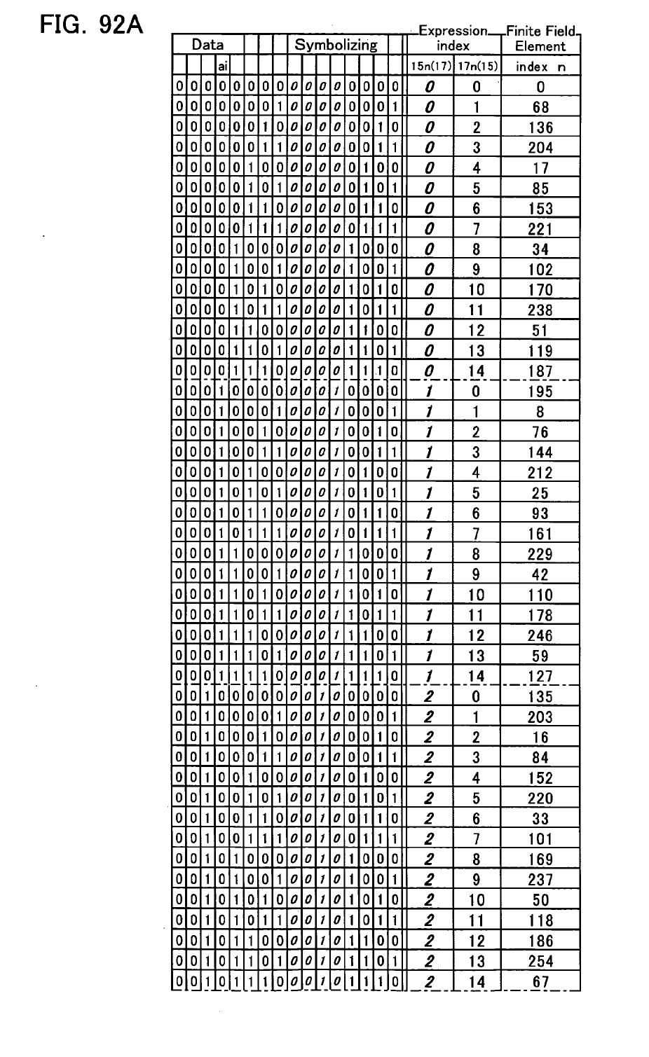

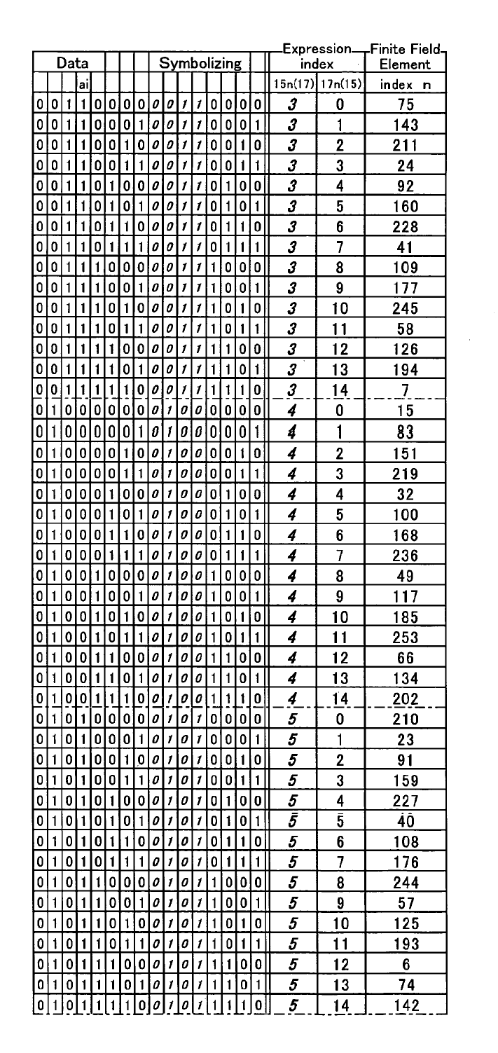

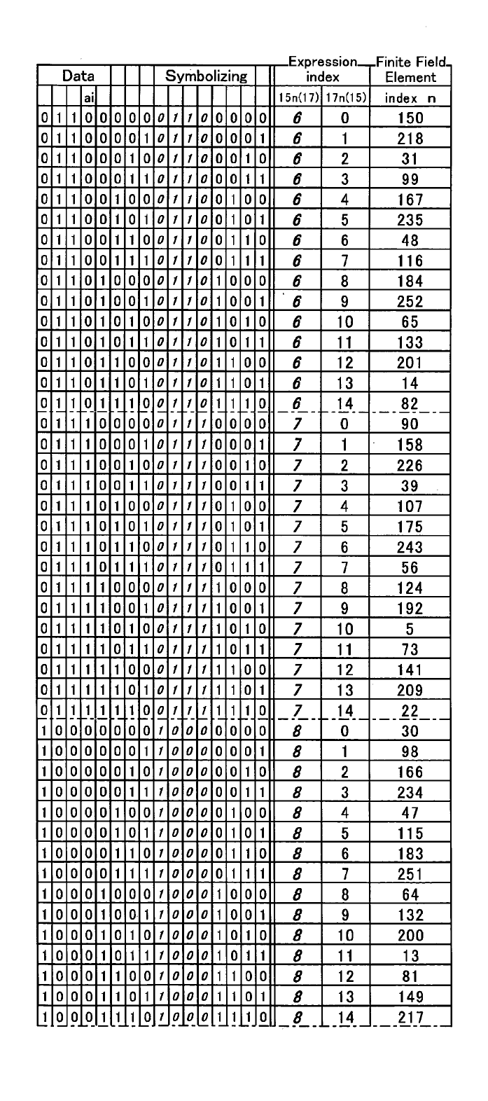

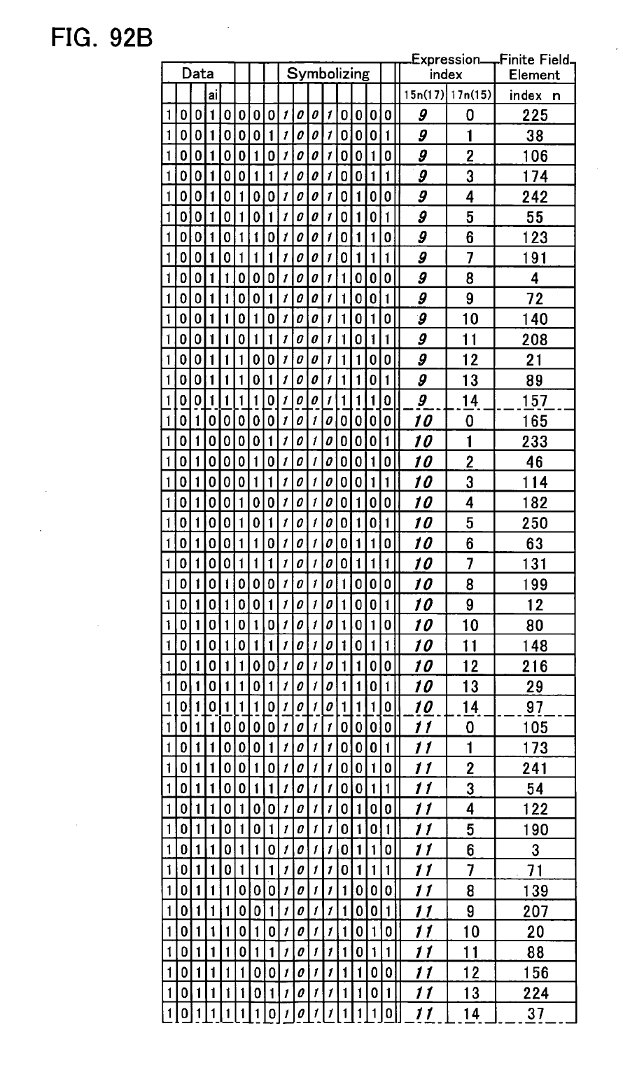

FIGS. 92A and 92B are tables collectively showing relations among external byte data used in the MUX circuit 700a for use in the above c(x) computing system, expression indexes associated with symbolization thereof, and finite field elements. Associations with all 256 finite field elements are shown though the multiplexer may be simply configured with a reduced circuitry scale because there is little variation in bit data.

FIGS. 93 and 94 show a data symbolizing circuit or a symbol MUX circuit and a zero judge circuit.

Latching byte data in synchronization with the clock CLK**, the symbol MUX circuit generates a signal SWAP=“1”, as a bit bm inside the computing system, if the lower part is F. When the signal SWAP=“1” is generated, 4 bits of the upper part b₄-b₇ and 4 bits of the lower part b₀-b₃ in the byte data are swapped to form a binary representation of an expression index. In this case, the binary representation of an expression index component 15n(17) is made all “0” except 15n(17)b₄.

The zero judge circuit generates the signal ZEROi if the binary representation of the expression index component 15n(17) obtained through multiplexing is F because the input data is a zero element symbol. In FIG. 94, i corresponds to i in gᵢ. CLK* corresponds to CLK** in 16 cycles and is the CLK* in the absence of the signal RS generated at the 17th cycle of CLK**. The latch is reset to “1” by RS, and accordingly in 17-20 cycles of CLK**, the bit bₘ corresponds to the input being FF.

In the case C.2, data to be stored in the memory is symbol data, or a binary representation of an expression index associated with byte data. This is effective to reduce the number of index decoders required in parallel computations of syndromes. As data reading requires an increased speed, syndrome computations are executed in parallel, if possible. In this case, parallel computations require corresponding index decoders and this part requires a vast circuitry scale. In the case C.2, therefore, in order to eliminate the index decoders from this part, data to be stored in the memory is symbol data such that data read out of the memory becomes an expression index.

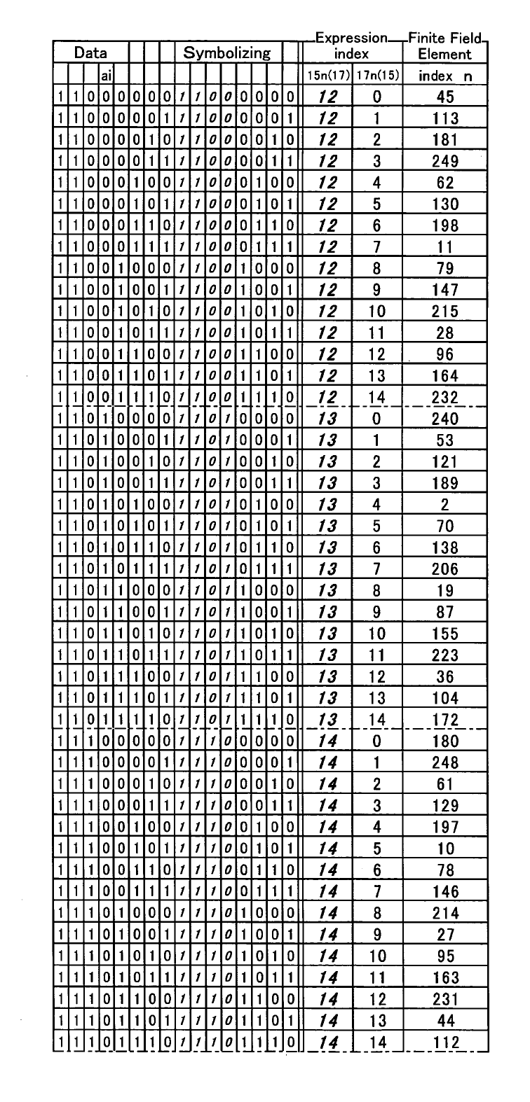

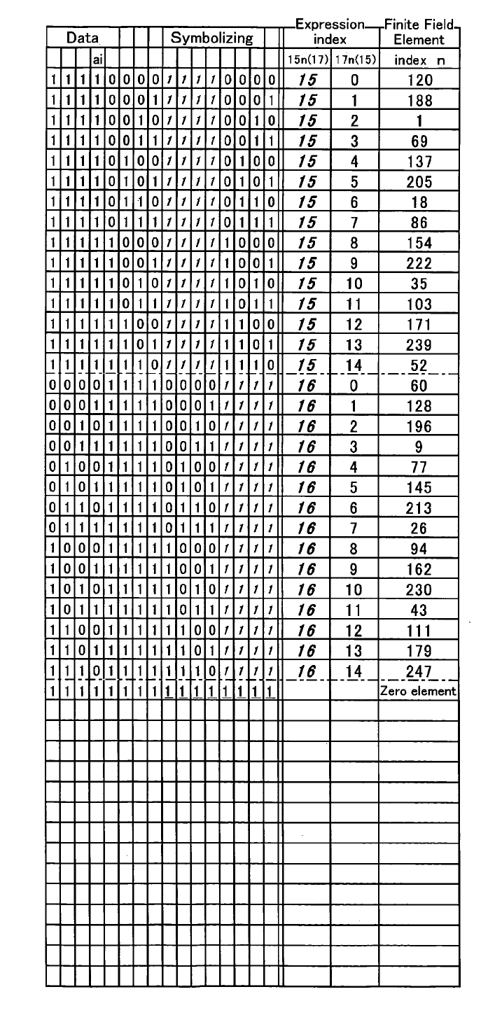

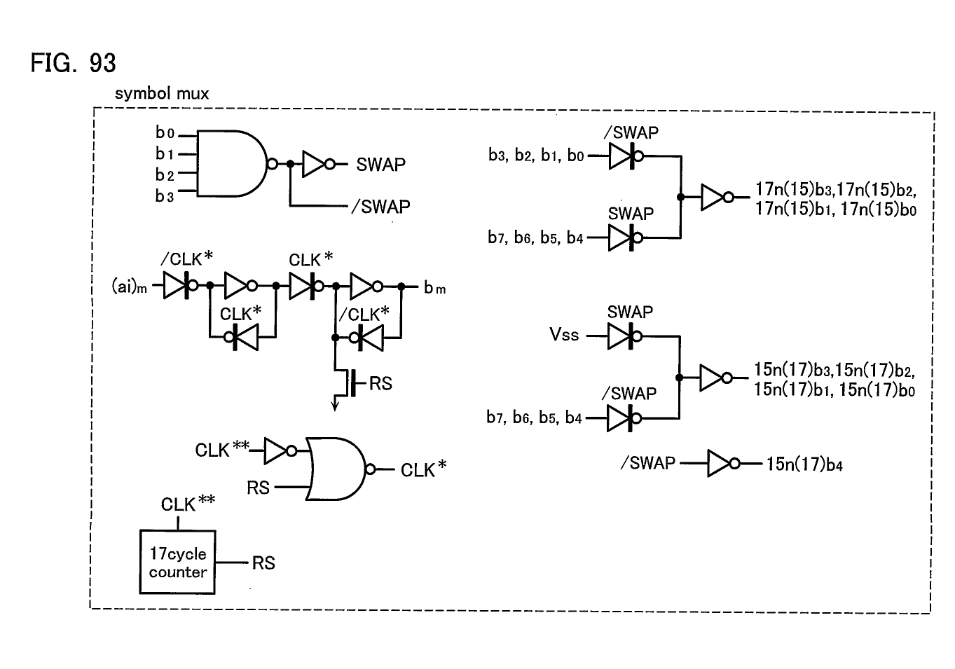

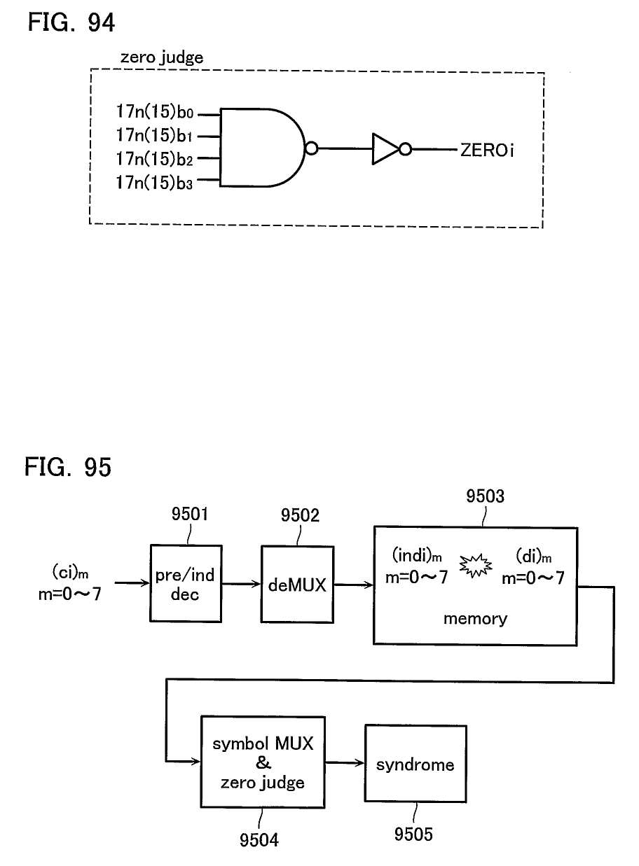

FIG. 95 shows the brief for storing a finite field element in the memory as symbol data of an expression index. At the input, an encoded result or code data is represented as a coefficient of pn(x), that is, (cᵢ)ₘ (m=0-7). Accordingly, this section requires a pre/index decoder circuit 9501 operative to convert the coefficient into a binary representation of an expression index, and a de-multiplexer (deMUX) circuit 9502 operative to convert the output data of 9 bits back to byte symbol data.

This system executes the conversion at every cycle on a byte basis and accordingly only an index decoder in one system is required. The output from the deMUX circuit 9502 is byte symbol data (indi)ₘ. If this data causes an error in the memory 9503, then byte symbol data read out thereof becomes (di)ₘ.

Before the data read out of the memory is fed into a syndrome arithmetic unit 9505, it is passed through a symbol MUX and zero judge circuit 9504 to convert (dᵢ)ₘ into a binary representation of an expression index.

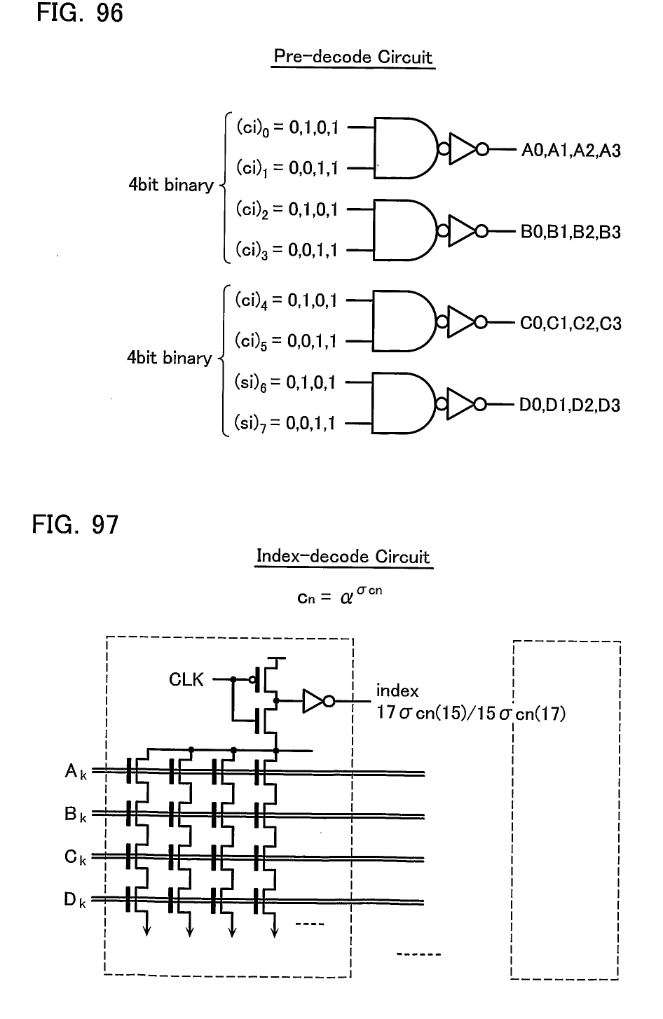

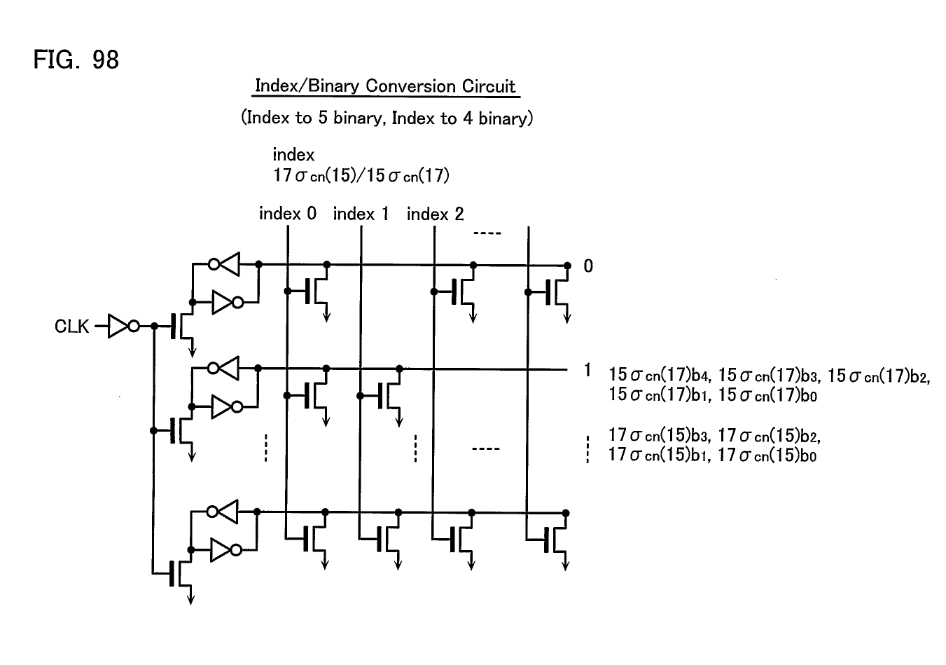

FIGS. 96 and 97 show a pre-decoding circuit and an index decoding circuit in the pre/index decoding circuit 9501. FIG. 98 shows an index/binary conversion circuit at the output section in the index decoding circuit.

The pre-decoding circuit in FIG. 96 generates a pre-decoded signal of each code cᵢ in accordance with the above association table of coefficients Ai, Bi, Ci, Di of the residue polynomial pn(x). The index decoding circuit in FIG. 97 receives Ak, Bk, Ck, Dk, which are NAND-connected in accordance with the table, grouped and NOR-connected to generate each component of an expression index in synchronization with the clock CLK.

The index/binary conversion circuit in FIG. 98 converts the output from the index decoding circuit into a binary representation in synchronization with the clock CLK. For that purpose, it converts a component modulo 17 into binary data of 5 bits and a component modulo 15 into binary data of 4 bits. If data is a zero element, A₀, B₀, C₀, D₀ are at “H”. Accordingly, the index decoding circuit has no associated decoding and provides an index of all “0”. Therefore, the binary representation of the expression index exhibits FF.

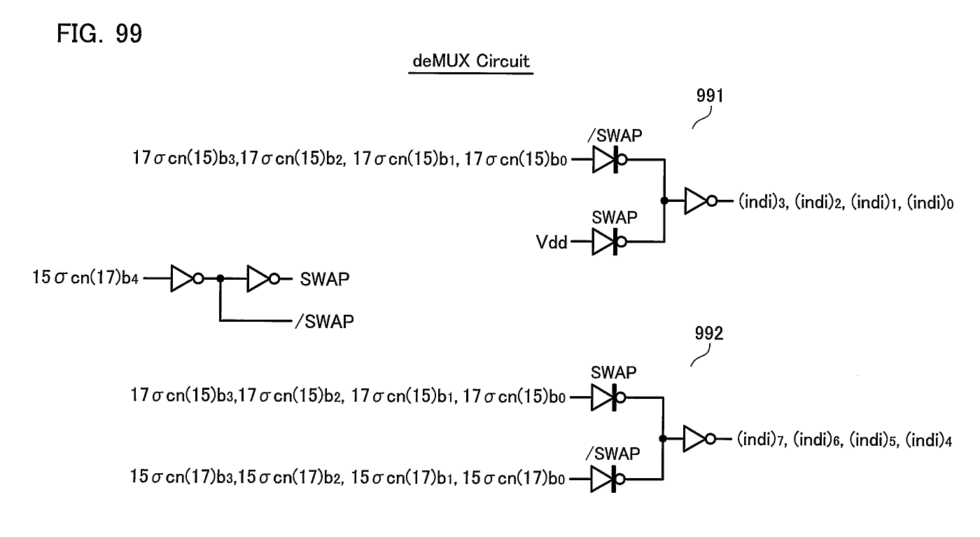

FIG. 99 shows a configuration of a conversion circuit for writing a binary representation of an expression index in the memory as byte symbol data, that is, the deMUX circuit 9502. It generates signals SWAP=“1”, /SWAP=“0” when an expression index component 15σcn(17)=16 to switch the binary representation of the expression index component 15σcn(17) from the lower 4-bit part of byte data to the upper 4-bit part by switching circuits 991, 992. The lower part (indi)ₘ(m=0-3) is connected to Vdd to exhibit all “1”. As for cᵢ or a zero element, the binary representation of the expression index is FF and accordingly the byte symbol data also becomes FF.

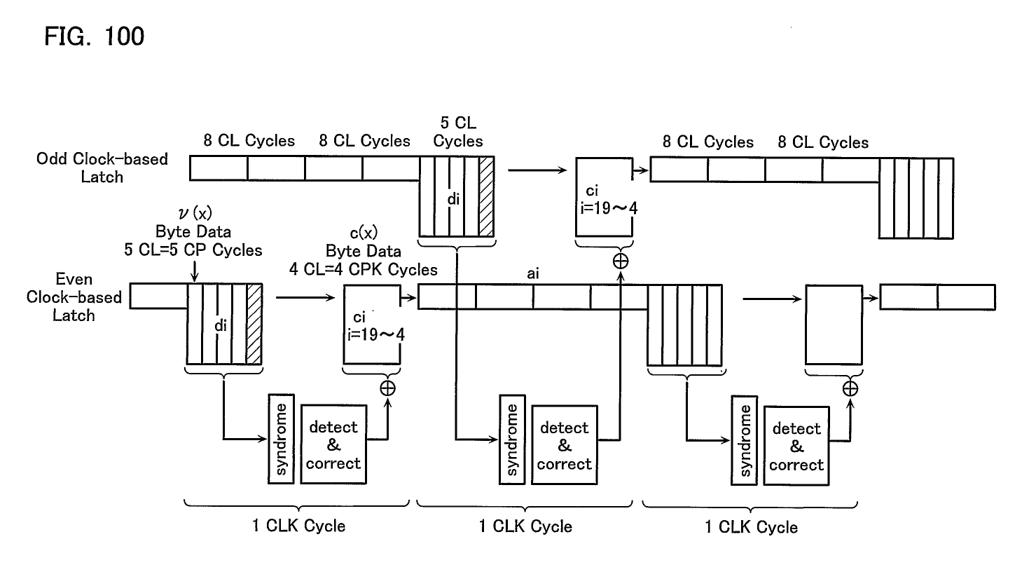

Next, a timing synchronization relation in reading data out of the memory is described with reference to FIG. 100. This is basically same as the case C.1 in FIG. 28. Storage places for data read out of the memory are prepared as 20-byte data registers in 2 systems. One is referred to as an even clock data latch system and the other as an odd clock data latch system. The registers in the 2 systems are used in an interleaved manner to provide data without a break. Hereinafter, the even clock system and the odd clock system are referred to as an ECL system and an OCL system, respectively.

The types of clocks are mainly two. One type is used for data transfer, and includes a clock CL for providing data, a clock CP having the same period but generated intermittently at every 5 cycles collectively for reading data out of the memory, and a clock CPK generated intermittently at every 4 cycles collectively after calculation for error location search and error correction. Another is a clock CLK for driving the ECC system, of which 1 cycle corresponds to 16 cycles of the clock CL.

Either the ECL system or the OCL system is used first.

20-byte data dᵢ (i=19-0) is read out of the memory by 4 bytes in 5 CP cycles and held in each latch in the data register in the ECL system and subjected to a syndrome calculation. From the syndrome, an error location and a symbol error are calculated and, through a computation of the result therefrom and the data in each latch, code data cᵢ (i=19-4) is newly overwritten in the latch in 4 CPK cycles.

Code data c₃-c₀ is not used in correction to information data. Thus, ECC in 1 CLK cycle is finished. Next, the code cᵢ overwritten in the latch is used to sequentially calculate information data aᵢ (i=15-0) in synchronization with clock CL and provide it to external.

While the ECL system is used to provide information data to external, next 20-byte data is read in the OCL system to execute similar operation. Thus, an interleaved operation is executed with the data registers in 2 systems such that one executes syndrome calculation and error checking and correction while the other simultaneously provides corrected information data to external.

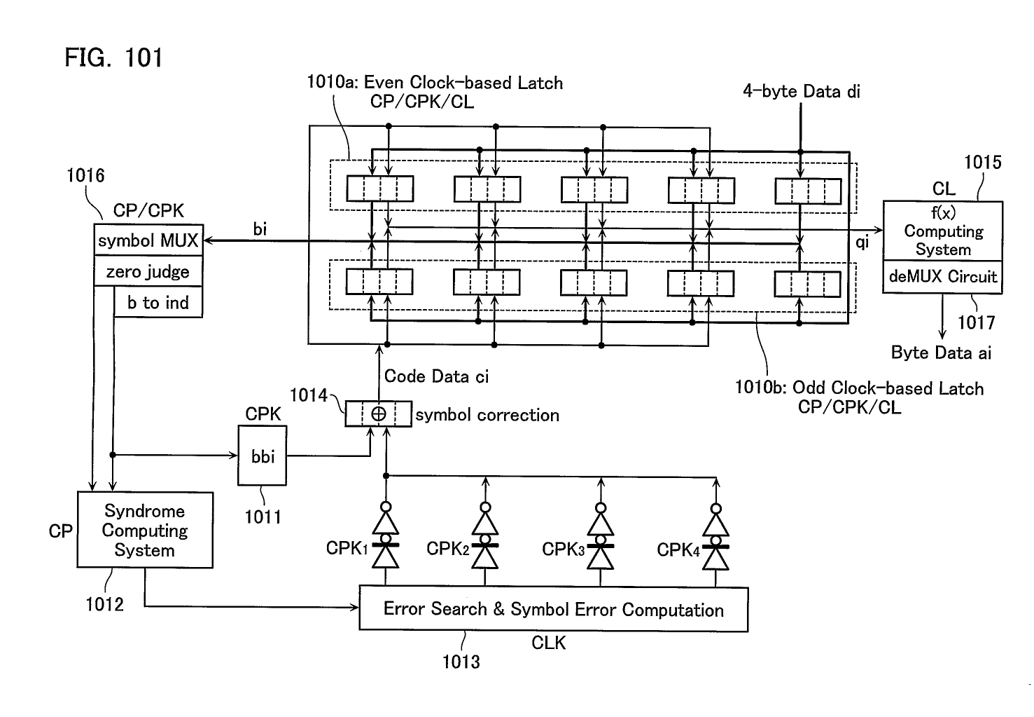

FIG. 101 is used to describe relations among data, clock and latch operations as a data flow. As shown, data latches in 2 systems, that is, an ECL-based data latch 1010a and an OCL-based data latch 1010b are provided in parallel.

Data dᵢ stored in the memory is read out by 4 bytes in synchronization with clock CL. At this time, the clock is activated only in either one of the ECL-based latch and the OCL-based latch, which are discriminated with superscripts “e”, “o” attached to the names of the clocks. When signals must be distinguished from each other at cycles of a clock, numerical subscripts are attached thereto. First, consideration is given to the case where data is stored in the ECL-based latch.

The ECL-based data latch 1010a stores data by 4 bytes in synchronization with clocks CP^{e}₀, CP^{e}₁, CP^{e}₂, CP^{e}₃, CP^{e}₄ and sends out data bᵢ simultaneously by 4 bytes to a symbol MUX circuit 1016. During this period, the OCL-based data latch 1010b sends out each data as qᵢ in synchronization with a clock CL° to an f(x) computing system 1015 for data output.

The case C.2 requires a conversion of data represented by the binary representation of the expression index into byte symbol data as the original information data. Therefore, a deMUX circuit 1017 is provided at the output section in the f(x) computing system 1015.

The symbol MUX circuit 1016 includes a zero judge circuit and a binary/index conversion circuit to convert data bᵢ into a binary representation of an expression index in synchronization with the clock CP, which is sent to a syndrome computing system 1012.

The syndrome computing system 1012 computes a syndrome in 5 CP cycles in synchronization with the clock CP and sends it to an error search/symbol error computing unit 1013. The error search/symbol error computing unit 1013 computes an error location and a symbol error in 20 bytes in synchronization with a clock CLK, of which one cycle corresponds to 16 CL.

The computed results are sent to a 4-byte symbol correction unit 1014 as the presence/absence of an error at a data location and the error correction information sequentially by 4 bytes using clocks CPK₁, CPK₂, CPK₃, CPK₄.

On the other hand, the ECL-based data latch 1010a sends data bᵢ to the symbol MUX circuit 1016 again with the clocks CPK₀, CPK₁, CPK₂, CPK₃. At the same time, the symbol MUX circuit 1016 coverts the data bᵢ into a binary representation of an expression index in synchronization with the clock CPK, which is sent to a bbi decoder circuit 1011.

The bbi decoder circuit 1011 is a circuit operative to convert the data bᵢ represented by the expression index by 4 bytes into a coefficient representation of a residue pn(x) and the output therefrom is sent to the symbol correction unit 1014 in synchronization with the clock CPK.

The symbol correction unit 1014 uses the data from the bbi decoder circuit 1011 and the data from the error search/symbol error computing unit 1013 to execute an error correction through an XOR operation at every bit in data in synchronization with the clock CPK in 4 cycles. Thus, it can reproduce the code data cᵢ by 4 bytes, which is sent to the ECL-based data latch 1010a as byte data of a coefficient of pn(x) with the clock CPK in 4 cycles.

Namely, the ECL-based data latch 1010a uses the clocks CPK^{e}₁, CPK^{e}₂, CPK^{e}₃, CPK^{e}₄ to overwrite data cᵢ in each latch by 4 bytes sequentially. Thus, the CLK cycles for preparation of the output from the ECL-based data latch 1010a is finished. The data held therein is sent as data qi to the f(x) computing system 1015 in synchronization with the clock CL^{e} and the OCL-based data latch 1010b operates similarly.

The earlier description given to the case C.1 contains no data flow that includes overwrite of code data into the latch and so forth though the decoder and so forth may be modified to achieve the similar configuration.

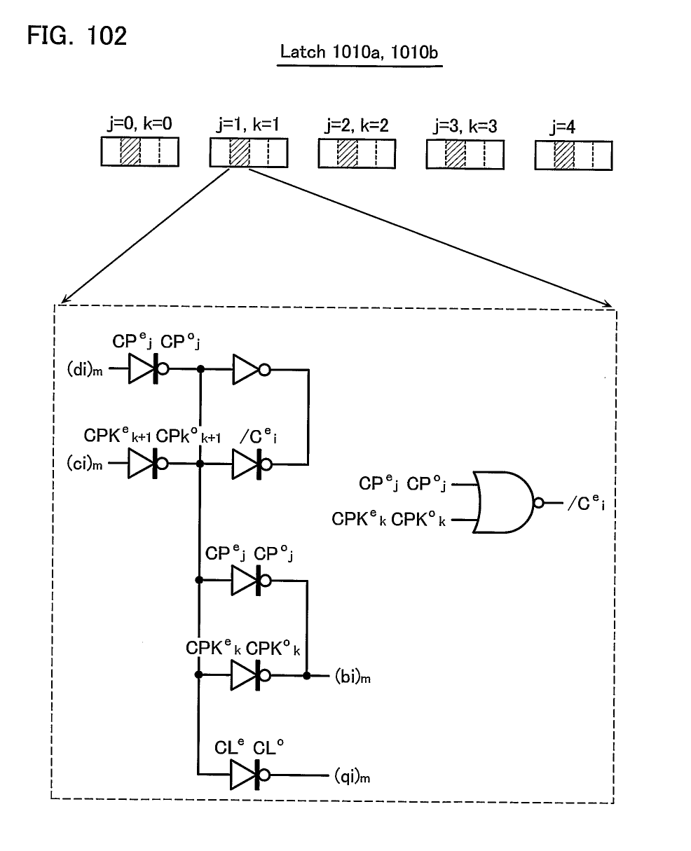

FIG. 102 shows a 1-bit latch configuration of the data latch 1010a, 1010b. The hatched portion in the figure corresponds to 1 byte, m=0-7, which configures a unit resister with resisters distinguished with i or k by 4 bytes.

In accordance with the fact that any one of the ECL system and the OCL system is configured, the data dᵢ is latched with the clock CP^{e}ⱼ, CP^{o}ⱼ and provided as an output of data bᵢ at the same time. The held data is provided as an output of data bᵢ in synchronization with the clock CPK^{e}ₖ, CPK^{o}ₖ.

The code data cᵢ is overwritten in synchronization with the clock CPK^{e}ₖ₊₁, CPK^{o}ₖ₊₁. It is overwritten with a 1-cycle shift because the data calculated on the basis of the output data is overwritten. The held code data cᵢ is output in synchronization with the clock CL^{e}, CL^{o}.

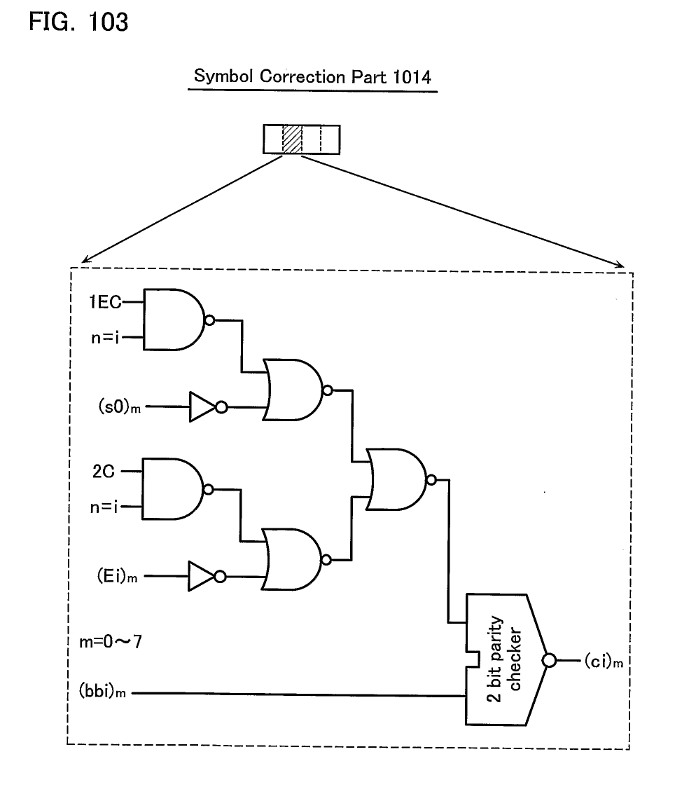

FIG. 103 shows the 1-bit circuitry of the symbol correction unit 1014. The symbol correction unit 1014 has circuit elements of 4 bytes including the hatched portion indicative of 1 byte. The specific circuitry shows only the 1-byte portion. The configuration is similar to FIG. 79 and a result from the error search/symbol error computing circuit and each bit data of data bbi are subjected to an XOR operation at the 2-bit parity checker to provide an output of a code symbol bit.

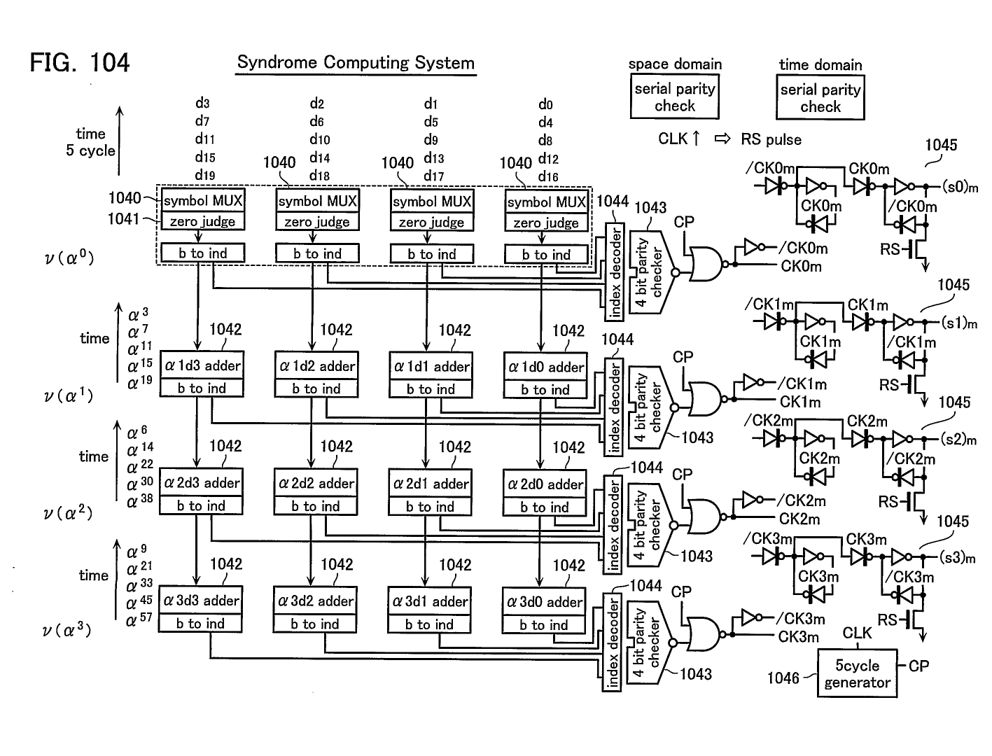

FIG. 104 shows the brief of the syndrome computing system in the case C.2. A 19th order polynomial read out of the memory has coefficients, which are denoted with d₁₉, d₁₈, d₁₇, . . . , d₂, d₁, d₀. These are multiplied by appropriate powers of a to obtain syndrome coefficients s0, s1, s2, s3.

This computing system computes 4 syndromes in 5 cycles simultaneously. Therefore, 4-byte data is fed into 12 expression index adder circuits 1042 at the same time. In association with 4 syndromes, four 4-bit parity checkers 1043 are provided to obtain sums of 4 GF(256)s simultaneously processed.

The parity checkers 1043 execute parallel parity check in space domain. The parity checkers 1043 provide outputs in 5 cycles, which are subjected to parity check at the section of “1” count circuits 1045. If the 4-bit parity checker 1043 provides an output of “1”, the section herein shifts “1” and “0” alternately to execute serial parity check in time domain.

This syndrome computing system uses the main clock CLK for error search/correction as a trigger to generate a shorter period clock CP in 5 cycles from a clock generator 1046 and executes a computation in synchronization with the clock CP. The period of the clock CP may be same as the clock CL for data output.

The input section includes symbol MUX circuits 1040 operative to receive 4-byte data d₁₉-d₁₆, d₁₅-d₁₂, d₁₁-dₛ, d₇-d₄, d₃-d₀ indicative of elements in GF(256) in 5 cycles as byte symbol data in binary representations of expression indexes. In this case, zero judge circuits 1041 are attached thereto.

These input circuits convert the data into binary representations of expression indexes and also judge a zero element. The section of the input circuits surrounded by a dotted line shows a decoder in common with the bbi circuit described in the previous data flow.

The computing system for the syndrome s0 of 4 syndrome computing systems executes a multiplication by the zeroth power of α, that is, 1, and according requires no substantial adder circuit. Therefore, a binary-converted expression index is directly fed into the parity checker 1043.

The calculations of the syndrome s1 and lower require the adder circuits 1042. The adder circuits 1042 for syndrome si (i=1-3) calculations receive binary-represented expression indexes of data di and binary representations of expression indexes of indexes of powers of α required for calculations and provide the results of union operations as expression indexes to the 4-bit parity checkers 1043.

If the input data is a zero element, then output expression indexes are all made “0” independent of the calculated result from the adder.

The outputs from the 4-bit parity checkers 1043 are used as signals for driving the counter circuits 1045 at the next stage in synchronization with the clock CP. The counter circuits 1045 start counting new “1” after they are reset by a reset pulse RS generated at the rise of the clock CLK.

The parity checkers 1043 and the counter circuits 1045 are provided 8, or m=0-7, in parallel for associated syndromes because coefficients of a residue polynomial pn(x) represent elements. This allows each syndrome to be output as pn(x) as an element in GF(256).

FIG. 105 shows a configuration example of the symbol MUX circuit 1040. This circuit receives byte data in synchronization with the clock CP or CPK. This symbol MUX circuit generates signals SWAP=“H”, /SWAP=“L” from a gate 1050 if the lower 4-bit part of the byte data is F.

On receipt of SWAP=“H”, switching circuits 1051, 1052 swap the upper 4-bit part and the lower 4-bit part to form a binary representation of an expression index. Bits in a binary representation of an expression index component 16σbᵢ(17) are all made “0” except 15σbᵢ(17) b₄.

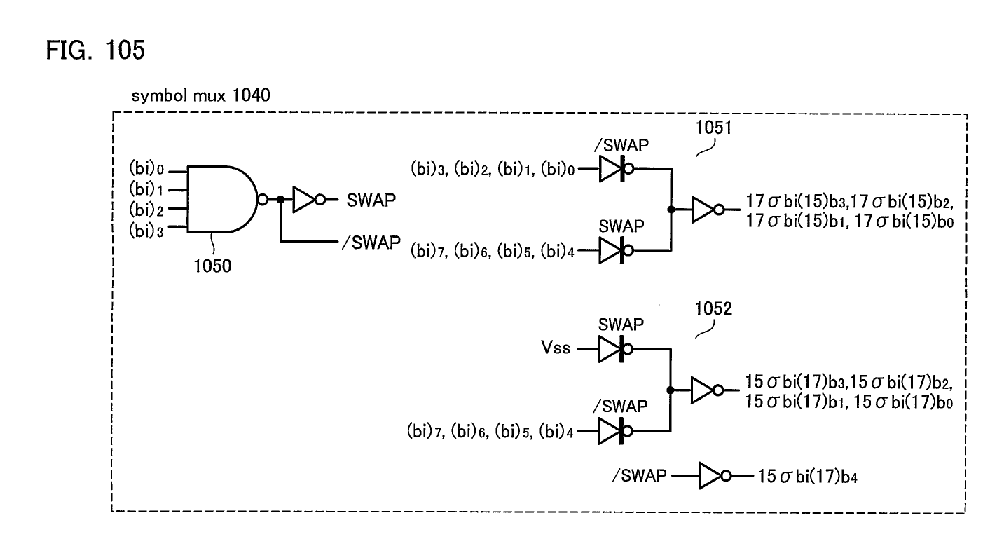

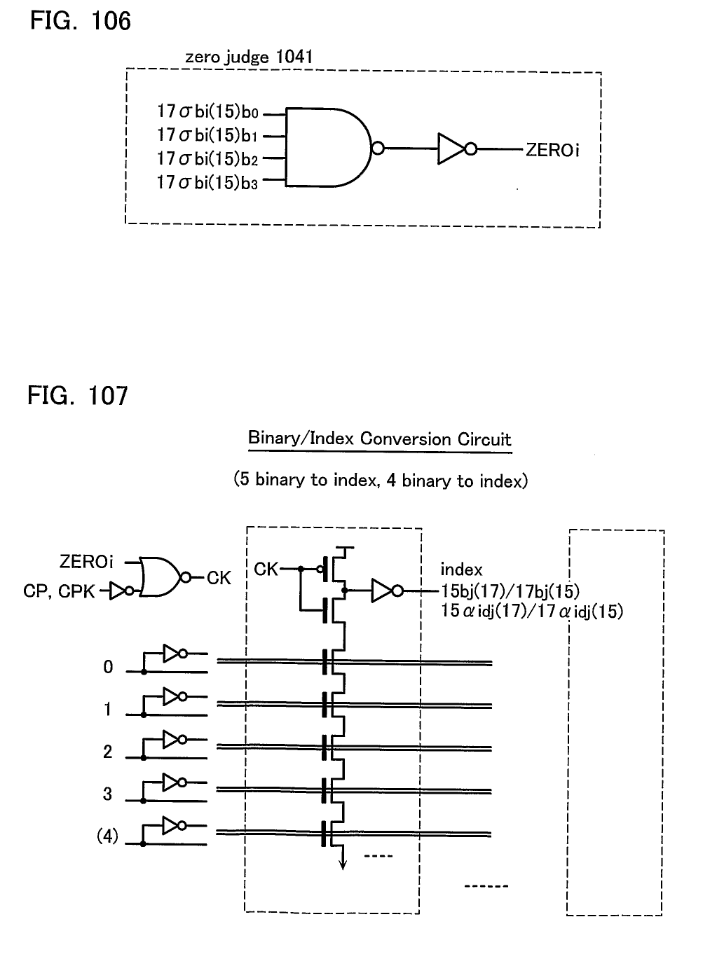

FIG. 106 shows the zero judge circuit 1041. If the binary representation of an expression index component 17σ_{bi}(15) obtained at the symbol MUX circuit 1040 is F, then the input data is a zero element symbol. In FIG. 106, the circuit generates a signal ZEROi. This signal is distinguished in 4 ways with i=0-3 in accordance with data at every 4 bytes.

FIG. 107 shows a decoding circuit (binary/index conversion circuit) for use in the symbol MUX circuit and the output section of the adder circuit. The computed results from the symbol MUX circuit and the adder are binary-represented indexes and accordingly converted into index signals available at the next stage in calculations between expression indexes.

The nodes precharged with the clock synchronized with the clock CP or CPK are discharged through an NAND logic of the decoded binary representation to yield indexes. If the input to the symbol MUX circuit is a zero element, then the output ZEROi from the zero judge circuit keeps the clock CK at “L” and the indexes all “0”.

An index for ν(α⁰) and bbi decoder circuit 1011 is 15bj(17)/17bj(15) (j=0-3) and an index for ν(α¹) (i=0-3) is 15σαbj(17)/17σαbj(15).

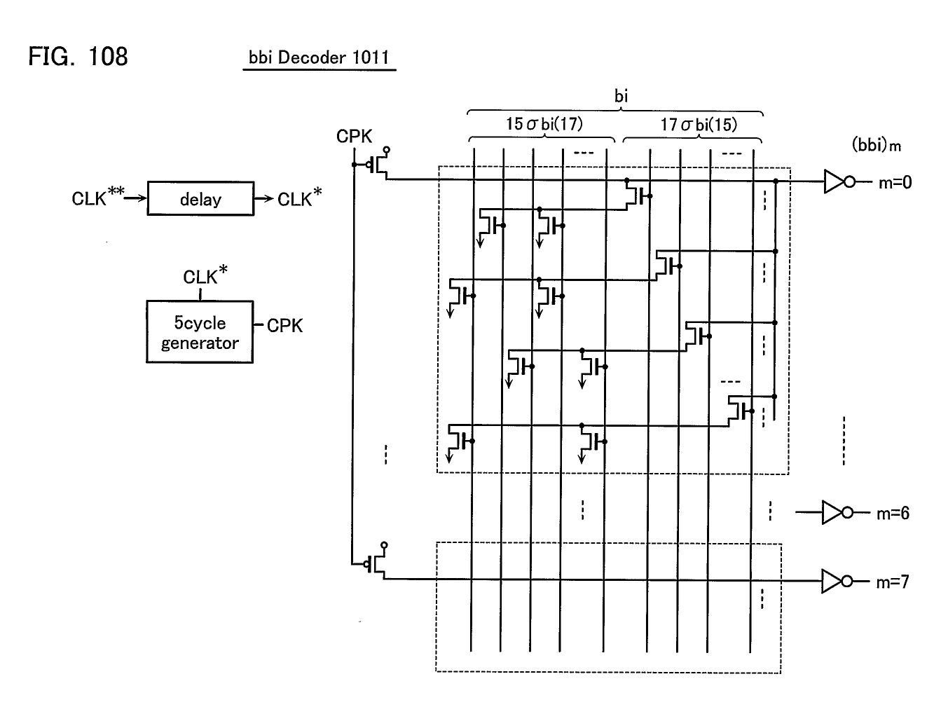

FIG. 108 shows a configuration of the bbi decoder circuit 1011, which is a circuit operative to calculate a coefficient (bbi)ₘ of pn(x) from an expression index converted from byte data bᵢ using the above association table of coefficients of elements in GF(256) and expression indexes. This circuit operates in synchronization with the clock CPK, which is generated for 5 cycles with a trigger of the clock CLK*, which is generated around at the time of completion of the symbol error calculation as delayed from the clock CLK**, which is generated around at the time of completion of the syndrome calculation as delayed from the clock CLK.

There are 5 cycles in the clock CPK. As for the decoder, after it operates in the first 4 cycles, the operation in the last 1 cycle corresponds to undesired data c₃, c₂, c₁, c₀. Therefore, the decoder may be designed to operate only in 4 cycles.

Input signals are expression indexes 15bj(17), 17bj(15) and nodes corresponding to m-th order coefficients are precharged with the clock CPK. A connection of an expression index signal on each node to a transistor gate can be determined from the above associated table of coefficients of elements in GF(256) and expression indexes.

For each m, a polynomial coefficient (bbi)ₘ can be obtained as the inversion of the level on the node. This allows easier logic formation because input decoding is achieved by node discharging.

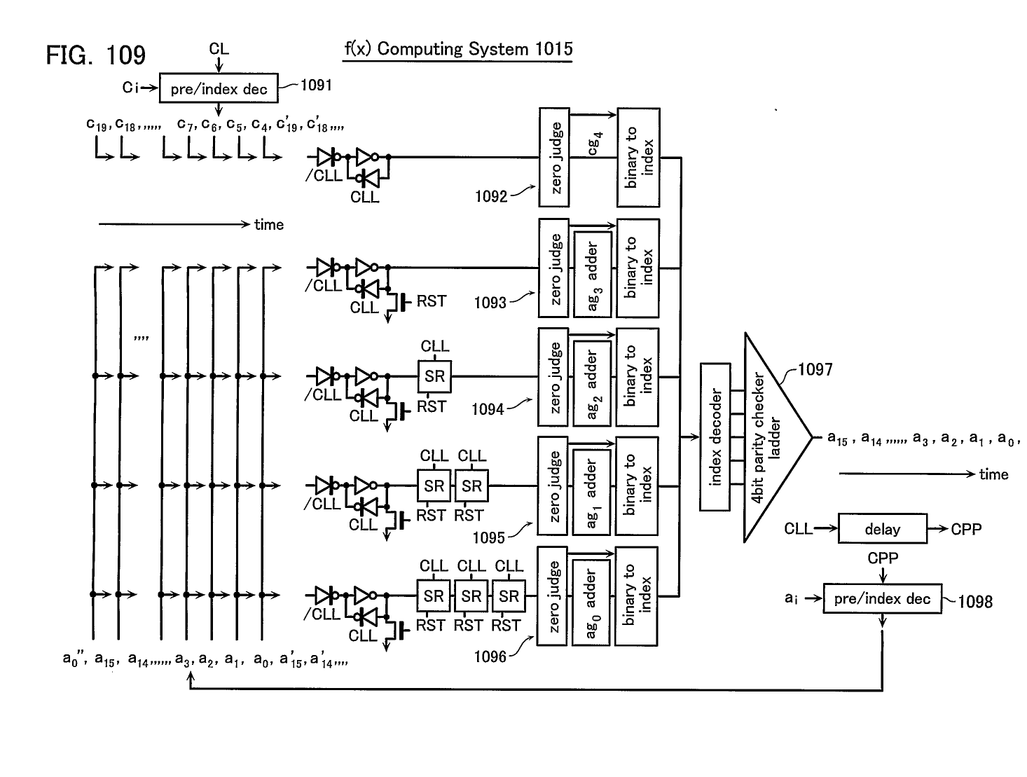

FIG. 109 shows circuitry of the f(x) computing system 1015. This is same as that in the case C.1 (FIG. 81). The output of data from the ECL-based or OCL-based data resister requires sending the data first to the f(x) computing system in synchronization with the clock CL.

The corrected symbol is represented as a coefficient of pn(x). Accordingly, the code cᵢ is converted into a binary representation of an expression index at a pre/index decoder circuit 1091 in synchronization with the clock CL for use in providing data to external. The sequence of this conversion is a decreasing order of i of cᵢ, and the converted output is fed to a cg₄ adder circuit 1092. This system includes no actual adder because g₄=1.

1-cycle, 2-cycle, 3-cycle, 4-cycle delayed output results from the computing system are converted into expression indexes, which are fed into ag₃, ag₂, ag₁, ag₀ adder circuits 1093, 1094, 1095, 1096. For that purpose, shift resisters SR are provided by a required number of stages at the input stages thereof.

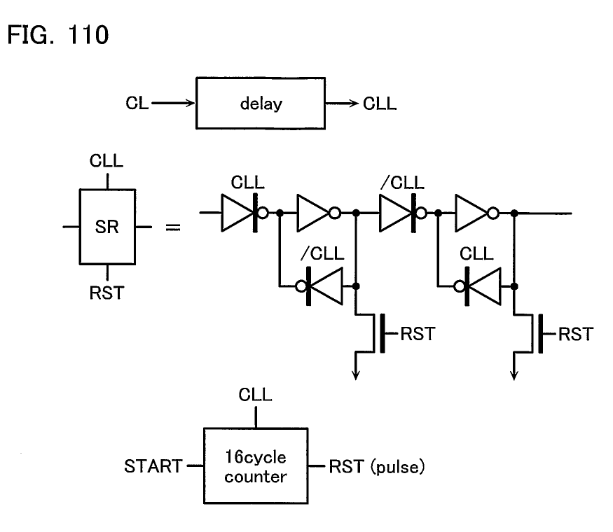

The shift resisters SR are driven with a clock CLL generated from the clock CL with a required delay interposed as shown in FIG. 110. The latches contained in the input stages are reset with a reset signal pulse RST to hold “0” at every 16 cycles of the clock CLL. The count of 16 cycles is started with a trigger signal START at the input cycle of c₁₉ as shown in FIG. 110.

In each adder circuit, a zero judge circuit is used to judge whether or not the input element is a zero element. If it is a zero element, then independent of the result from the adder, the output index is made “0”. The adder circuit calculates a sum of binary representations of an input expression index and an expression index component of a constant gᵢ.

The adder output is a binary representation and accordingly this is converted into an expression index. Then, a sum of elements is obtained at a 4-bit parity checker/ladder 1097 and aᵢ is calculated in descending order of i. The calculated aᵢ is converted into a binary representation at a pre/index decoder circuit 1098 driven with the clock CPP generated with an appropriate delay from the clock CLL for use in driving the computing system. The binary representation is fed back as a binary representation to the input of the computing system.

Different from the case C.1, the pre/index decoder circuit 1098 for feedback, driven with the clock CPP, may utilize one that is used in writing symbol data in the memory. This is because the input of and the output of data are executed at different timings.

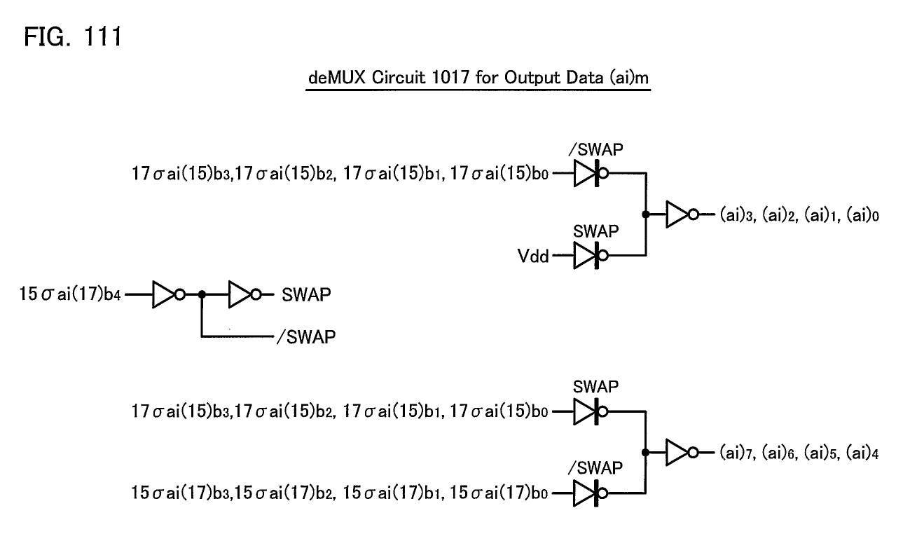

FIG. 111 shows a configuration of a deMUX circuit 1017 provided at the output section in the f(x) computing system 1015. This circuit converts a binary representation of an expression index of aᵢ of a finite field element into byte symbol data as the original information data. The deMUX circuit has same circuitry, except the input signals, as that of the deMUX circuit shown in FIG. 99 on writing code data ci in the memory.

### [Description of Case C.3]

In the cases C.1, C.2, data is exchanged on a byte basis between the ECC system and the outside on the assumption that a data block simultaneously processed at ECC is read in the memory in 16 cycles. It may be required, however, to increase the bandwidth required for data transfer by simultaneously processing 2 bytes or more.

As an example of the case C.3 for multi-byte simultaneous transfer, a method of exchanging data on a 4-byte basis as a modification of the case C.2 scheme is described below with an interface configuration thereof. Data input/output on a 4-byte basis and complete data transfer in 4 clock cycles achieve an increased data transfer speed but require encoding and decoding circuits arranged in parallel for that purpose.

In symbolization of 8-bit data, the 8-bit data ai is directly regarded as expression index components and associated with finite field elements as described in FIG. 90 as the case C.2. In such the case C.2, multiplexing of the code generation may be considered. With respect to a relation cᵢ=g₄aᵢ₋₄+g₃aᵢ₋₃+g₂aᵢ₋₂+g₂aᵢ₋₂+g₀aᵢ between information symbols and code symbols, 4 computational equations shown in the following Expression 31 can be successively used to generate 4 codes from 4-byte data in 1 cycle.

cᵢ=aᵢ₋₄+g₃aᵢ₋₃+g₂aᵢ₋₂+g₁aᵢ₋₁+g₀aᵢ

cᵢ₋₁=aᵢ₋₅+g₃aᵢ₋₄+g₂aᵢ₋₃+g₁aᵢ₋₂+g₀aᵢ₋₁

cᵢ₋₂=aᵢ₋₆+g₃aᵢ₋₅+g₂aᵢ₋₄+g₁aᵢ₋₃+g₀aᵢ₋₂

cᵢ₋₃=aᵢ₋₇+g₃aᵢ₋₆+g₂aᵢ₋₅+g₁aᵢ₋₄+g₀aᵢ₋₃ [Expression 31]

Namely, calculations of codes c₁₉, c₁₈, c₁₇, c₁₆ require data a₁₅, a₁₄, a₁₃, a₁₂ and calculations of c₁₆, c₁₄, c₁₃, c₁₂ require aₙ, a₁₀, a₉, a₈. Thus, reading data in on a 4-symbol basis enables calculations of codes by 4 codes in 5 clock cycles.

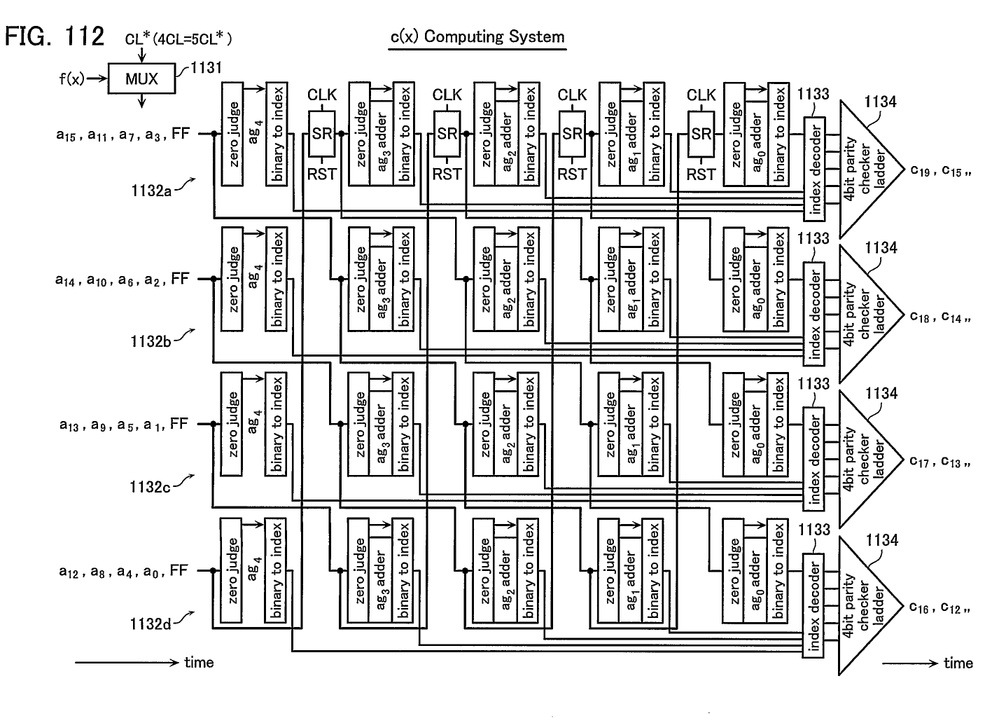

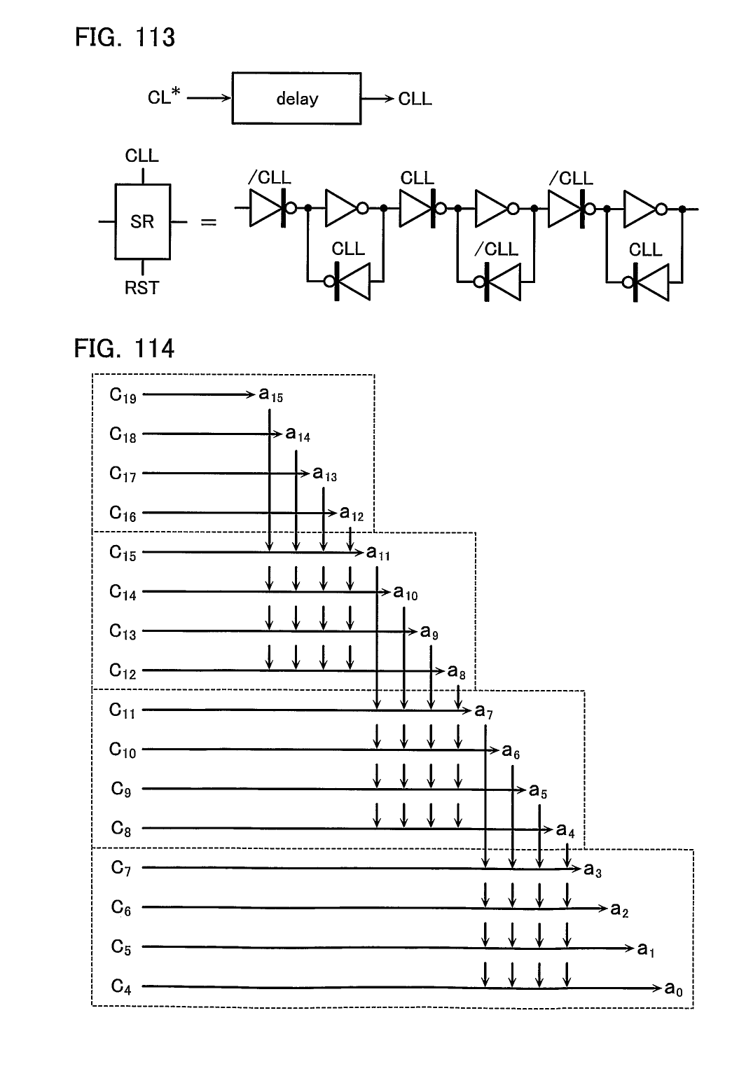

A specific circuit for code generation in the case C.3, that is, a c(x) computing system is shown in FIG. 112.

Data f(x) is converted at a MUX circuit 1131 into binary number representations of expression indexes by 4 elements in a finite field in synchronization with the clock CL*. These are sequentially fed into an adder matrix having 4 computing rows 1132a, 1132b, 1132c, 1132d, as (a₁₅, a₁₄, a₁₃, a₁₂), (a₁₁, a₁₀, a₉, a₈), (a₇, a₆, a₅, a₄), (a₃, a₂, a₁, a₀) with data (FF, FF, FF, FF) corresponding to a zero element interposed in the fifth cycle.

The computing system is driven in synchronization with a clock CLK generated with a delay from the clock CL*. The clock CL* is a clock operative in 5 cycles during 4 cycles of the clock CL for data transfer.

The uppermost computing row 1132a computes code data c₁₉, c₁₅, c₁₁, c₃. The second computing row 1132b computes code data c₁₈, c₁₄, c₁₀, c₆, c₂. The third computing row 1132c computes code data c₁₇, c₁₃, c₉, c₅, c₁. The fourth computing row 1132d computes code data c₁₆, c₁₂, cₛ, c₄, c₀.

Each computing row includes an index decoder circuit 1133 and a 4-bit parity checker/ladder 1134 for the decoded output therefrom.

This code computation corresponds to computations of i=19, 15, 11, 7, 3 in the above-described computational equations (1)-(4) and directly represents the computational equations. The computation in the first row uses the input data ahead of 1 cycle. Accordingly, a shift resister SR operative to hold 1-cycle data is interposed before the input of adders at the second and later stages. The shift resister SR operates with a clock CLL generated with a delay from the clock CL*.

No actual adder exists at each first stage because g₄=1.

After the code data generation, error location search/correction can be computed similarly as in the cases C.1 and C.2.

Also in reconstruction of information data after the code data cᵢ is reconstructed, computations are paralleled to achieve a higher speed. Namely, in consideration of g₄=1={1, 1}, g₃=α⁷⁵={3, 0}, g₂=α²⁴⁹={12, 3}, g₁=α⁷⁸={14, 6}, g₀=α⁶={5, 12}, the above Expression 31 can be rewritten to yield relational equations in Expression 32.

$$\begin{matrix} {a}_{i} = {c}_{i + 4} + {g}_{03} {a}_{i + 1} + {g}_{02} {a}_{i + 2} + {g}_{01} {a}_{i + 3} + {g}_{00} {a}_{i + 4} & [ Expression 32 ] \\ {a}_{i - 1} = {c}_{i + 3} + {h}_{3} {c}_{i + 4} + {g}_{13} {a}_{i + 1} + {g}_{12} {a}_{i + 2} + {g}_{11} {a}_{i + 3} + {g}_{10} {a}_{i + 4} & \\ {a}_{i - 2} = {c}_{i + 2} + {h}_{3} {c}_{i + 3} + {h}_{2} {c}_{i + 4} + {g}_{23} {a}_{i + 1} + {g}_{22} {a}_{i + 2} + {g}_{21} {a}_{i + 3} + {g}_{20} {a}_{i + 4} & \\ {a}_{i - 3} = {c}_{i + 1} + {h}_{3} {c}_{i + 2} + {h}_{2} {c}_{i + 3} + {h}_{1} {c}_{i + 4} + {g}_{33} {a}_{i + 1} + {g}_{32} {a}_{i + 2} + {g}_{31} {a}_{i + 3} + {g}_{30} {a}_{i + 4} & \end{matrix}$$

In accordance with these 4 relational equations, 4 symbols are calculated simultaneously in 4 cycles to obtain each information data aᵢ based on the code data cᵢ and the information data obtained in the previous cycle or before.

Coefficients of Expression 32 can be fixed as expression indexes shown in the following Expressions 33 and 34.

h₃=g₃, h₂=g₃²+g₂, h₁=g₃³+g₁,

g₀₃=g₃, g₀₂=g₂^{, g}₀₁=g₁, g₀₀=g₀,

g₁₃=g₃²+g₂, g₁₂=g₃g₂+g₁, g₁₁=g₃g₁+g₀, g₁₀=g₃g₀,

g₂₃=g₃³+g₂, g₂₂=g₃²g₂+g₃g₁+g₂²+g₀,

g₂₁=g₃²g₁+g₃g₀+g₂g₁, g₂₀=g₃²g₀+g₂g₀,

g₃₃=g₃⁴+g₃²g₂+g₂²+g₀, g₃²=g₃³g₂+g₃²g₁+g₃g₀,

g₃₁=g₃³g₁+g₃²g₀+g₂g₀+g₁², g₃₀=g₃³g₀+g₁g₀ [Expression 33]

h₃=α⁷⁵={3,0}, h₂=α¹⁶³={14, 11}, h₃=α¹³¹={5,12},

g₀₃=α⁷⁵={3,0}, g₀₂=α²⁴⁹={12,3}, g₀₁=α⁷⁸={14,6}, g₀₀=α⁶={5,12},

g₁₃=α¹⁶³={14,11}, g₁₂=α¹⁸⁹={13,3}, g₁₁=α⁵⁹={1,13}, g₁₀=α⁸¹={8,12},

g₂₃=α¹³¹={10, 7}, g₂₂=α⁶⁶={4,12}, g₂₁=α¹⁶²={16,9}, g₂₀=α¹⁶={2, 8},

g₃₃=α¹⁹⁴={3,14}, g₃₂α⁴⁹={4, 8}, g₃₁=α²⁵³={4, 11}, g₃₀=α¹³⁷={15,4}. [Expression 34]

FIG. 114 is an illustrative view of a procedure of using the code data cᵢ and the already calculated information data aᵢ to sequentially calculate subsequent information data aᵢ collectively.

Information data (a₁₅, a₁₄, a₁₃, a₁₂) can be obtained through computations directly from code data (c₁₉, c₁₈, c₁₇, c₁₆). Information data (a₁₁, a₁₀, a₉, a₈) can be obtained through computations from code data (c₁₅, c₁₄, c₁₃, c₁₂) and the information data (a₁₅, a₁₄, a₁₃, a₁₂) obtained in the previous cycle.

Information data (a₇, a₆, a₅, a₄) can be obtained through computations from code data (c₁₁, c₁₀, c₉, c₈) and the information data (a₁₁, a₁₀, a₉, a₈) obtained in the previous cycle. Information data (a₃, a₂, a₁, a₀) can be obtained through computations from code data (c₇, c₆, c₅, c₄) and the information data (a₇, a₆, a₅, a₄) obtained in the previous cycle.

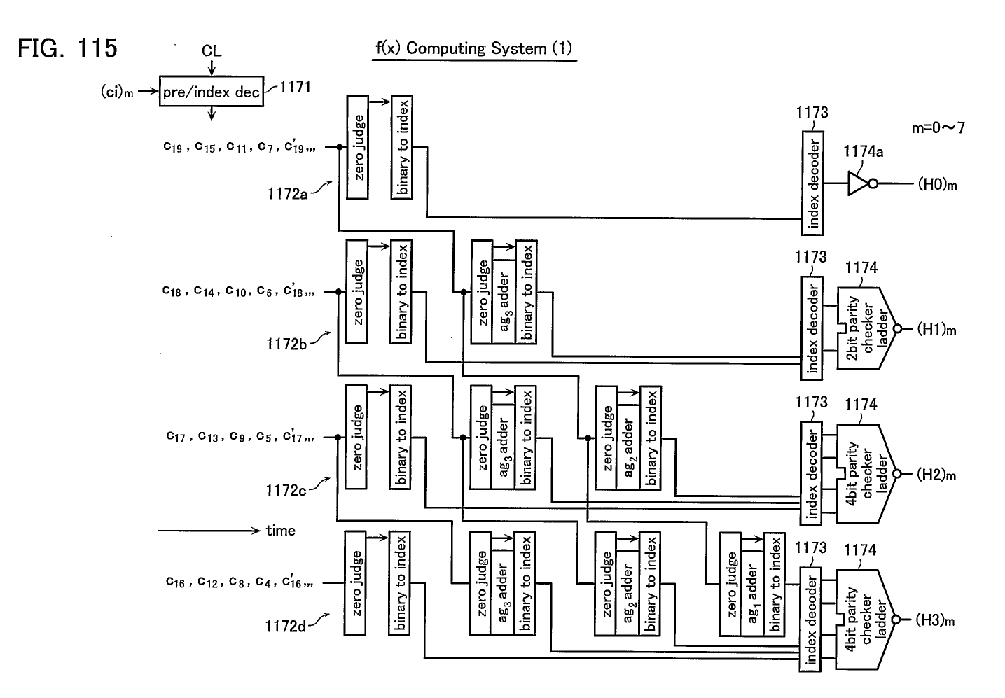

FIG. 115 shows a specific configuration example (1) of the f(x) computing system, which includes the input section of code data cᵢ. Inputs are code data cᵢ of coefficient representations converted into binary representations of expression indexes at a pre/index decoding circuit 1171 in synchronization with the clock CL. In a word, (c₁₉, c₁₈, c₁₇, c₁₆), (c₁₅, c₁₄, c₁₃, c₁₂), (c₁₁, c₁₀, c₉, c₈), (c₇, c₆, c₅, c₄) are fed into 4 computing rows 1172a, 1172b, 1172c, 1172d in the adder matrix in parallel in 4 cycles.

The first computing row 1172a computes the cᵢ₊₄ part of aᵢ. The second computing row 1172b computes the cᵢ₊₃+h_{3ci+4} part of aᵢ₋₁. The third computing row 1172c computes the cᵢ₊₂+h_{3ci+3}+h_{2ci+4} part of aᵢ₋₂. The fourth computing row 1172d computes the cᵢ₊₁+h_{3ci+2}+h_{2ci+3}+h_{1ci+4} part of aᵢ₋₃.

The computation results can be obtained as coefficient representations of finite field elements, (H0)m, (H1)ₘ, (H2)ₘ, (H3)ₘ, via index decoding circuits 1173 and via 2-bit parity checkers 1174 (except an inverter 1174a in the first row).

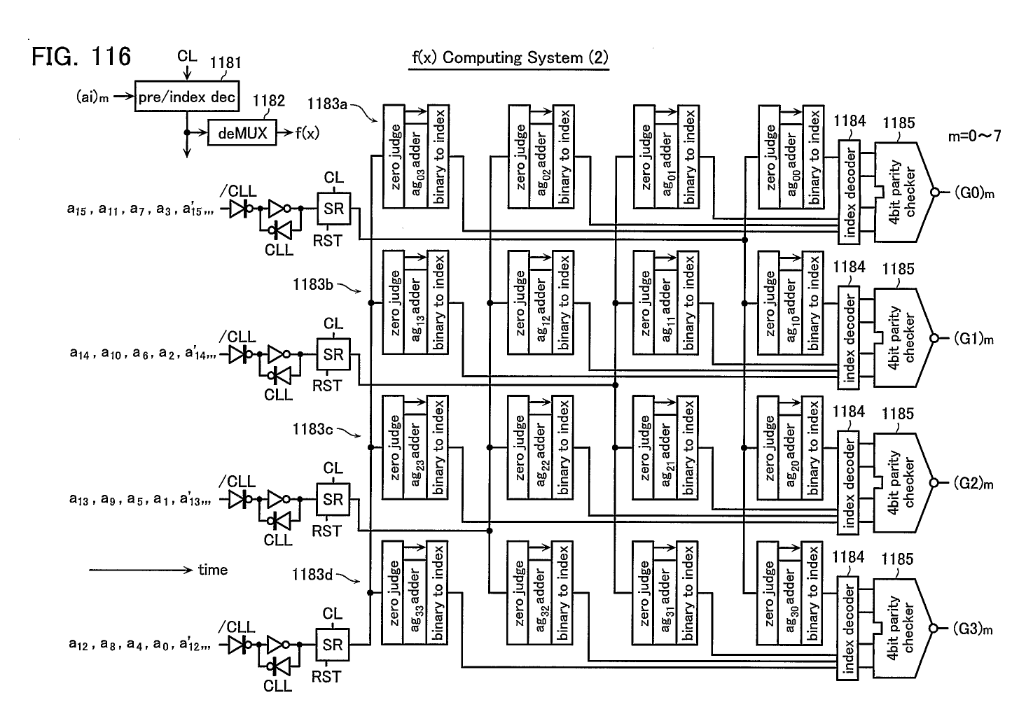

FIG. 116 shows a specific configuration example (2) of the f(x) computing system, which includes the computing section of data aᵢ of 4 bytes resulted in the previous cycle. Inputs are the computed data aᵢ of coefficient representations converted into binary representations of expression indexes at a pre/index decoding circuit 1181 in synchronization with the clock CL. In a word, (a₁₅, a₁₄, a₁₃, a₁₂), (a₁₁, a₁₀, a₉, a₈), (a₇, a₆, a₅, a₄), (a₃, a₂, a₁, a₀) are fed into 4 computing rows 1183a, 1183b, 1183c, 1183d in the adder matrix in parallel in 4 cycles.

The data converted into the binary representation is converted into coefficients of information data as byte data at a deMUX circuit 1182 and utilized in an adder in the next cycle.

The first row 1183a computes the g₀₃aᵢ₊₁+g₀₂aᵢ₊₂+g₀₁aᵢ₊₃+g_{O0}aᵢ₊₄ part of aᵢ. The second row 1183b computes the g₁₃aᵢ₊₁+g₁₂aᵢ₊₂+g₁₁aᵢ₊₃+g₁₀aᵢ₊₄ part of aᵢ₋₁. The third row 1183c computes the g₂₃aᵢ₊₁+g₂₂aᵢ₊₂+g₂₁aᵢ₊₃+g₂₀aᵢ₊₄ part of aᵢ₋₂. The fourth row 1183d computes the g₃aᵢ₊₁+g₃₂aᵢ₊₂g₃₁aᵢ₊₃+g₃₀aᵢ₊₄ part of aᵢ₋₃.

The computation results can be obtained as coefficient representations of finite field elements, (G0)ₘ, (G1)ₘ, (G2)ₘ, (G3)ₘ, via index decoding circuits 1184 and via 4-bit parity checkers 1185.

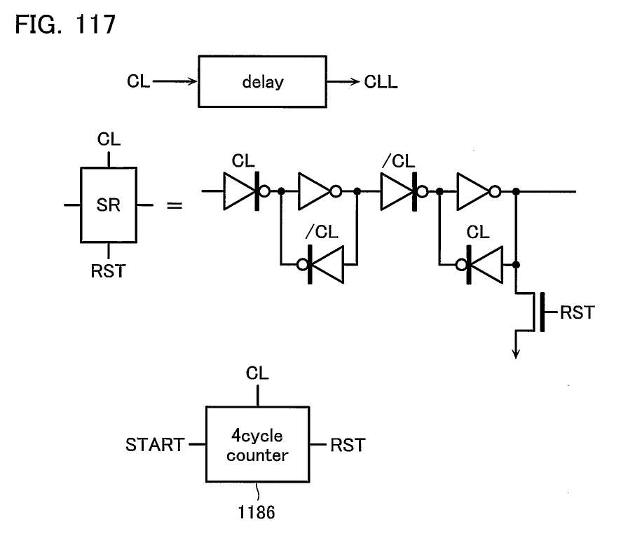

In order to hold the data until the next cycle, shift resisters SR are provided operable in synchronization with the clock CL. As shown in FIG. 117, the shift resisters SR take in data with a clock CLL generated with a delay from the clock CL. The shift resisters SR have data outputs, which are reset with a reset signal RST generated by 4 cycles of the clock CL from a counter 1186, and provide zero elements to external. This corresponds to the case without the use of (a₃, a₂, a₁, a₀) in computations.

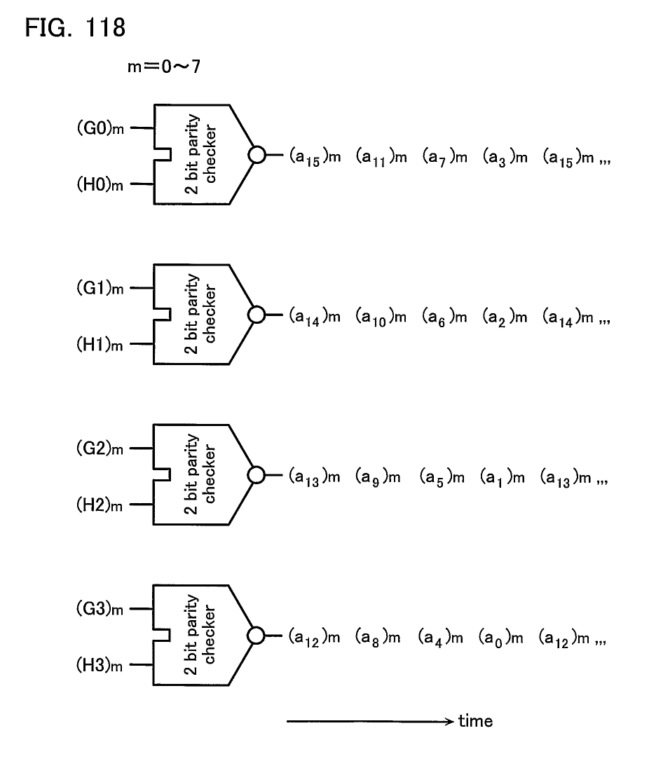

FIG. 118 shows a specific configuration example (3) of the f(x) computing system, which includes 2-bit parity checkers operative to calculate a sum of the computed results (H0)ₘ, (H1)ₘ, (H2)ₘ, (H3)ₘ from the computing section (FIG. 115) using code data and the computed results (G0)ₘ, (G1)ₘ, (G2)ₘ, (G3)ₘ from the computing section (FIG. 116) based on 4-byte data aᵢ resulted from the computations in the previous cycle.

The outputs from the parity checkers provide byte data in coefficient representation of pn(x) of finite field elements represented as symbols by information data. The data may be converted into a binary representation of an expression index and symbolized at the deMUX circuit into information data, thereby enabling 4-byte information data to be obtained at every cycle.

1. A semiconductor memory device with an error checking/correction system, comprising:
a memory cell array; and
the error checking/correction system capable of symbolizing data to be written in the memory cell array at every set of certain bits as a symbol corresponding to a finite field element of a Galois Field, searching errors of data read from the memory cell array by solving equations of finite elements with decoders representing a solution elements wherein the solution element is expressed by a specific index, correcting data based on the searched errors, and outputting the corrected data in parallel with the other error checking/correction to the next data.

2. A semiconductor memory device with an error checking/correction system, comprising:
a memory cell array; and
the error checking/correction system capable of symbolizing data to be written in the memory cell array at every set of certain bits as a symbol corresponding to a finite field element of a Galois Field, searching errors of data read from the memory cell array by solving equations of finite elements with decoders representing solution elements wherein the solution element is expressed by a specific index, correcting data based on the searched errors, and outputting the corrected data.

3. The semiconductor memory device according to claim 1,
wherein the error checking/correction system is operative to previously create a table of candidates for a solution of an error location search equation and derive an index of a root using the table to check/correct a symbol error,
wherein the error checking/correction system executes a variable conversion to the error location search equation to separate a variable part from a syndrome part and utilizes a correspondence relation between indexes of a finite field element assigned to the variable part and a finite field element assigned to the syndrome part to check a symbol error location.

4. The semiconductor memory device according to claim 1,
wherein the error checking/correction system is operative, in an index calculation for symbol error location checking and correction, to divide the number of elements in the finite field GF(2^{m}) except a zero element into mutually prime integer factors having almost the same dimension, and use expression indexes expressing indexes of primitive roots of finite field elements with residues modulo respective integer factors.

5. The semiconductor memory device claim 1, wherein the error checking/correction system is operative to associate data to be written in the memory cell array at every certain bits with a coefficient of an irreducible residue polynomial of a primitive polynomial.

6. The semiconductor memory device according to claim 1,
wherein the error checking/correction system is operative to divide the number of elements in the finite field GF(2^{m}) into mutually prime integer factors having almost the same dimension, and use expression indexes expressing indexes of primitive roots of finite field elements with residues modulo respective integer factors to configure code data to be written in the memory cell array as a binary representation of the expression index or a code derived from the binary representation through a further conversion.

7. The semiconductor memory device according to according to claim 1,
wherein the error checking/correction system includes
a first and a second data register operative to alternately receive data read out of the memory cell array, and
an error checking/correction unit operative to execute error checking and correction to read data in the first and second data registers,
wherein the error checking/correction unit executes error checking/correction to read data in one of the first and second data registers and overwrites corrected data therein while outputting overwritten data from the other.

8. The semiconductor memory device according to claim 1,
wherein the error checking/correction system is capable of symbolizing data to be written in the memory cell array at every byte as a finite field element associated with an element in a finite field GF(256), checking data read out of the memory cell array for an error-caused symbol and correcting the data,
wherein the error checking/correction system is operative to divide the number of elements, 255, in the finite field into mutually prime integer factors, 17 and 15, and express an index of a primitive root of a finite field element with an expression index a(17) as a residue modulo 17 and an expression index b(15) as a residue modulo 15,
wherein the error checking/correction system divides byte data to be symbolized into an upper part and a lower part, of each 4 bits, and regards the upper part as a binary representation of a(17) and the lower part as a binary representation of b(15) if a(17) is equal to 0-15, regards the upper part as a binary representation of b(15) and the lower part as a binary representation of a(17) if a(17) is equal to 16, and regards the data as a zero element of the finite field element if all bits are equal to 1.

9. The semiconductor memory device according to claim 2,
wherein the error checking/correction system is operative to previously create a table of candidates for a solution of an error location search equation and derive an index of a root using the table to check/correct a symbol error,
wherein the error checking/correction system executes a variable conversion to the error location search equation to separate a variable part from a syndrome part and utilizes a correspondence relation between indexes of a finite field element assigned to the variable part and a finite field element assigned to the syndrome part to check a symbol error location.

10. The semiconductor memory device according to claim 2,
wherein the error checking/correction system is operative, in an index calculation for symbol error location checking and correction, to divide the number of elements in the finite field GF(2^{m}) except a zero element into mutually prime integer factors having almost the same dimension, and use expression indexes expressing indexes of primitive roots of finite field elements with residues modulo respective integer factors.

11. The semiconductor memory device according to claim 2, wherein the error checking/correction system is operative to associate data to be written in the memory cell array at every certain bits with a coefficient of an irreducible residue polynomial of a primitive polynomial.

12. The semiconductor memory device according to claim 2,
wherein the error checking/correction system is operative to divide the number of elements in the finite field GF(2^{m}) into mutually prime integer factors having almost the same dimension, and use expression indexes expressing indexes of primitive roots of finite field elements with residues modulo respective integer factors to configure code data to be written in the memory cell array as a binary representation of the expression index or a code derived from the binary representation through a further conversion.

13. The semiconductor memory device according to claim 2,
wherein the error checking/correction system includes
a first and a second data register operative to alternately receive data read out of the memory cell array, and
an error checking/correction unit operative to execute error checking and correction to read data in the first and second data registers,
wherein the error checking/correction unit executes error checking/correction to read data in one of the first and second data registers and overwrites corrected data therein while outputting overwritten data from the other.

14. The semiconductor memory device according to claim 1,
wherein the error checking/correction system is capable of symbolizing data to be written in the memory cell array at every byte as a finite field element associated with an element in a finite field GF(256), checking data read out of the memory cell array for an error-caused symbol and correcting the data,
wherein the error checking/correction system is operative to divide the number of elements, 255, in the finite field into mutually prime integer factors, 17 and 15, and express an index of a primitive root of a finite field element with an expression index a(17) as a residue modulo 17 and an expression index b(15) as a residue modulo 15,
wherein the error checking/correction system divides byte data to be symbolized into an upper part and a lower part, of each 4 bits, and regards the upper part as a binary representation of a(17) and the lower part as a binary representation of b(15) if a(17) is equal to 0-15, regards the upper part as a binary representation of b(15) and the lower part as a binary representation of a(17) if a(17) is equal to 16, and regards the data as a zero element of the finite field element if all bits are equal to 1.
